(19) United States
(12) Patent Application Publication
(10) Pub. No.: US 2026/0059886 A1
(43) Pub. Date: Feb. 26, 2026

(54) SEMICONDUCTOR DEVICE, MANUFACTURING METHOD OF THE SAME, AND ELECTRONIC DEVICE

(71) Applicant: SONY SEMICONDUCTOR SOLUTIONS CORPORATION, Kanagawa (JP)

(72) Inventors: Naoto SASAKI, Nagasaki (JP); Keisuke HATANO, Kanagawa (JP); Keishi TANAKA, Kanagawa (JP); Masataka MAEHARA, Kanagawa (JP); Takahisa FURUHASHI, Kanagawa (JP)

(73) Assignee: SONY SEMICONDUCTOR SOLUTIONS CORPORATION, Kanagawa (JP)

(21) Appl. No.: 18/997,486

(22) PCT Filed: Jul. 28, 2023
(86) PCT No.: PCT/JP2023/027708

§ 371 Date: Jan. 21, 2025

(30) Foreign Application Priority Data
Jul. 29, 2022 (JP) 2022-121640

(51) Int. Cl. H10F 39/00

(52) U.S. Cl. CPC H10F 39/811; H10F 39/803

(57) ABSTRACT

A semiconductor device, a manufacturing method, and an electronic device capable of achieving both formation of a capacitive element and reduction in parasitic capacitance. A semiconductor device includes an internal electrode on a first surface side of a semiconductor substrate, a through hole at a position corresponding to the internal electrode, a first rewiring on a second surface side of the semiconductor substrate and connected to the internal electrode via the through hole, a second rewiring connected to the first rewiring on a side closer to an external connection terminal than the first rewiring, and an interlayer insulating film between the first and second rewirings. Two of a first internal electrode and a second internal electrode are provided as the internal electrode, and the first rewiring connected to the first internal electrode, the second rewiring connected to the second internal electrode, and the interlayer insulating film constitute a capacitor.

### TECHNICAL FIELD

The present disclosure relates to a semiconductor device, a manufacturing method of the same, and an electronic device, and more particularly relates to a semiconductor device, a manufacturing method of the same, and an electronic device capable of achieving both formation of a capacitive element and reduction in parasitic capacitance.

### BACKGROUND ART

Conventionally, a chip size package has been employed in order to achieve downsizing of a semiconductor device. In particular, in a chip size package type solid-state imaging device for achieving downsizing of a camera module, a configuration has been employed in which a logic substrate such as a drive element is bonded to a back surface of an image sensor substrate, and a rewiring connected to an external connection terminal formed on a back surface side of the logic substrate is connected to an internal electrode on the logic substrate side via a through hole penetrating a silicon substrate casing portion. At this time, the rewiring and the silicon substrate casing portion are electrically separated by the insulating film, but there is a problem that a signal delay occurs due to parasitic capacitance between the rewiring and the silicon substrate casing portion, and the input/output response speed varies.

In order to suppress the signal delay, it is conceivable to stabilize the potential by connecting a capacitive element to an internal electrode connected to a power supply voltage of the solid-state imaging device. For example, Patent Document 1 discloses a technique of forming a capacitive element in a through hole.

### CITATION LIST

### Patent Document

PATENT DOCUMENT 1 Japanese Patent Application Laid-Open No. 2020-141090

### SUMMARY OF THE INVENTION

### Problems to be Solved by the Invention

However, the structure of the capacitive element disclosed in Patent Document 1 uses a wiring structure specialized for capacitive element formation, and in a case where these wirings are used for signal input and output, the parasitic capacitance of the wirings increases. In order to reduce the parasitic capacitance of the wiring, while it is necessary to increase the thickness of the insulating film between the electrodes, it is necessary to reduce the thickness of the capacitor in order to store electric charge, and both cannot be achieved.

The present disclosure has been made in view of such a situation, and aims to achieve both formation of a capacitive element and reduction in parasitic capacitance.

### Solutions to Problems

A semiconductor device according to a first aspect of the present disclosure includes: an internal electrode formed on a first surface side of a semiconductor substrate; a through hole formed at a position corresponding to the internal electrode of the semiconductor substrate;
a first rewiring formed on a second surface side opposite to the first surface side of the semiconductor substrate and connected to the internal electrode via the through hole;
a second rewiring connected to the first rewiring and formed on a side closer to an external connection terminal than the first rewiring; and
an interlayer insulating film formed between the first rewiring and the second rewiring, in which
two of a first internal electrode and a second internal electrode are provided as the internal electrode, and
the first rewiring connected to the first internal electrode, the second rewiring connected to the second internal electrode, and the interlayer insulating film constitute a capacitor.

A manufacturing method of a semiconductor device according to a second aspect of the present disclosure includes:
forming an internal electrode formed on a first surface side of a semiconductor substrate,
a through hole formed at a position corresponding to the internal electrode of the semiconductor substrate,
a first rewiring formed on a second surface side opposite to the first surface side of the semiconductor substrate and connected to the internal electrode via the through hole,
a second rewiring connected to the first rewiring and formed on a side closer to an external connection terminal than the first rewiring, and
an interlayer insulating film formed between the first rewiring and the second rewiring, in which
two of a first internal electrode and a second internal electrode are formed as the internal electrode, and the first rewiring connected to the first internal electrode, the second rewiring connected to the second internal electrode, and the interlayer insulating film constitute a capacitor.

An electronic device according to a third aspect of the present disclosure includes a semiconductor device including:
an internal electrode formed on a first surface side of a semiconductor substrate;
a through hole formed at a position corresponding to the internal electrode of the semiconductor substrate;
a first rewiring formed on a second surface side opposite to the first surface side of the semiconductor substrate and connected to the internal electrode via the through hole;
a second rewiring connected to the first rewiring and formed on a side closer to an external connection terminal than the first rewiring; and
an interlayer insulating film formed between the first rewiring and the second rewiring, in which
two of a first internal electrode and a second internal electrode are provided as the internal electrode, and the first rewiring connected to the first internal electrode, the second rewiring connected to the second internal electrode, and the interlayer insulating film constitute a capacitor.

In the first to third aspects of the present disclosure, an internal electrode formed on a first surface side of a semiconductor substrate, a through hole formed at a position corresponding to the internal electrode of the semiconductor substrate, a first rewiring formed on a second surface side opposite to the first surface side of the semiconductor substrate and connected to the internal electrode via the through hole, a second rewiring connected to the first rewiring and formed on a side closer to an external connection terminal than the first rewiring, and an interlayer insulating film formed between the first rewiring and the second rewiring are provided, in which two of a first internal electrode and a second internal electrode are formed as the internal electrode, and the first rewiring connected to the first internal electrode, the second rewiring connected to the second internal electrode, and the interlayer insulating film constitute a capacitor.

A semiconductor device according to a fourth aspect of the present disclosure includes:
a first electrode connected to a rewiring formed on a back surface side of a semiconductor substrate;
a second electrode surrounding a periphery of the first electrode in plan view; and
an insulating film between the first electrode and the second electrode, in which
a capacitor is constituted by the first electrode, the second electrode, and the insulating film.

A manufacturing method of a semiconductor device according to a fifth aspect of the present disclosure includes:
forming a first electrode connected to a rewiring formed on a back surface side of a semiconductor substrate,
a second electrode surrounding a periphery of the first electrode in plan view, and
an insulating film between the first electrode and the second electrode, in which
a capacitor is constituted by the first electrode, the second electrode, and the insulating film.

In the fourth and fifth aspects of the present disclosure, a first electrode connected to a rewiring formed on a back surface side of a semiconductor substrate, a second electrode surrounding a periphery of the first electrode in plan view, and an insulating film between the first electrode and the second electrode are provided, and a capacitor is constituted by the first electrode, the second electrode, and the insulating film.

A semiconductor device according to a sixth aspect of the present disclosure includes:
a trench formed in a semiconductor substrate and having a side surface inclined at a predetermined angle;
at least two electrode films of a first electrode film and a second electrode film stacked in the trench; and
a dielectric film formed between at least the first electrode film and the second electrode film, in which
the first electrode film formed along the side surface of the trench is connected to a first rewiring on the semiconductor substrate,
the second electrode film formed along the side surface of the trench is connected to another of the first rewirings on the semiconductor substrate, and
a capacitor is constituted by stacking the first electrode film, the dielectric film, and the second electrode film.

A manufacturing method of a semiconductor device according to a seventh aspect of the present disclosure includes:
forming a trench having a side surface inclined at a predetermined angle in a semiconductor substrate;
forming at least two electrode films of a first electrode film and a second electrode film stacked in the trench;
forming a dielectric film between at least the first electrode film and the second electrode film, in which
the first electrode film formed along the side surface of the trench is formed to be connected to a first rewiring on the semiconductor substrate, and the second electrode film formed along the side surface of the trench is formed to be connected to another of the first rewirings on the semiconductor substrate, and
a capacitor is constituted by stacking the first electrode film, the dielectric film, and the second electrode film.

In the sixth and seventh aspects of the present disclosure, a trench formed in a semiconductor substrate and having a side surface inclined at a predetermined angle, at least two electrode films of a first electrode film and a second electrode film stacked in the trench, and a dielectric film formed between at least the first electrode film and the second electrode film are further included, the first electrode film formed along the side surface of the trench is connected to a first rewiring on the semiconductor substrate, the second electrode film formed along the side surface of the trench is connected to another of the first rewirings on the semiconductor substrate, and a capacitor is constituted by stacking the first electrode film, the dielectric film, and the second electrode film.

The semiconductor device and the electronic device may be independent devices, or modules incorporated in other devices.

### BRIEF DESCRIPTION OF DRAWINGS

FIG. 1 is an overall configuration cross-sectional view of a first embodiment of a solid-state imaging device to which the present technology is applied.

FIG. 2 is a cross-sectional view illustrating a detailed structure of a capacitor according to a first configuration example.

FIG. 3 is a view describing a manufacturing method of the capacitor according to the first configuration example.

FIG. 4 is a view describing the manufacturing method of the capacitor according to the first configuration example.

FIG. 5 is a view describing the manufacturing method of the capacitor according to the first configuration example.

FIG. 6 is a cross-sectional view illustrating a detailed structure of a capacitor according to a second configuration example.

FIG. 7 is a view describing a first manufacturing method of a solid-state imaging device including the capacitor according to the second configuration example.

FIG. 8 is a view describing the first manufacturing method of the solid-state imaging device including the capacitor according to the second configuration example.

FIG. 9 is a view describing a second manufacturing method of the solid-state imaging device including the capacitor according to the second configuration example.

FIG. 10 is a view describing the second manufacturing method of the solid-state imaging device including the capacitor according to the second configuration example.

FIG. 11 is a view describing a third manufacturing method of the solid-state imaging device including the capacitor according to the second configuration example.

FIG. 12 is a view describing the third manufacturing method of the solid-state imaging device including the capacitor according to the second configuration example.

FIG. 13 is a cross-sectional view illustrating a detailed structure of a capacitor according to a third configuration example.

FIG. 14 is a view describing a manufacturing method of a solid-state imaging device including the capacitor according to the third configuration example.

FIG. 15 is a view describing the manufacturing method of the solid-state imaging device including the capacitor according to the third configuration example.

FIG. 16 is a cross-sectional view illustrating a detailed structure of a capacitor according to a fourth configuration example.

FIG. 17 is a view describing the manufacturing method of a solid-state imaging device including the capacitor according to the fourth configuration example.

FIG. 18 is a view describing the manufacturing method of the solid-state imaging device including the capacitor according to the fourth configuration example.

FIG. 19 is a cross-sectional view illustrating a detailed structure of a capacitor according to a fifth configuration example.

FIG. 20 is a view describing a manufacturing method of a solid-state imaging device including the capacitor according to the fifth configuration example.

FIG. 21 is a cross-sectional view illustrating a detailed structure of a capacitor according to a sixth configuration example.

FIG. 22 is a view describing a manufacturing method of a solid-state imaging device including the capacitor according to the sixth configuration example.

FIG. 23 is a cross-sectional view illustrating a detailed structure of a capacitor according to a seventh configuration example.

FIG. 24 is a view describing a manufacturing method of a solid-state imaging device including the capacitor according to the seventh configuration example.

FIG. 25 is a view describing the manufacturing method of the solid-state imaging device including the capacitor according to the seventh configuration example.

FIG. 26 is a view describing the manufacturing method of the solid-state imaging device including the capacitor according to the seventh configuration example.

FIG. 27 is a cross-sectional view illustrating a detailed structure of a capacitor according to an eighth configuration example.

FIG. 28 is a view describing a manufacturing method of a solid-state imaging device including the capacitor according to the eighth configuration example.

FIG. 29 is a view describing the manufacturing method of the solid-state imaging device including the capacitor according to the eighth configuration example.

FIG. 30 is a view describing the manufacturing method of the solid-state imaging device including the capacitor according to the eighth configuration example.

FIG. 31 is a cross-sectional view illustrating a detailed structure of a capacitor according to a ninth configuration example.

FIG. 32 is a plan view of a capacitor according to the ninth configuration example.

FIG. 33 is an overall configuration cross-sectional view of a tenth embodiment of a solid-state imaging device to which the present technology is applied.

FIG. 34 is a plan view of a solid-state imaging device 1 according to the tenth embodiment.

FIG. 35 is a cross-sectional view of a solid-state imaging device having a stacked structure in which three substrates are stacked.

FIG. 36 is a cross-sectional view illustrating a detailed structure of a capacitor according to an 11th configuration example.

FIG. 37 is a cross-sectional view illustrating the detailed structure of the capacitor according to the 11th configuration example.

FIG. 38 is a view describing a manufacturing method of a solid-state imaging device including the capacitor according to the 11th configuration example.

FIG. 39 is a view describing the manufacturing method of the solid-state imaging device including the capacitor according to the 11th configuration example.

FIG. 40 is a view describing the manufacturing method of the solid-state imaging device including the capacitor according to the 11th configuration example.

FIG. 41 is a view describing the manufacturing method of the solid-state imaging device including the capacitor according to the 11th configuration example.

FIG. 42 is a view describing the manufacturing method of the solid-state imaging device including the capacitor according to the 11th configuration example.

FIG. 43 is a view describing the manufacturing method of the solid-state imaging device including the capacitor according to the 11th configuration example.

FIG. 44 is a view describing the manufacturing method of the solid-state imaging device including the capacitor according to the 11th configuration example.

FIG. 45 is a view describing the manufacturing method of the solid-state imaging device including the capacitor according to the 11th configuration example.

FIG. 46 is a view describing the manufacturing method of the solid-state imaging device including the capacitor according to the 11th configuration example.

FIG. 47 is a cross-sectional view of a solid-state imaging device according to a 12th embodiment.

FIG. 48 is a plan view of the vicinity of capacitors in FIG. 47 as viewed from a back surface side of the solid-state imaging device.

FIG. 49 is a view describing a manufacturing method of the solid-state imaging device including the capacitors according to a 12th configuration example.

FIG. 50 is a view describing the manufacturing method of the solid-state imaging device including the capacitors according to the 12th configuration example.

FIG. 51 is a view describing the manufacturing method of the solid-state imaging device including the capacitors according to the 12th configuration example.

FIG. 52 is a view describing the manufacturing method of the solid-state imaging device including the capacitors according to the 12th configuration example.

FIG. 53 is a view describing the manufacturing method of the solid-state imaging device including the capacitors according to the 12th configuration example.

FIG. 54 is a view describing the manufacturing method of the solid-state imaging device including the capacitors according to the 12th configuration example.

FIG. 55 is a view describing the manufacturing method of the solid-state imaging device including the capacitors according to the 12th configuration example.

FIG. 56 is a view describing the manufacturing method of the solid-state imaging device including the capacitors according to the 12th configuration example.

FIG. 57 is a view describing the manufacturing method of the solid-state imaging device including the capacitors according to the 12th configuration example.

FIG. 58 is a cross-sectional view illustrating a detailed structure of a first modification of the capacitors according to the 12th configuration example.

FIG. 59 is a view describing a manufacturing method of a solid-state imaging device including the capacitors according to the first modification of the 12th configuration example.

FIG. 60 is a view describing the manufacturing method of the solid-state imaging device including the capacitors according to the first modification of the 12th configuration example.

FIG. 61 is a view describing the manufacturing method of the solid-state imaging device including the capacitors according to the first modification of the 12th configuration example.

FIG. 62 is a view describing the manufacturing method of the solid-state imaging device including the capacitors according to the first modification of the 12th configuration example.

FIG. 63 is a view describing the manufacturing method of the solid-state imaging device including the capacitors according to the first modification of the 12th configuration example.

FIG. 64 is a view describing the manufacturing method of the solid-state imaging device including the capacitors according to the first modification of the 12th configuration example.

FIG. 65 is a view describing the manufacturing method of the solid-state imaging device including the capacitors according to the first modification of the 12th configuration example.

FIG. 66 is a view describing the manufacturing method of the solid-state imaging device including the capacitors according to the first modification of the 12th configuration example.

FIG. 67 is a view describing the manufacturing method of the solid-state imaging device including the capacitors according to the first modification of the 12th configuration example.

FIG. 68 is a view describing the manufacturing method of the solid-state imaging device including the capacitors according to the first modification of the 12th configuration example.

FIG. 69 is a cross-sectional view illustrating a detailed structure of a second modification of the capacitors according to the 12th configuration example.

FIG. 70 is a view describing a manufacturing method of a solid-state imaging device including the capacitors according to the second modification of the 12th configuration example.

FIG. 71 is a view describing the manufacturing method of the solid-state imaging device including the capacitors according to the second modification of the 12th configuration example.

FIG. 72 is a view describing the manufacturing method of the solid-state imaging device including the capacitors according to the second modification of the 12th configuration example.

FIG. 73 is a view describing the manufacturing method of the solid-state imaging device including the capacitors according to the second modification of the 12th configuration example.

FIG. 74 is a view describing the manufacturing method of the solid-state imaging device including the capacitors according to the second modification of the 12th configuration example.

FIG. 75 is a view describing the manufacturing method of the solid-state imaging device including the capacitors according to the second modification of the 12th configuration example.

FIG. 76 is a cross-sectional view illustrating a detailed structure of a third modification of the capacitors according to the 12th configuration example.

FIG. 77 is a view describing a manufacturing method of a solid-state imaging device including the capacitors according to the third modification of the 12th configuration example.

FIG. 78 is a view describing the manufacturing method of the solid-state imaging device including the capacitors according to the third modification of the 12th configuration example.

FIG. 79 is a view describing the manufacturing method of the solid-state imaging device including the capacitors according to the third modification of the 12th configuration example.

FIG. 80 is a view describing the manufacturing method of the solid-state imaging device including the capacitors according to the third modification of the 12th configuration example.

FIG. 81 is a cross-sectional view of a solid-state imaging device according to a 13th embodiment.

FIG. 82 is a cross-sectional view illustrating a first configuration example of an internal electrode on a left side of FIG. 81.

FIG. 83 is a plan view of a lattice pattern wiring.

FIG. 84 is a cross-sectional view illustrating a second configuration example of the internal electrode on the left side of FIG. 81.

FIG. 85 is a cross-sectional view illustrating a first configuration example of an internal electrode on a right side of FIG. 81.

FIG. 86 is a plan view passing through a lattice pattern wiring in the cross-sectional view of FIG. 85.

FIG. 87 is a cross-sectional view illustrating a second configuration example of the internal electrode on the right side of FIG. 81.

FIG. 88 is a cross-sectional view illustrating a third configuration example of the internal electrode on the right side of FIG. 81.

FIG. 89 is a cross-sectional view illustrating a fourth configuration example of the internal electrode on the right side of FIG. 81.

FIG. 90 is a plan view passing through a predetermined lattice pattern wiring of the internal electrode of FIG. 89.

FIG. 91 is a cross-sectional view of a cylinder-type MIM capacitor.

FIG. 92 is a simplified conceptual view of the cylinder-type MIM capacitor of FIG. 91.

FIG. 93 is a view describing a manufacturing method of the cylinder-type MIM capacitor in FIG. 91.

FIG. 94 is a view describing the manufacturing method of the cylinder-type MIM capacitor in FIG. 91.

FIG. 95 is a view describing the manufacturing method of the cylinder-type MIM capacitor in FIG. 91.

FIG. 96 is a view describing the manufacturing method of the cylinder-type MIM capacitor in FIG. 91.

FIG. 97 is a view describing the manufacturing method of the cylinder-type MIM capacitor in FIG. 91.

FIG. 98 is a view describing the manufacturing method of the cylinder-type MIM capacitor in FIG. 91.

FIG. 99 is a view describing the manufacturing method of the cylinder-type MIM capacitor in FIG. 91.

FIG. 100 is a cross-sectional view of a cylinder-type MIM two-layer capacitor.

FIG. 101 is a view describing a manufacturing method of the cylinder-type MIM two-layer capacitor in FIG. 100.

FIG. 102 is a view describing a manufacturing method of the cylinder-type MIM two-layer capacitor in FIG. 100.

FIG. 103 is a view describing a manufacturing method of the cylinder-type MIM two-layer capacitor in FIG. 100.

FIG. 104 is a view describing a manufacturing method of the cylinder-type MIM two-layer capacitor in FIG. 100.

FIG. 105 is a view describing a manufacturing method of the cylinder-type MIM two-layer capacitor in FIG. 100.

FIG. 106 is a view describing a manufacturing method of the cylinder-type MIM two-layer capacitor in FIG. 100.

FIG. 107 is a view describing a manufacturing method of the cylinder-type MIM two-layer capacitor in FIG. 100.

FIG. 108 is a cross-sectional view illustrating an example in which the cylinder-type MIM capacitor is applied to a single-plate front surface irradiation type solid-state imaging device.

FIG. 109 is a cross-sectional view of a solid-state imaging device according to a 14th embodiment.

FIG. 110 is an enlarged view illustrating a detailed structure of a capacitor according to a 14th configuration example.

FIG. 111 is a view describing a manufacturing method of the capacitor according to the 14th configuration example.

FIG. 112 is a view describing the manufacturing method of the capacitor according to the 14th configuration example.

FIG. 113 is a view describing the manufacturing method of the capacitor according to the 14th configuration example.

FIG. 114 is a view describing the manufacturing method of the capacitor according to the 14th configuration example.

FIG. 115 is a view describing the manufacturing method of the capacitor according to the 14th configuration example.

FIG. 116 is a cross-sectional view of a capacitor according to a modification of the 14th configuration example.

FIG. 117 is a cross-sectional view of a capacitor according to a modification of the 14th configuration example.

FIG. 118 is a plan view illustrating a configuration example in which the capacitors of FIG. 110 are connected in parallel.

FIG. 119 is a view illustrating another configuration example of the capacitor according to the 14th configuration example.

FIG. 120 is a cross-sectional view illustrating a modification of the solid-state imaging device according to the 14th embodiment.

FIG. 121 is a diagram describing a usage example of an image sensor.

FIG. 122 is a block diagram illustrating a configuration example of an imaging device as an electronic device to which the technology of the present disclosure is applied.

FIG. 123 is a view illustrating an example of a schematic configuration of an endoscopic surgery system.

FIG. 124 is a block diagram illustrating an example of functional configurations of a camera head and a camera control unit (CCU).

FIG. 125 is a block diagram illustrating an example of a schematic configuration of a vehicle control system.

FIG. 126 is an explanatory diagram describing an example of installation positions of an outside-vehicle information detecting section and an imaging section.

### MODE FOR CARRYING OUT THE INVENTION

Hereinafter, modes for carrying out the technique of the present disclosure (hereinafter, referred to as embodiments) will be described with reference to the accompanying drawings. The description will be given in the following order.
1. First embodiment of solid-state imaging device
2. Detailed configuration of first configuration example of capacitor
3. Manufacturing method of capacitor according to first configuration example
4. Second configuration example of capacitor
5. First manufacturing method of capacitor according to second configuration example
6. Second manufacturing method of capacitor according to second configuration example
7. Third manufacturing method of capacitor according to second configuration example
8. Third configuration example of capacitor
9. Manufacturing method of capacitor according to third configuration example
10. Fourth configuration example of capacitor
11. Manufacturing method of capacitor according to fourth configuration example
12. Fifth configuration example of capacitor
13. Manufacturing method of capacitor according to fifth configuration example
14. Sixth configuration example of capacitor
15. Manufacturing method of capacitor according to sixth configuration example
16. Seventh configuration example of capacitor
17. Manufacturing method of capacitor according to seventh configuration example
18. Eighth configuration example of capacitor
19. Manufacturing method of capacitor according to eighth configuration example
20. Ninth configuration example of capacitor
21. Tenth embodiment of solid-state imaging device
22. Summary of first to tenth embodiments
23. Three-layer stacked configuration example
24. 11th configuration example of capacitor
25. Manufacturing method of capacitor according to 11th configuration example
26. 12th configuration example of capacitor
27. Manufacturing method of capacitor according to 12th configuration example
28. First modification of 12th configuration example
29. Manufacturing method of capacitor according to first modification of 12th configuration example
30. Second modification of 12th configuration example
31. Manufacturing method of capacitor according to second modification of 12th configuration example
32. Third modification of 12th configuration example
33. Manufacturing method of capacitor according to third modification of 12th configuration example
34. 13th configuration example of capacitor
35. Cross-sectional view of extraction electrode connection of cylinder-type MIM capacitor
36. Manufacturing method of cylinder-type MIM capacitor
37. Extraction electrode connection cross-sectional view of cylinder-type MIM two-layer capacitor
38. Manufacturing method of cylinder-type MIM two-layer capacitor
39. 14th configuration example of capacitor
40. Manufacturing method of capacitor according to 14th configuration example
41. Modification of 14th configuration example
42. Combination of capacitor according to 14th configuration example and another capacitor
43. Usage example of image sensor
44. Application example for electronic device
45. Application example to endoscopic surgery system
46. Application example to mobile body

Note that, in the drawings referred to in the following description, the same or similar parts are denoted by the same or similar reference numerals, and the description thereof will not be repeated as appropriate. The drawings are schematic, and the relationship between the thickness and the plane dimension, the ratio of the thickness of each layer, and other points are different from the actual ones. Furthermore, the drawings may include portions having different dimensional relationships and ratios.

Furthermore, the definitions of directions such as up and down or the like in the following description are merely definitions for convenience of description, and do not limit the technical idea of the present disclosure. For example, when an object is observed by rotating the object by 90°, the up and down are converted into and read as left and right, and when the object is observed by rotating the object by 180°, the up and down are inverted and read.

Hereinafter, an embodiment of a solid-state imaging device to which the present technology is applied will be described, but the present technology can be applied to all semiconductor devices.

### 1. First Embodiment of Solid-State Imaging Device

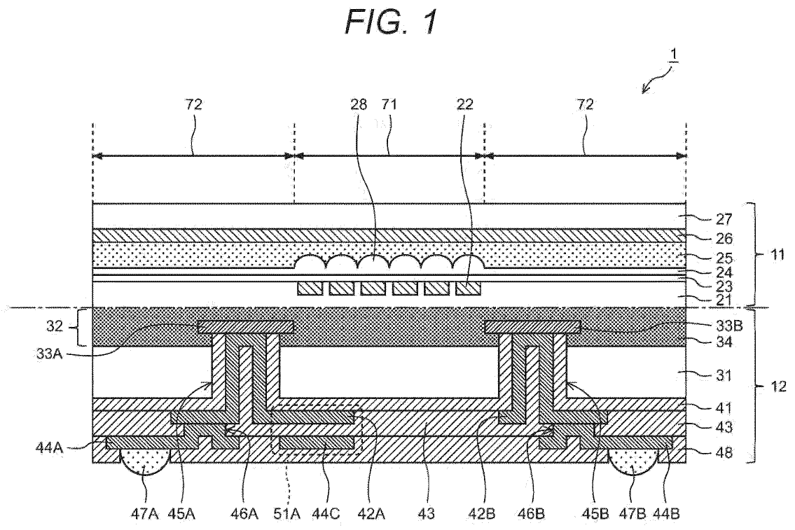

FIG. 1 is an overall configuration cross-sectional view of a first embodiment of a solid-state imaging device to which the present technology is applied.

A solid-state imaging device 1 illustrated in FIG. 1 is a chip size package type CMOS solid-state imaging device configured by stacking a sensor substrate 11 and a logic substrate 12. The sensor substrate 11 and the logic substrate 12 are joined by a surface indicated by a one-dot chain line.

The sensor substrate 11 includes, for example, a semiconductor substrate 21 (hereinafter, referred to as a silicon substrate 21) constituted by silicon (Si), and photodiodes 22 as photoelectric conversion elements are formed on the silicon substrate 21 in units of pixels. In the drawing, a planarization film 23, a lens layer 24, an interlayer insulating film 25, a bonding resin 26, and a light-transmissive substrate 27 are stacked on one surface of a silicon substrate 21 that is an upper side.

In the lens layer 24 on upper sides of the photodiodes 22 formed in units of pixels, on-chip lenses 28 are formed in units of pixels. The on-chip lenses 28 are formed on an upper side of the planarization film 23 formed on an upper surface of the silicon substrate 21, and upper sides of the on-chip lenses 28 are formed flat by the interlayer insulating film 25. The interlayer insulating film 25 is formed by a material having a refractive index lower than that of the material of the on-chip lenses 28, and a refractive index difference is provided between the on-chip lenses 28 and the interlayer insulating film 25 thereon, thereby increasing the light collecting power of the on-chip lenses 28.

The light-transmissive substrate 27 is bonded to an upper side of the interlayer insulating film 25 with the bonding resin 26. The light-transmissive substrate 27 is, for example, a substrate having a light-transmissive property such as a glass substrate or the like. The light-transmissive substrate 27 also has a function of protecting the on-chip lenses 28.

The surface on which the on-chip lenses 28 and the like are formed is a front surface of the sensor substrate 11 and is a light incident surface on which incident light is to be incident. The logic substrate 12 is bonded to a back surface side of the sensor substrate 11.

The logic substrate 12 includes, for example, a semiconductor substrate 31 (hereinafter, referred to as a silicon substrate 31) constituted by silicon (Si), and a multilayer wiring layer 32 is formed on a first surface side (sensor substrate 11 side) of the silicon substrate 31, which is an upper side in the drawing. The multilayer wiring layer 32 includes a plurality of metal wiring layers (not illustrated) including at least an internal electrode 33 and an interlayer insulating film 34 therebetween. In the example of FIG. 1, two internal electrodes 33A and 33B are formed. The internal electrodes 33A and 33B respectively serve as receiving portions in the logic substrate 12 corresponding to solder bumps 47A and 47B as external connection terminals formed on a back surface of the logic substrate 12.

Two interlayer insulating films and two rewirings are formed on a second surface side opposite to the first surface side of the silicon substrate 31 on which the multilayer wiring layer 32 is formed. Specifically, a first interlayer insulating film 41, a first rewiring 42, a second interlayer insulating film 43, and a second rewiring 44 are formed in this order from a side closer to the silicon substrate 31. The first surface side of the silicon substrate 31 on which the multilayer wiring layer 32 is formed corresponds to a front surface side of the silicon substrate 31, and the second surface side on which the two interlayer insulating films and the rewirings are formed corresponds to a back surface side of the silicon substrate 31.

In FIG. 1, reference numerals of the first rewiring 42, the second rewiring 44, and the solder bumps 47 are distinguished corresponding to two internal electrodes 33A and 33B. Specifically, the first rewiring 42, the second rewiring 44, and the solder bump 47 connected to the internal electrode 33A are a first rewiring 42A, a second rewiring 44A, and a solder bump 47A, and the first rewiring 42, the second rewiring 44, and the solder bump 47 connected to the internal electrode 33B are a first rewiring 42B, a second rewiring 44B, and a solder bump 47B.

The solid-state imaging device 1 is divided into a pixel region 71 at the center of a rectangular chip region and a peripheral region 72 on the outer periphery thereof in plan view. In the pixel region 71, pixels having photodiodes 22 are arranged in a matrix, and in the peripheral region 72, for example, a drive control unit (not illustrated) that drives each pixel and the like are arranged. In the example of FIG. 1, the solder bumps 47 that are external connection terminals are arranged in the peripheral region 72, but the solder bumps 47 may be arranged in the entire region of the back surface of the logic substrate 12.

In the silicon substrate 31, a through hole 45 that is a through-silicon-via (TSV) is formed corresponding to the internal electrode 33 formed in the multilayer wiring layer 32 on the front surface side. More specifically, a through hole 45A is formed at a position corresponding to the internal electrode 33A, and a through hole 45B is formed at a position corresponding to the internal electrode 33B.

The first interlayer insulating film 41 is formed on a side wall (inner peripheral surface) of the through hole 45A formed at a position corresponding to the internal electrode 33A and the back surface side of the silicon substrate 31. The first interlayer insulating film 41 electrically isolates the first rewiring 42A from the silicon substrate 31. The first rewiring 42A is formed on the back surface side of the silicon substrate 31 and the side wall (inner peripheral surface) of the through hole 45A, and is connected to the internal electrode 33A formed in the multilayer wiring layer 32 on the front surface side. Furthermore, the first rewiring 42A is also connected to the second rewiring 44A embedded in a through hole 46A penetrating the second interlayer insulating film 43. The solder bump 47A is formed on a part of an upper surface (a lower surface in FIG. 1) of the second rewiring 44A.

Therefore, the first rewiring 42A is connected to the internal electrode 33A formed on the front surface side of the silicon substrate 31, and is also connected to the solder bump 47A via the second rewiring 44A. For the first rewiring 42B, the second rewiring 44B, a through hole 46B, and the solder bump 47B connected to the internal electrode 33B, similarly, the first rewiring 42B is connected to the internal electrode 33B formed on the front surface side of the silicon substrate 31, and is also connected to the solder bump 47B via the second rewiring 44B. A region other than the solder bumps 47A and 47B on a back surface side of the logic substrate 12 is covered with a protective film 48. As a material of the protective film 48, for example, a solder resist which is an organic material is used.

The internal electrodes 33A and 33B, the first rewirings 42A and 42B, and the second rewirings 44A and 44B can be formed by, for example, copper (Cu), tungsten (W), titanium (Ti), tantalum (Ta), a titanium tungsten alloy (TiW), polysilicon, or the like. The first interlayer insulating film 41 and the second interlayer insulating film 43 are formed by, for example, a SiO2 film, a low-k film (low dielectric constant insulating film), a SiOC film, or the like.

The solder bumps 47A and 47B are external connection terminals for inputting and outputting a power supply voltage, a ground (GND), or various signals (for example, pixel signals and control signals) to and from an external module board.

The solder bump 47A on the left side in FIG. 1 is, for example, an external connection terminal that receives supply of a power supply voltage from the external module board. Since the internal electrode 33A is connected to the solder bump 47A via the first rewiring 42A and the second rewiring 44A, a power supply voltage supplied to the solder bump 47A is drawn into the internal electrode 33A on the multilayer wiring layer 32 side.

On the other hand, the right solder bump 47B is, for example, an external connection terminal that outputs a signal to the external module board. Since the internal electrode 33B is connected to the solder bump 47B via the first rewiring 42B and the second rewiring 44B, a signal generated in the solid-state imaging device 1 is output from the solder bump 47B to the outside.

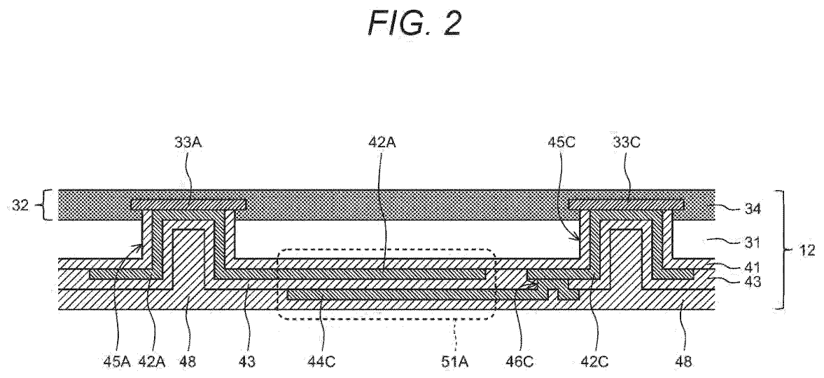

When the left solder bump 47A side to which the power supply voltage is supplied is compared with the solder bump 47B side that outputs a signal, a capacitor 51A is formed on the solder bump 47A side. The capacitor 51A includes the first rewiring 42A, another second rewiring 44C formed in the same layer as the second rewiring 44A, and the second interlayer insulating film 43 therebetween. That is, the capacitor 51A is a parallel plate capacitor (MIM capacitor) using the first rewiring 42A and the second rewiring 44C formed on the back surface side of the logic substrate 12 (silicon substrate 31) as capacitance electrodes. The second rewiring 44C is a second rewiring connected to another internal electrode 33C (FIG. 2) different from the internal electrodes 33A and 33B, which will be described later in detail with reference to FIG. 2.

The first rewiring 42B and the second rewiring 44B, which are rewirings connected to the solder bump 47B as a signal output terminal, are electrically separated from the silicon substrate 31 by the first interlayer insulating film 41, but are affected, due to parasitic capacitance therebetween, by signal delay (increase in signal rise time and signal fall time) and noise of the silicon substrate 31, and jitter may occur.

As one method of suppressing the influence of signal delay and jitter, there is a method of connecting a capacitive element to the internal electrode 33A connected to the power supply voltage to stabilize the potential. The solid-state imaging device 1 has a configuration in which the planar capacitor 51A is formed by the first rewiring 42A connected to the internal electrode 33A connected to the power supply voltage, the second rewiring 44C formed in the same layer as the second rewiring 44A, and the second interlayer insulating film 43 therebetween, thereby improving signal delay and jitter.

The capacitor 51A is a capacitor 51 included in the solid-state imaging device 1 of the first embodiment, and is a first configuration example of a capacitor 51 using the first rewiring 42 connected to the internal electrode 33A connected to the power supply voltage as one of capacitance electrodes. Similarly, capacitors 51 included in the solid-state imaging devices 1 of the second to tenth embodiments will be referred to as second to tenth configuration examples of the capacitors 51, and will be described with different reference numerals such as capacitors 51B to 51K.

### 2. Detailed Configuration of First Configuration Example of Capacitor

FIG. 2 is a cross-sectional view illustrating a detailed structure of the capacitor 51A according to a first configuration example, which is the capacitor 51 included in the solid-state imaging device 1 of the first embodiment. FIG. 2 is a cross-sectional view of only the logic substrate 12, and corresponds to a cross-sectional view of the capacitor 51A of FIG. 1 as viewed from a direction different from that of FIG. 1.

The capacitor 51A is configured so that the first rewiring 42A and the second rewiring 44C are arranged to face each other with the second interlayer insulating film 43 interposed therebetween. The material of the second interlayer insulating film 43 can be, for example, a silicon oxide film, and the film thickness of the second interlayer insulating film 43 is, for example, about 5 μm to 10 μm. The first rewiring 42A constituting one of a pair of capacitance electrodes is connected to the internal electrode 33A via the through hole 45A opened in the silicon substrate 31. The second rewiring 44A and the solder bump 47A connected to the first rewiring 42A in FIG. 1 are not illustrated because the second rewiring 44A and the solder bump 47A are in a region invisible from a cross-sectional direction in FIG. 2.

The other second rewiring 44C constituting the pair of capacitance electrodes is connected to a first rewiring 42C via a through hole 46C penetrating the second interlayer insulating film 43, and the first rewiring 42C is connected to the internal electrode 33C via a through hole 45C opened in the silicon substrate 31. Therefore, the second rewiring 44C constituting the other of the capacitance electrodes of the capacitor 51A is a second rewiring of the internal electrode 33C different from the internal electrode 33A.

As described above, the power supply voltage is supplied to the first rewiring 42A constituting one capacitance electrode of the capacitor 51A via the solder bump 47A and the second rewiring 44A in FIG. 1. On the other hand, the second rewiring 44C constituting the other capacitance electrode of the capacitor 51A is connected to the ground, and the capacitor 51A functions as a capacitive element for suppressing fluctuation of the power supply voltage.

As the capacitive element for suppressing the fluctuation of the power supply voltage, for example, a method of forming the capacitive element in the multilayer wiring layer 32 of the logic substrate 12 is considered. However, the logic substrate 12 has a large area restriction, and mounting a large-scale capacitive element has a large influence on high integration of a circuit, and thus, it is easily assumed that there is a problem in future chip size shrink or the like. Therefore, it is desirable to reduce the installation area of the capacitive element as much as possible.

Since the capacitor 51A described above is formed not in the multilayer wiring layer 32 but on the external connection terminal side, it does not affect the high integration of the circuit formed in the multilayer wiring layer 32. By replacing the capacitive element formed in the multilayer wiring layer 32 with the capacitor 51A, the circuit area in the multilayer wiring layer 32 can be effectively utilized. Furthermore, in a case where the capacitor 51A is added to the capacitive element formed in the multilayer wiring layer 32, a higher capacitance can be achieved.

### 3. Manufacturing Method of Capacitor According to First Configuration Example

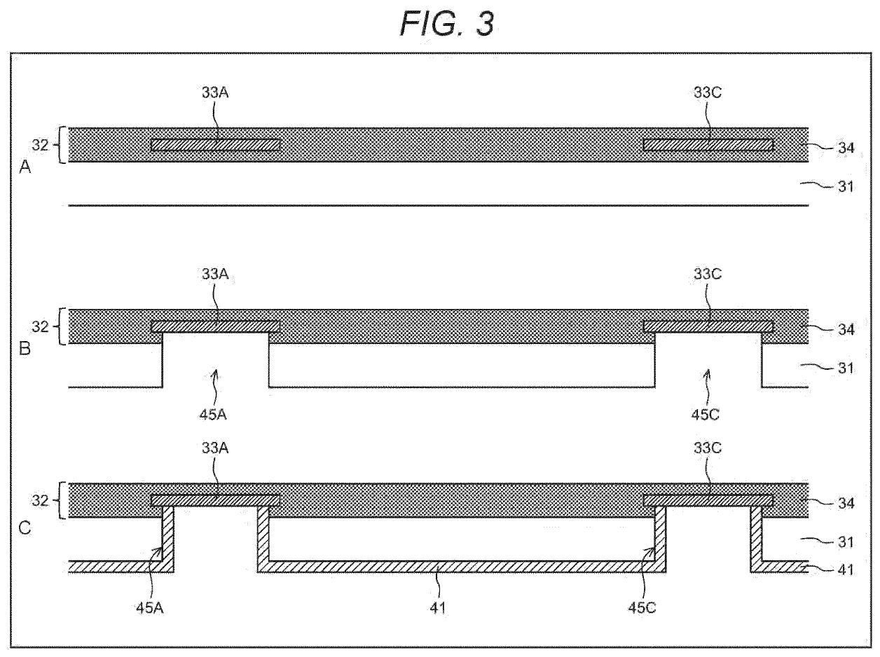

Next, a manufacturing method of the solid-state imaging device 1 including the capacitor 51A illustrated in FIG. 2 will be described with reference to FIGS. 3 to 5. Note that although the cross-sectional views illustrated in FIGS. 3 to 5 are illustrated in the same direction as FIGS. 1 and 2, that is, in a direction in which the light incident surface of the solid-state imaging device 1 is the upper surface, in the manufacturing step, since the surface of the silicon substrate 31 on the side on which the solder bump 47, which is an external connection terminal, is formed is processed as the upper surface, the lower surface of the substrate or film in the drawings will also be referred to as the upper surface.

First, as illustrated in A of FIG. 3, the multilayer wiring layer 32 is formed on the first surface of the silicon substrate 31 on the sensor substrate 11 side. The multilayer wiring layer 32 includes a plurality of metal wiring layers (not illustrated) including at least two internal electrodes 33A and 33C and the interlayer insulating film 34 therebetween.

Next, as illustrated in B of FIG. 3, the through holes 45A and 45C penetrating the silicon substrate 31 are formed at positions corresponding to the internal electrodes 33A and 33C, respectively. The through holes 45A and 45C are formed until reaching the internal electrodes 33A and 33C, respectively, and a part of upper surfaces of the internal electrodes 33A and 33C is exposed.

Next, as illustrated in C of FIG. 3, the first interlayer insulating film 41 is formed on the upper surface of the silicon substrate 31 and the side walls of the through holes 45A and 45C. The first interlayer insulating film 41 can be formed, for example, by forming the first interlayer insulating film 41 on the entire upper surface of the silicon substrate 31 and bottom surfaces and side walls of the through holes 45A and 45C and then etching back to remove only bottom surfaces of the through holes 45A and 45C.

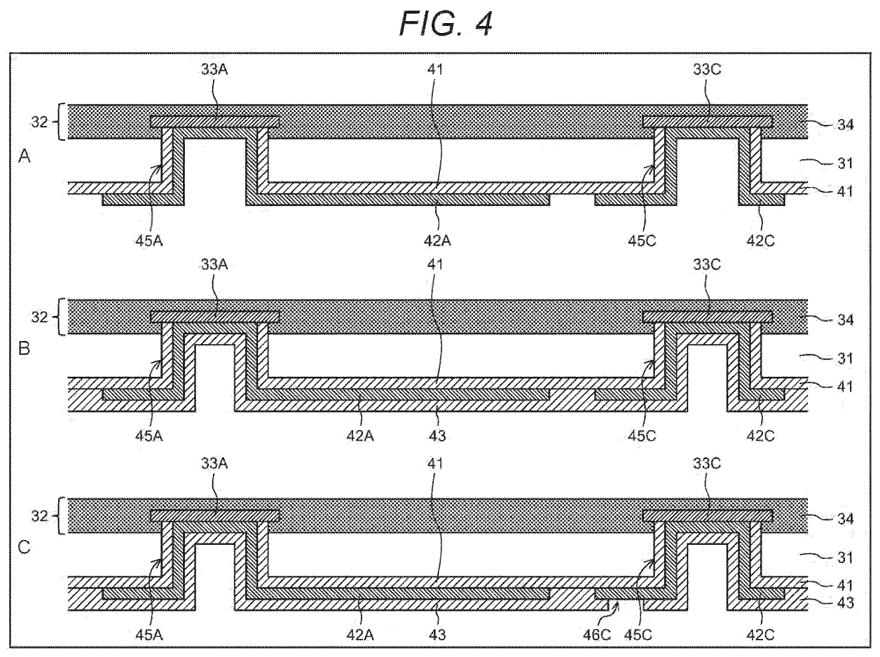

Next, as illustrated in A of FIG. 4, the first rewiring 42A connected to the internal electrode 33A and the first rewiring 42C connected to the internal electrode 33C are simultaneously formed. The material of the first rewirings 42A and 42C is, for example, copper. In this case, for example, the first rewirings 42A and 42C can be formed by forming a resist material provided with an opening pattern in a predetermined region, and forming a copper film by an electrolytic plating method using the formed resist material as a mask. The film thickness of the first rewirings 42A and 42C is, for example, about several μm to several tens of μm.

Next, as illustrated in B of FIG. 4, the second interlayer insulating film 43 is formed on upper surfaces of the first rewirings 42A and 42C and an upper surface of the first interlayer insulating film 41 on which the first rewirings 42A and 42C are not formed. As a material of the second interlayer insulating film 43, an organic material such as a solder resist, an inorganic material such as a silicon oxide film (SiO2 film), or the like can be used. The solder resist can be formed using a coating apparatus, and the silicon oxide film can be formed using, for example, vapor phase growth (chemical vapor deposition, hereinafter referred to as CVD), atomic layer deposition (atomic layer deposition, hereinafter referred to as ALD), or the like. The second interlayer insulating film 43 is formed so as to be deposited inside the through holes 45A and 45C with a uniform film thickness. The film thickness of the second interlayer insulating film 43 can be several nm to several tens of μm.

Next, as illustrated in C of FIG. 4, a through hole 46C penetrating the second interlayer insulating film 43 is formed in a predetermined region on the first rewiring 42C. In a case where the second interlayer insulating film 43 is a solder resist of a photosensitive material or the like, the through hole 46C can be formed by a lithography method. Furthermore, for example, in a case where the second interlayer insulating film 43 is a silicon oxide film, the through hole 46C can be formed by forming a resist pattern by a lithography method, and dry-etching the second interlayer insulating film 43 using the resist pattern as a mask. Note that, although not illustrated in C of FIG. 4, the through hole 46A (FIG. 1) is also formed on the first rewiring 42A on the internal electrode 33A side simultaneously with the through hole 46C.

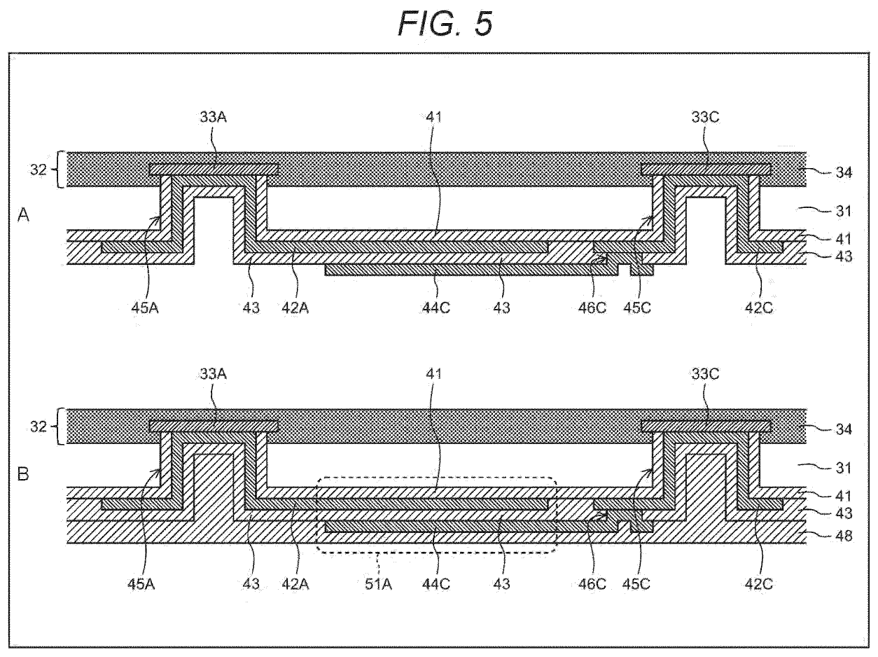

Next, as illustrated in A of FIG. 5, the second rewiring 44C is formed in a predetermined region on the second interlayer insulating film 43 and inside the through hole 46C. The material of the second rewiring 44C can also be copper, similarly to the first rewiring 42A. The method for forming the second rewiring 44C is also similar to the method for forming the first rewiring 42A. The film thickness of the second rewiring 44C is, for example, about several μm to several tens of μm. Note that, although not illustrated in A of FIG. 5, the second rewiring 44A on the internal electrode 33A side is also formed simultaneously with the second rewiring 44C.

Next, as illustrated in B of FIG. 5, the protective film 48 is formed on an upper surface of the second rewiring 44C and an upper surface of the second interlayer insulating film 43 on which the second rewiring 44C is not formed. As a material of the protective film 48, for example, a solder resist which is an organic material is used. As the solder resist, it is desirable to use a photosensitive solder resist in order to provide an insulating film opening for arranging the solder bump 47 in the next step.

Next, although not illustrated, the insulating film opening is formed by opening the protective film 48 in the region where the solder bumps 47A and 47B are arranged, and the solder bumps 47A and 47B are formed on the exposed second rewirings 44A and 44B, respectively.

Through the above steps, the logic substrate 12 including the capacitor 51A according to the first configuration example illustrated in FIG. 2 is manufactured. The logic substrate 12 is bonded to the sensor substrate 11 at an appropriate timing to complete the solid-state imaging device 1.

In the manufacturing method of the solid-state imaging device 1 including the capacitor 51A according to the first configuration example, the first rewiring 42A and the second rewiring 44C are a pair of capacitance electrodes, and the second interlayer insulating film 43 formed between the rewirings is a capacitance film, so that the formation of the capacitor 51A and the formation of wiring to the solder bump 47 which is an external connection terminal can be performed simultaneously without adding a dedicated process for capacitor formation.

### 4. Second Configuration Example of Capacitor

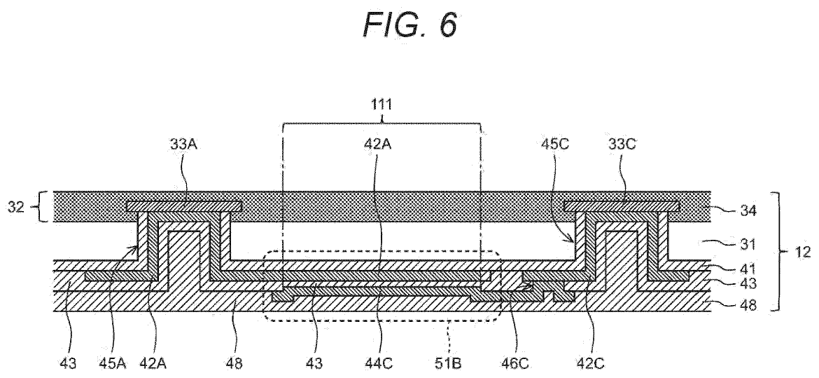

FIG. 6 is a cross-sectional view illustrating a detailed structure of a capacitor 51B according to a second configuration example, which is the capacitor 51 included in the solid-state imaging device 1 of the second embodiment.

In the second configuration example to the ninth configuration example of the capacitor 51 described below, only a cross-sectional view corresponding to FIG. 2 of the first configuration example is illustrated, and a cross-sectional view corresponding to FIG. 1 is omitted. The electrical connection between the solder bump 47 and the internal electrode 33 is similar to that in the first configuration example illustrated in FIG. 1. In the drawings of FIG. 6 and subsequent drawings, the same reference numerals are given to parts common to those of the solid-state imaging device 1 of the first embodiment, and the description of the parts will be omitted as appropriate, and different portions will be focused and described.

The capacitor 51B according to the second configuration example illustrated in FIG. 6 is common to the capacitor 51A according to the first configuration example in that the first rewiring 42A and the second rewiring 44C are a pair of capacitance electrodes, and the second interlayer insulating film 43 formed between these rewirings is a capacitance film.

On the other hand, the capacitor 51B according to the second configuration example is different from the first configuration example in which the film thickness of the second interlayer insulating film 43 is the same as the film thickness of the second interlayer insulating film 43 in the other region in that the capacitor includes an interlayer thin film portion 111 in which the film thickness of the second interlayer insulating film 43 is formed thin as compared with the film thickness of the second interlayer insulating film 43 in the other region. The film thickness of the thin second interlayer insulating film 43 of the capacitor 51B is equal to or less than 500 nm, and is preferably about 10 nm to 200 nm.

With the capacitor 51B of the second configuration example configured as described above, since the film thickness of the second interlayer insulating film 43 which is a capacitance film is formed to have a small film thickness, it is possible to achieve high electrostatic capacitance as compared with the first configuration example. The parasitic capacitance between the first rewiring 42A and the second rewiring 44C in the region other than the capacitor 51B does not change from the first configuration example. Therefore, it is possible to increase the capacitance of the capacitive element for stabilizing the power supply voltage while suppressing the signal delay due to the parasitic capacitance of the rewiring.

### 5. First Manufacturing Method of Capacitor According to Second Configuration Example

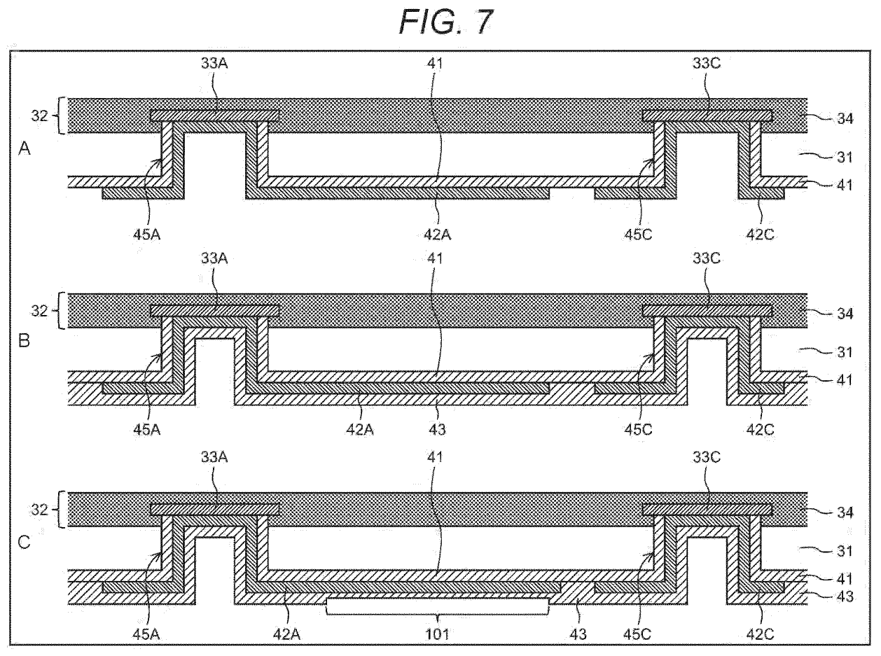

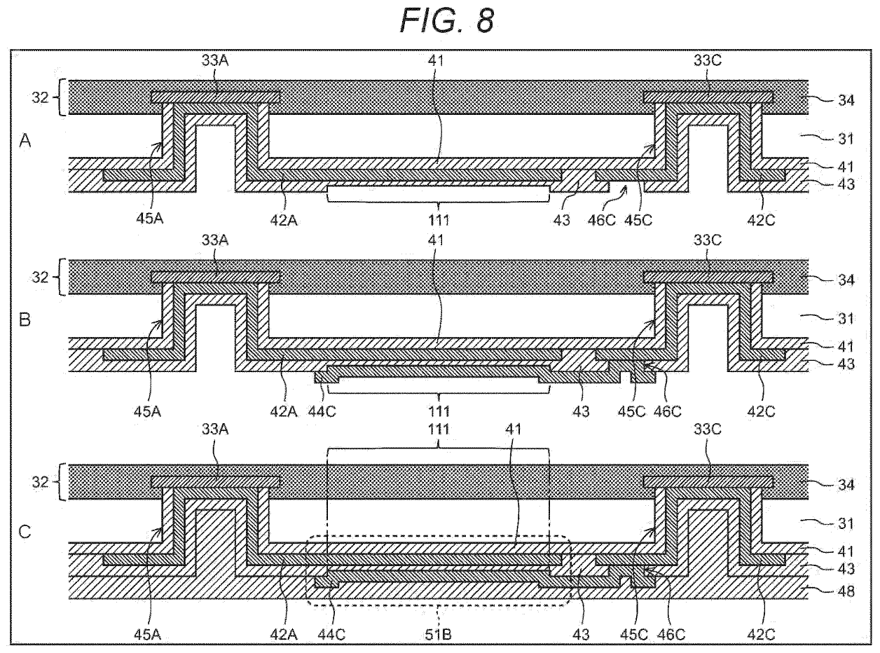

Next, a first manufacturing method of the solid-state imaging device 1 including the capacitor 51B according to the second configuration example illustrated in FIG. 6 will be described with reference to FIGS. 7 and 8.

A of FIG. 7 is the same as A of FIG. 4 after the first rewirings 42A and 42C are formed in the capacitor 51A of the above-described first configuration example. The steps until the first rewirings 42A and 42C in A of FIG. 7 are formed are similar to the steps described in A of FIG. 3 to A of FIG. 4 of the first configuration example.

Next, as illustrated in B of FIG. 7, the second interlayer insulating film 43 is formed on the upper surfaces of the first rewirings 42A and 42C and the upper surface of the first interlayer insulating film 41 on which the first rewirings 42A and 42C are not formed. As a material of the second interlayer insulating film 43, an organic material such as a solder resist, an inorganic material such as a silicon oxide film, or the like can be used. The solder resist can be formed using a coating apparatus, and the silicon oxide film can be formed using, for example, CVD, ALD, or the like. The film thickness of the second interlayer insulating film 43 can be several nm to several tens of μm.

Next, as illustrated in C of FIG. 7, the interlayer thin film portion 111 is formed by thinning the second interlayer insulating film 43 to be a formation region of the capacitor 51B. For example, the interlayer thin film portion 111 can be formed by forming a resist pattern on the second interlayer insulating film 43 other than the region to be the interlayer thin film portion 111 and performing dry etching using the resist pattern as a mask.

Next, as illustrated in A of FIG. 8, the through hole 46C is formed in a predetermined region on the first rewiring 42C. This step is similar to the step in C of FIG. 4 in the first configuration example.

Next, as illustrated in B of FIG. 8, the second rewiring 44C is formed in a predetermined region on the second interlayer insulating film 43 and inside the through hole 46C. This step is similar to the step in A of FIG. 5 in the first configuration example, but in the second configuration example, since the interlayer thin film portion 111 is formed, a step corresponding to the interlayer thin film portion 111 is formed on the second rewiring 44C.

Next, as illustrated in C of FIG. 8, the protective film 48 is formed on the upper surface of the second rewiring 44C and the upper surface of the second interlayer insulating film 43 on which the second rewiring 44C is not formed. This step is similar to the step in B of FIG. 5 in the first configuration example.

Steps subsequent to C in FIG. 8 are similar to those in the first configuration example. That is, an insulating film opening is formed in a predetermined region of the uppermost protective film 48, and the solder bumps 47A and 47B are formed on the exposed second rewirings 44A and 44B, respectively.

Through the above steps, the logic substrate 12 including the capacitor 51B according to the second configuration example illustrated in FIG. 6 is manufactured. The logic substrate 12 is bonded to the sensor substrate 11 at an appropriate timing to complete the solid-state imaging device 1.

According to the first manufacturing method of the solid-state imaging device 1 including the capacitor 51B according to the second configuration example, the second interlayer insulating film 43 as a capacitance film can be formed to have a small film thickness, and the capacitor 51B having high electrostatic capacitance can be formed.

### 6. Second Manufacturing Method of Capacitor According to Second Configuration Example

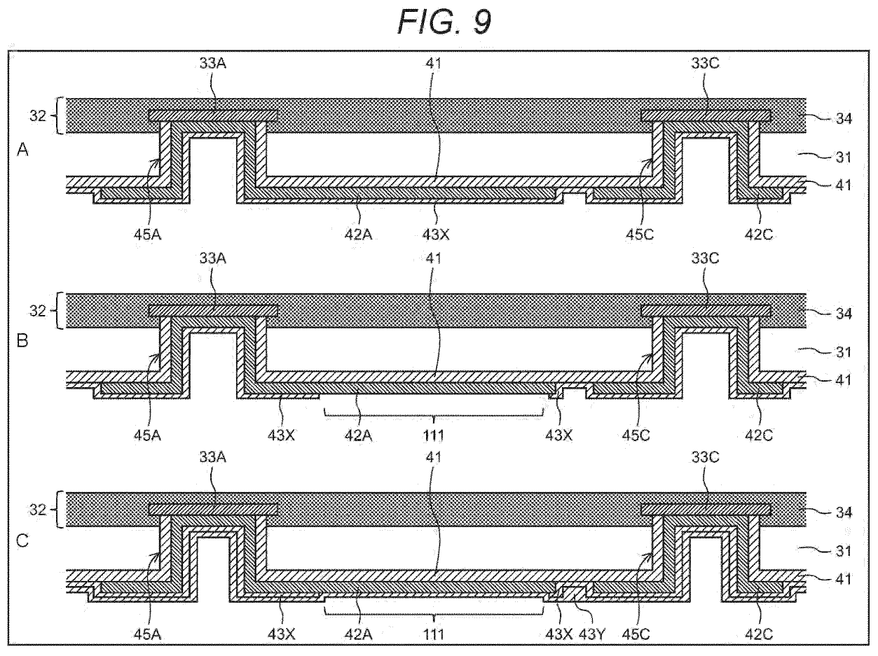

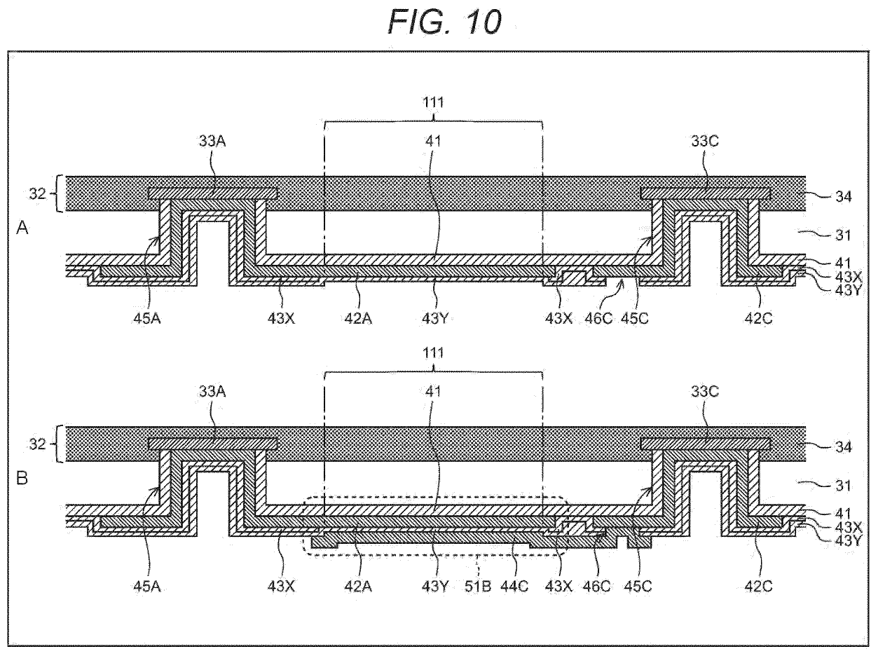

Next, a second manufacturing method of the solid-state imaging device 1 including the capacitor 51B according to the second configuration example illustrated in FIG. 6 will be described with reference to FIGS. 9 and 10.

A of FIG. 9 illustrates a state in which a second interlayer insulating film 43X is formed on the upper surfaces of the first rewirings 42A and 42C and the upper surface of the first interlayer insulating film 41 on which the first rewirings 42A and 42C are not formed, similarly to B of FIG. 7 of the first manufacturing method. The difference from B of FIG. 7 is that the film thickness of the second interlayer insulating film 43X is formed to be thinner than that of the second interlayer insulating film 43 in B of FIG. 7. The steps up to the formation of the second interlayer insulating film 43X are similar to the steps described in A of FIG. 3 to B of FIG. 4 of the first configuration example.

Next, as illustrated in B of FIG. 9, the second interlayer insulating film 43X in the region to be the interlayer thin film portion 111 of the capacitor 51B is removed. For example, the second interlayer insulating film 43X in the region to be the interlayer thin film portion 111 is removed by forming a resist pattern on the second interlayer insulating film 43 other than the region to be the interlayer thin film portion 111 by a lithography method, and performing dry etching using the resist pattern as a mask.

Next, as illustrated in C of FIG. 9, the second interlayer insulating film 43Y is formed on the entire surface including the first rewiring 42A and the upper surface of the second interlayer insulating film 43X in the region to be the interlayer thin film portion 111. In the interlayer thin film portion 111, only the second interlayer insulating film 43Y is formed, and a region other than the interlayer thin film portion 111 is a stacked film of the second interlayer insulating films 43X and 43Y. The stacked film of the second interlayer insulating films 43X and 43Y corresponds to the second interlayer insulating film 43 having a large film thickness in the second configuration example illustrated in FIG. 6. The second interlayer insulating films 43X and 43Y may be formed by the same material or different materials.

Next, as illustrated in A of FIG. 10, the through hole 46C penetrating the second interlayer insulating films 43X and 43Y is formed in a predetermined region on the first rewiring 42C. This step is similar to the step in C of FIG. 4 in the first configuration example.

Next, as illustrated in B of FIG. 10, the second rewiring 44C is formed in a predetermined region on the second interlayer insulating film 43Y including the interlayer thin film portion 111 and inside the through hole 46C. This step is similar to the step in A of FIG. 5 in the first configuration example, but in the second configuration example, since the interlayer thin film portion 111 is formed, a step corresponding to the interlayer thin film portion 111 is formed on the second rewiring 44C.

Steps subsequent to B in FIG. 10 are similar to those in the first configuration example. That is, after the protective film 48 is formed on the uppermost layer, an insulating film opening is formed in a predetermined region of the protective film 48, and the solder bumps 47A and 47B are formed on the exposed second rewirings 44A and 44B, respectively.

Through the above steps, the logic substrate 12 including the capacitor 51B according to the second configuration example illustrated in FIG. 6 is manufactured. The logic substrate 12 is bonded to the sensor substrate 11 at an appropriate timing to complete the solid-state imaging device 1.

According to the second manufacturing method of the solid-state imaging device 1 including the capacitor 51B according to the second configuration example, the second interlayer insulating film 43 which is a capacitance film can be formed to have a small film thickness, and the capacitor 51B having high electrostatic capacitance can be formed. As compared with the first manufacturing method described above, since the film thickness of the second interlayer insulating film 43 of the interlayer thin film portion 111 is determined by the growth film thickness of the second interlayer insulating film 43Y, controllability of the film thickness is high as compared with the case of thinning by etching processing or the like, and it is possible to suppress variation in capacitance of the capacitor 51B.

<7. Third manufacturing method of capacitor according to second configuration example>

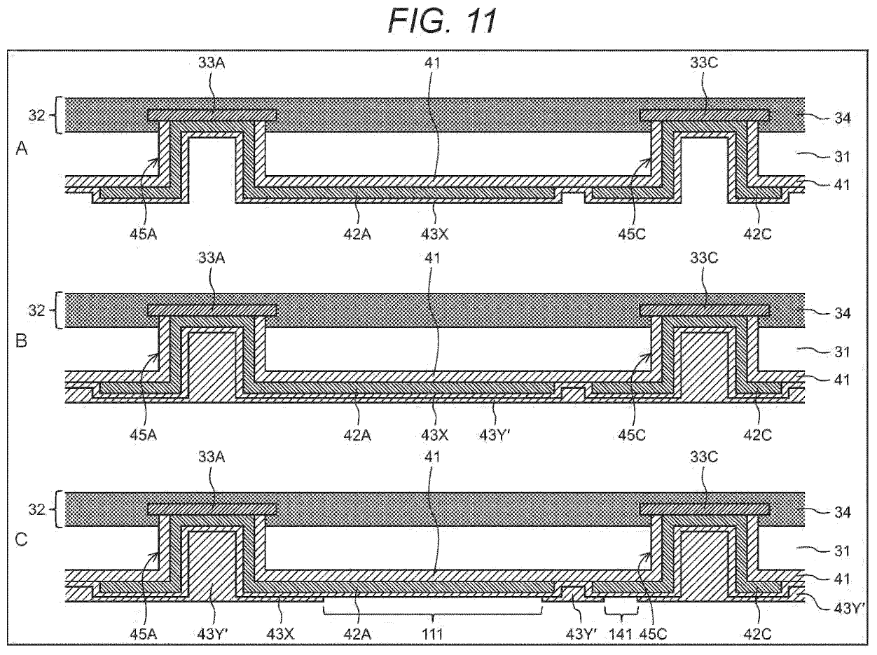

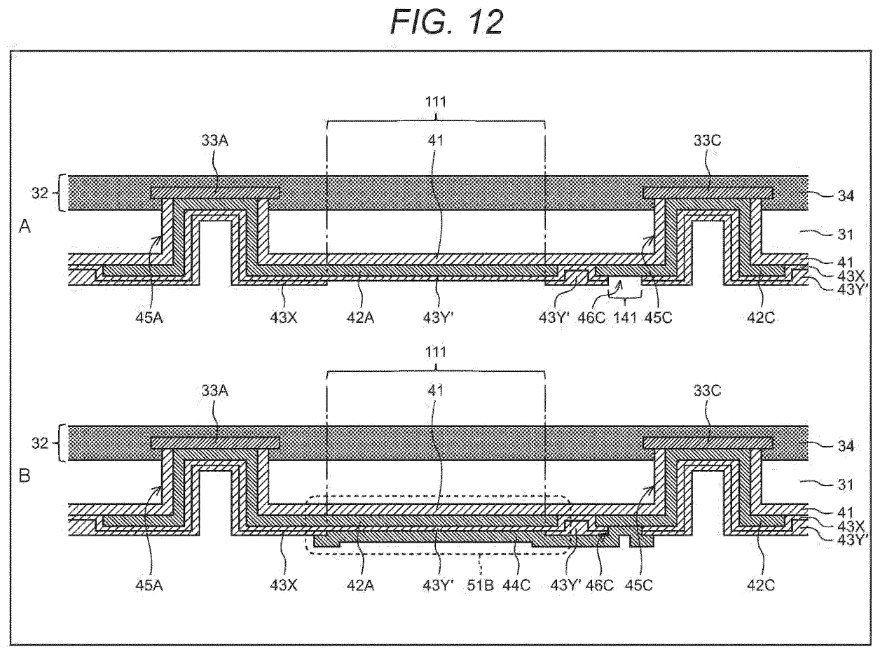

Next, a third manufacturing method of the solid-state imaging device 1 including the capacitor 51B according to the second configuration example illustrated in FIG. 6 will be described with reference to FIGS. 11 and 12.

A of FIG. 11 illustrates a state similar to A of FIG. 9 of the second manufacturing method, that is, a state in which the second interlayer insulating film 43X is formed on the upper surfaces of the first rewirings 42A and 42C and the upper surface of the first interlayer insulating film 41 on which the first rewirings 42A and 42C are not formed. The film thickness of the second interlayer insulating film 43X is formed to be thinner than the second interlayer insulating film 43 in B of FIG. 7. The steps up to the formation of the second interlayer insulating film 43X are similar to the steps described in A of FIG. 3 to B of FIG. 4 of the first configuration example.

Next, as illustrated in B of FIG. 11, a second interlayer insulating film 43Y′ is formed on the entire surface of the second interlayer insulating film 43X. Thus, a stacked film of the second interlayer insulating films 43X and 43Y′ is formed. In the second manufacturing method described above, the second interlayer insulating films 43X and 43Y may be formed by the same material or different materials, but a material having an etching rate different from that of the second interlayer insulating film 43X is used for the second interlayer insulating film 43Y′ formed by the third manufacturing method. For example, an inorganic material film such as a silicon oxide film is used for the second interlayer insulating film 43X, and an organic material film such as a photosensitive solder resist is used for the second interlayer insulating film 43Y′.

Next, as illustrated in C of FIG. 11, the second interlayer insulating film 43Y′ in the region to be the interlayer thin film portion 111 of the capacitor 51B and the second interlayer insulating film 43Y′ in a region 141 (hereinafter, referred to as a through hole region 141) to be the through hole 46C are removed. In a case where the second interlayer insulating film 43Y′ is an organic material film such as a photosensitive solder resist, the second interlayer insulating film 43Y′ is removed by a lithography method. Since the second interlayer insulating films 43X and 43Y′ are materials having different etching rates, only the second interlayer insulating film 43Y′ can be removed while leaving the second interlayer insulating film 43X.

Next, as illustrated in A of FIG. 12, the second interlayer insulating film 43X in the through hole region 141 is removed by etching, and the through hole 46C penetrating the second interlayer insulating films 43X and 43Y′ is formed. The stacked film of the second interlayer insulating films 43X and 43Y′ corresponds to the second interlayer insulating film 43 having a large film thickness in the second configuration example illustrated in FIG. 6.

Next, as illustrated in B of FIG. 12, the second rewiring 44C is formed on the second interlayer insulating film 43Y including the interlayer thin film portion 111 and inside the through hole 46C. This step is similar to the step in A of FIG. 5 in the first configuration example, but in the second configuration example, since the interlayer thin film portion 111 is formed, a step corresponding to the interlayer thin film portion 111 is formed on the second rewiring 44C.

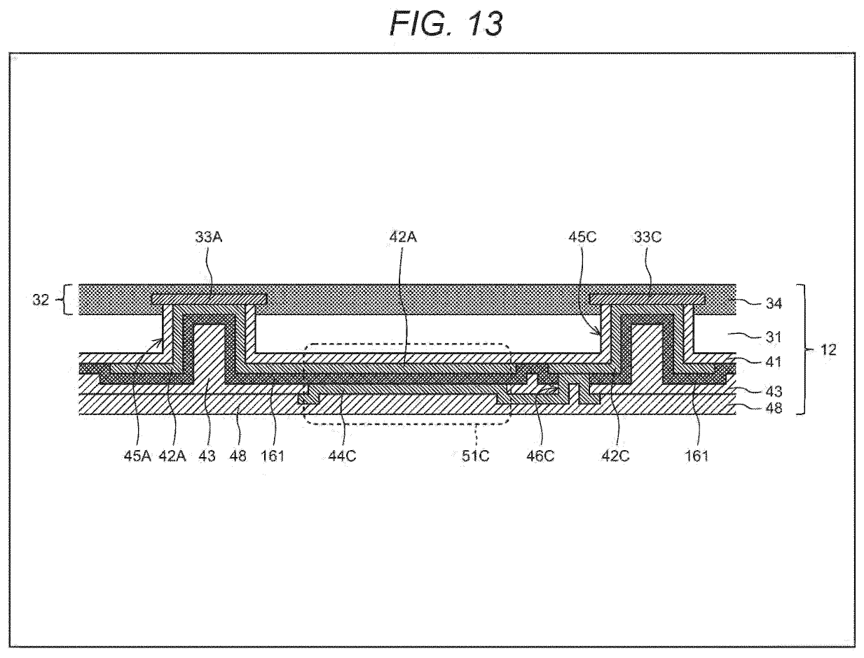

Steps subsequent to B in FIG. 13 are similar to those in the first configuration example.

That is, after the protective film 48 is formed on the uppermost layer, an insulating film opening is formed in a predetermined region of the protective film 48, and the solder bumps 47A and 47B are formed on the exposed second rewirings 44A and 44B, respectively.

Through the above steps, the logic substrate 12 including the capacitor 51B according to the second configuration example illustrated in FIG. 6 is manufactured. The logic substrate 12 is bonded to the sensor substrate 11 at an appropriate timing to complete the solid-state imaging device 1.

According to the third manufacturing method of the solid-state imaging device 1 including the capacitor 51B according to the second configuration example, the second interlayer insulating film 43 as a capacitance film can be formed to have a small film thickness, and the capacitor 51B having high electrostatic capacitance can be formed. As compared with the first manufacturing method described above, since the film thickness of the second interlayer insulating film 43 of the interlayer thin film portion 111 is determined by the growth film thickness of the second interlayer insulating film 43Y, controllability of the film thickness is high as compared with the case of thinning by etching processing or the like, and it is possible to suppress variation in capacitance of the capacitor 51B.

### 8. Third Configuration Example of Capacitor

FIG. 13 is a cross-sectional view illustrating a detailed structure of a capacitor 51C according to a third configuration example, which is the capacitor 51 included in the solid-state imaging device 1 of the third embodiment.

The capacitor 51C according to the third configuration example illustrated in FIG. 13 is different from the first and second configuration examples described above in that the space between the first rewiring 42A and the second rewiring 44C, which are a pair of capacitance electrodes, is not the second interlayer insulating film 43 but a high dielectric film 161. The high dielectric film 161 can be a tantalum oxide film, an aluminum oxide film, a hafnium oxide film, a titanium oxide film, a zirconium oxide film, a niobium oxide film, a silicon nitride film, or the like by using, for example, CVD, ALD, sputtering, or the like, or may be a stacked film of two or more thereof. Moreover, a titanium nitride film may be formed on an upper layer and a lower layer of a single layer film or a stacked film of these dielectric films. The film thickness of the high dielectric film 161 can be several nm to several hundred nm. For example, in a case where tantalum oxide (Ta2O5) is used as the material of the high dielectric film 161 and the film thickness is 100 nm, the relative permittivity εr is about 20 to 25 (εr=20-25).

The high dielectric film 161 is formed not only in the region of the capacitor 51C but also on the entire upper surface of the silicon substrate 31 in plan view. In a region other than the region of the capacitor 51C, the second interlayer insulating film 43 is formed on the high dielectric film 161, and the through hole 46C penetrates the high dielectric film 161 and the second interlayer insulating film 43. The film thickness of the second interlayer insulating film 43 between the first rewiring 42 and the second rewiring 44 other than the region of the capacitor 51C can be, for example, about 20 μm.

With the capacitor 51C according to the third configuration example configured as described above, since the high dielectric film 161 is used as the capacitance film, high electrostatic capacitance can be achieved as compared with the first configuration example. The second interlayer insulating film 43 is formed in a region other than the capacitor 51B of the high dielectric film 161 formed on the entire surface, and the parasitic capacitance between the first rewiring 42 and the second rewiring 44 is not increased. Therefore, it is possible to increase the capacitance of the capacitive element for stabilizing the power supply voltage while suppressing the signal delay due to the parasitic capacitance of the rewiring.

### 9. Manufacturing Method of Capacitor According to Third Configuration Example

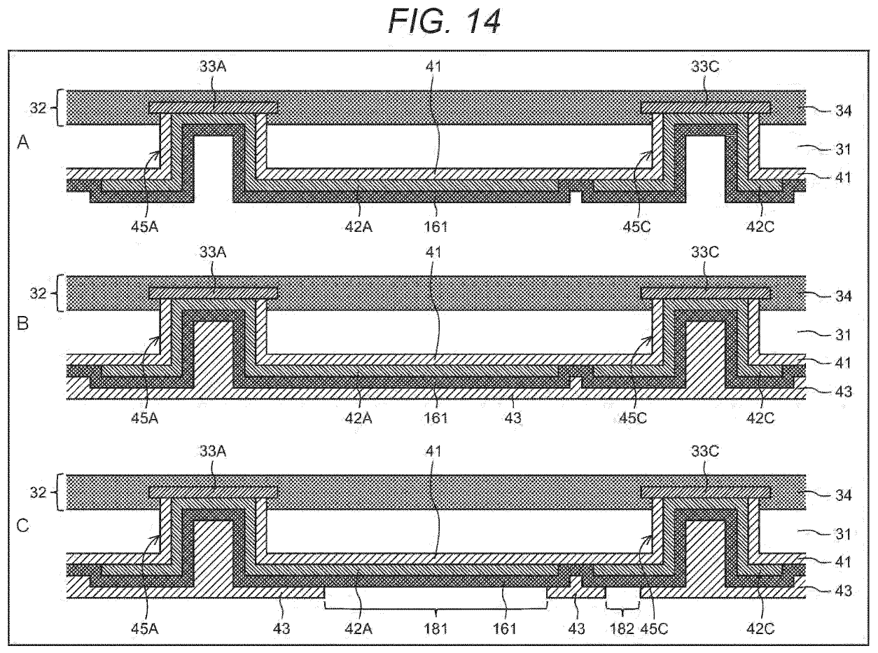

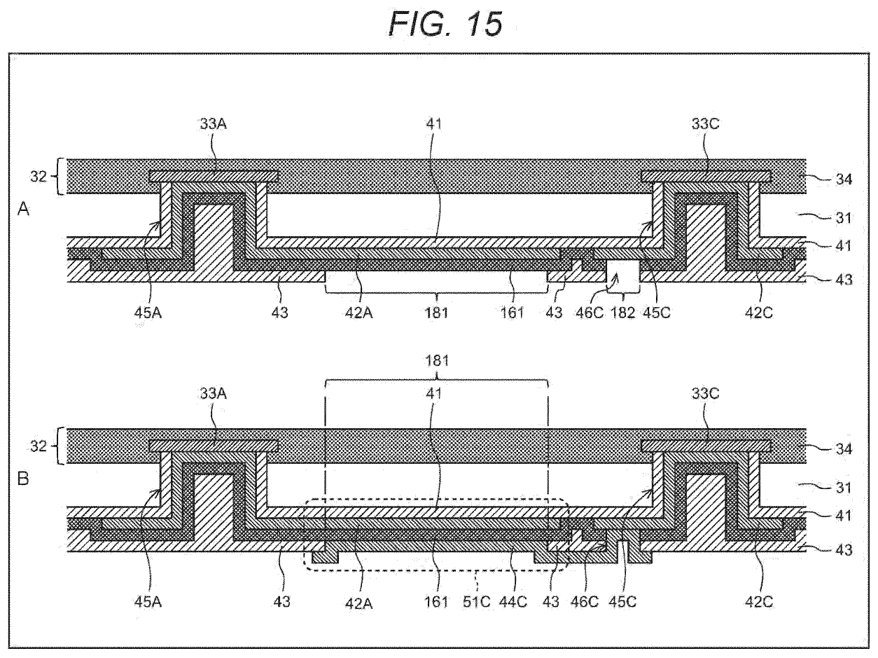

Next, a manufacturing method of the solid-state imaging device 1 including the capacitor 51C according to the third configuration example illustrated in FIG. 13 will be described with reference to FIGS. 14 and 15.

As illustrated in A of FIG. 14, the high dielectric film 161 is formed on the entire upper surface of the silicon substrate 31. The high dielectric film 161 is formed on the upper surfaces of the first rewirings 42A and 42C in a region where the first rewirings 42A and 42C are formed, and is formed on the upper surface of the first interlayer insulating film 41 in a region where the first rewirings 42A and 42C are not formed. The process before forming the high dielectric film 161 is similar to the process described in A of FIG. 3 to A of FIG. 4 of the first configuration example.

Next, as illustrated in B of FIG. 14, the second interlayer insulating film 43 is formed on an upper surface of the high dielectric film 161. As a material of the second interlayer insulating film 43, an organic material such as a solder resist, an inorganic material such as a silicon oxide film (SiO2 film), or the like can be used. In this example, the material of the second interlayer insulating film 43 is, for example, a solder resist having photosensitivity. The film thickness of the second interlayer insulating film 43 can be several nm to several tens of μm. This step is similar to the step in B of FIG. 4 in the first configuration example.

Next, as illustrated in C of FIG. 14, the second interlayer insulating film 43 in a region 181 to be the capacitor 51C and a region 182 to be the through hole 46C is removed. When the material of the second interlayer insulating film 43 is a solder resist having photosensitivity, the second interlayer insulating film 43 in the regions 181 and 182 can be removed by a lithography method.

Next, as illustrated in A of FIG. 15, the high dielectric film 161 in the region 182 to be the through hole 46C is removed by dry etching or the like using a resist pattern formed by a lithography method as a mask, thereby forming the through hole 46C. Note that, although not illustrated in A of FIG. 15, the through hole 46A (FIG. 1) is also formed on the first rewiring 42A on the internal electrode 33A side simultaneously with the through hole 46C.

Next, as illustrated in B of FIG. 15, the second rewiring 44C is formed on the high dielectric film 161 in the region 181 to be the capacitor 51C and in the region including the inside of the through hole 46C. This step is similar to the step in A of FIG. 5 in the first configuration example, but in the third configuration example, a step corresponding to the presence or absence of the second interlayer insulating film 43 is formed.

Steps subsequent to B in FIG. 15 are similar to those in the first configuration example. That is, after the protective film 48 is formed on the uppermost layer, an insulating film opening is formed in a predetermined region of the protective film 48, and the solder bumps 47A and 47B are formed on the exposed second rewirings 44A and 44B, respectively.

Through the above steps, the logic substrate 12 including the capacitor 51C according to the third configuration example illustrated in FIG. 13 is manufactured. The logic substrate 12 is bonded to the sensor substrate 11 at an appropriate timing to complete the solid-state imaging device 1.

According to the manufacturing method of the solid-state imaging device 1 including the capacitor 51C according to the third configuration example, the capacitor 51C having high electrostatic capacitance can be formed by using the high dielectric film 161 as the capacitance film.

### 10. Fourth Configuration Example of Capacitor

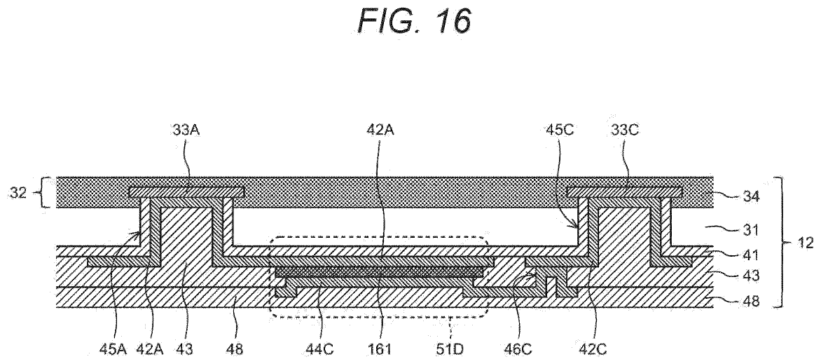

FIG. 16 is a cross-sectional view illustrating a detailed structure of a capacitor 51D according to a fourth configuration example, which is the capacitor 51 included in the solid-state imaging device 1 of the fourth embodiment.

The capacitor 51C according to the fourth configuration example illustrated in FIG. 16 is common to the capacitor 51C according to the third configuration example illustrated in FIG. 13 in that the first rewiring 42A and the second rewiring 44C are a pair of capacitance electrodes, and the high dielectric film 161 is formed between these rewirings.

On the other hand, the fourth configuration example illustrated in FIG. 16 is different from the third configuration example illustrated in FIG. 13 in that the high dielectric film 161 is formed not on the entire surface above the silicon substrate 31 but only in a region where the first rewiring 42A and the second rewiring 44C constituting the capacitor 51D overlap. Since the high dielectric film 161 is often a material having a high film stress, in a case of being formed on the entire upper surface of the silicon substrate 31, warpage may occur in the entire solid-state imaging device 1. By forming the high dielectric film 161 only in the region of the capacitor 51D, it is possible to suppress warpage of the entire device and to enhance connection reliability with a module board to be mounted.

With the capacitor 51D according to the fourth configuration example configured as described above, since the high dielectric film 161 is used as the capacitance film, high electrostatic capacitance can be achieved as compared with the first configuration example. Since the high dielectric film 161 is formed only in the region of the capacitor 51D, warpage of the entire device can be suppressed, and connection reliability to the mounting substrate can be enhanced.

The second interlayer insulating film 43 is formed in a region other than the capacitor 51D, and does not increase the parasitic capacitance between the first rewiring 42 and the second rewiring 44. Therefore, it is possible to increase the capacitance of the capacitive element for stabilizing the power supply voltage while suppressing the signal delay due to the parasitic capacitance of the rewiring.

### 11. Manufacturing Method of Capacitor According to Fourth Configuration Example

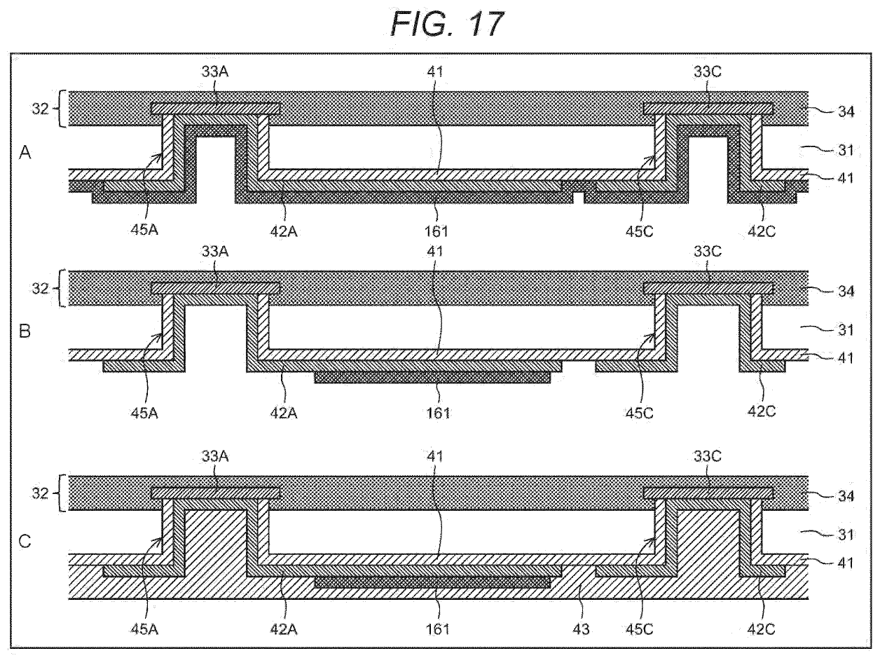

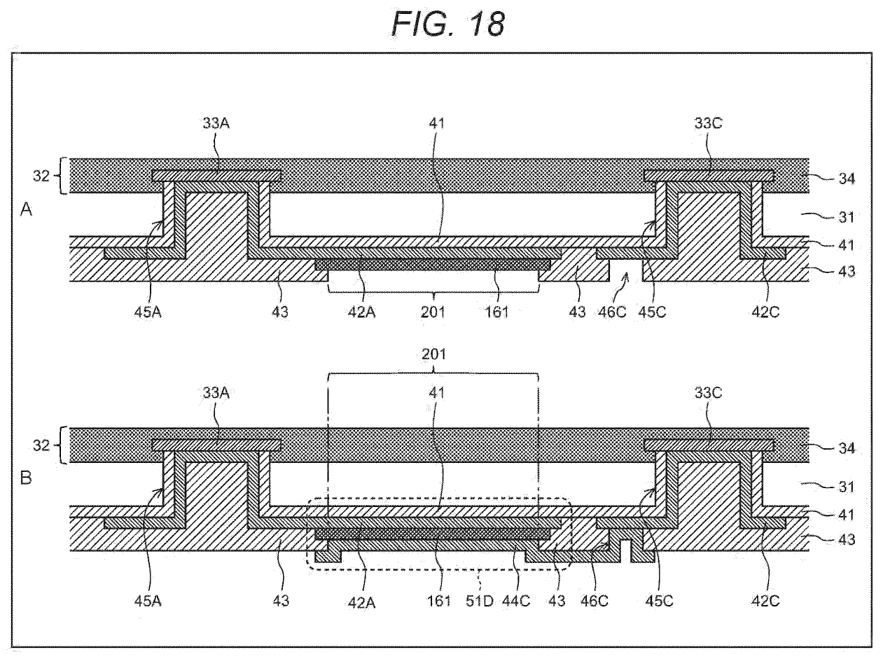

Next, a manufacturing method of the solid-state imaging device 1 including the capacitor 51D according to the fourth configuration example illustrated in FIG. 16 will be described with reference to FIGS. 17 and 18.

As illustrated in A of FIG. 17, the high dielectric film 161 is formed on the entire upper surface of the silicon substrate 31. This step is similar to the step described in A of FIG. 14 of the third configuration example.

Next, as illustrated in B of FIG. 17, the high dielectric film 161 in the other region is removed so that only the region where the high dielectric film 161 becomes the capacitance film of the capacitor 51D remains. The high dielectric film 161 other than the region to be the capacitor 51D can be removed by forming a resist pattern in a region to be left, masking the resist pattern, and performing dry etching.

Next, as illustrated in C of FIG. 17, the second interlayer insulating film 43 is formed on the entire top layer. The second interlayer insulating film 43 is formed on the upper surface of the high dielectric film 161 in a region where the uppermost layer is the high dielectric film 161, is formed on the upper surfaces of the first rewirings 42A and 42C in a region where the uppermost layer is the first rewirings 42A and 42C, and is formed on the upper surface of the first interlayer insulating film 41 in a region where the uppermost layer is the first interlayer insulating film 41. This step is similar to the step described in B of FIG. 14 of the third configuration example.

Next, as illustrated in A of FIG. 18, the second interlayer insulating film 43 in a region 201 to be the capacitor 51D is removed, and the second interlayer insulating film 43 in a predetermined region on the first rewiring 42C is also removed to form the through hole 46C. In a case where the material of the second interlayer insulating film 43 is a solder resist having photosensitivity, the second interlayer insulating film 43 in a desired region can be removed by a lithography method.

Next, as illustrated in B of FIG. 18, the second rewiring 44C is formed on the high dielectric film 161 in the region 201 to be the capacitor 51D and in the region including the inside of the through hole 46C. This step is similar to the step in A of FIG. 5 in the first configuration example, but in the fourth configuration example, a step corresponding to the presence or absence of the second interlayer insulating film 43 is formed.

Steps subsequent to B in FIG. 18 are similar to those in the first configuration example. That is, after the protective film 48 is formed on the uppermost layer, an insulating film opening is formed in a predetermined region of the protective film 48, and the solder bumps 47A and 47B are formed on the exposed second rewirings 44A and 44B, respectively.

Through the above steps, the logic substrate 12 including the capacitor 51D according to the fourth configuration example illustrated in FIG. 16 is manufactured. The logic substrate 12 is bonded to the sensor substrate 11 at an appropriate timing to complete the solid-state imaging device 1.

According to the manufacturing method of the solid-state imaging device 1 including the capacitor 51D according to the fourth configuration example, the capacitor 51D having high electrostatic capacitance can be formed by using the high dielectric film 161 as the capacitance film. As compared with the capacitor 51C according to the third configuration example, since processing is performed so as to leave only the region to be the capacitance film of the capacitor 51D immediately after the high dielectric film 161 is once deposited on the entire surface, it is not necessary to remove the high dielectric film 161 when forming the through hole 46C. In the step in A of FIG. 18, since the through hole 46C can be formed simultaneously with the removal of the second interlayer insulating film 43 in the region 201 to be the capacitor 51D, the step can be performed more easily than that for the capacitor 51C according to the third configuration example.

### 12. Fifth Configuration Example of Capacitor

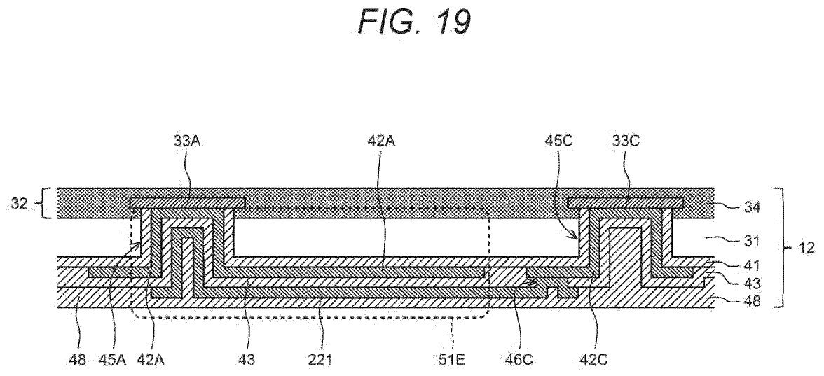

FIG. 19 is a cross-sectional view illustrating a detailed structure of a capacitor 51E according to a fifth configuration example, which is the capacitor 51 included in the solid-state imaging device 1 of the fifth embodiment.

The capacitor 51E according to the fifth configuration example illustrated in FIG. 19 is different from the capacitor 51A according to the first configuration example illustrated in FIG. 2 in that the second rewiring 44C is replaced with a second rewiring 221.

The second rewiring 44C of the capacitor 51A according to the first configuration example of FIG. 2 is not formed inside the through hole 45A penetrating the silicon substrate 31, and is formed as a flat plate only on the flat surface portion on the back surface side of the silicon substrate 31.

On the other hand, the second rewiring 221 of the capacitor 51E in FIG. 19 is formed not only in the planar portion on the back surface side of the silicon substrate 31 but also in the through hole 45A. Thus, the area of the second rewiring 221 facing the first rewiring 42A with the second interlayer insulating film 43 interposed therebetween increases, and high electrostatic capacitance can be achieved as compared with the first configuration example. There is no increase in the element area specialized for the capacitor.

With the capacitor 51E according to the fifth configuration example configured as described above, since the area of the second rewiring 221 facing the first rewiring 42A is increased, high electrostatic capacitance can be achieved as compared with the first configuration example. Therefore, it is possible to increase the capacitance of the capacitive element for stabilizing the power supply voltage while suppressing the signal delay due to the parasitic capacitance of the rewiring.

In the capacitor 51E, when a flat plate-shaped capacitor in an upper portion of the back surface of the silicon substrate 31 is referred to as a planar capacitor, and a capacitor portion inside the through hole 45A is referred to as a cylindrical capacitor, the capacitor 51E in FIG. 19 has a configuration in which the planar capacitor and the cylindrical capacitor are connected in series. The capacitor 51E may have a configuration in which the planar capacitor and the cylindrical capacitor are connected in parallel.

### 13. Manufacturing Method of Capacitor According to Fifth Configuration Example

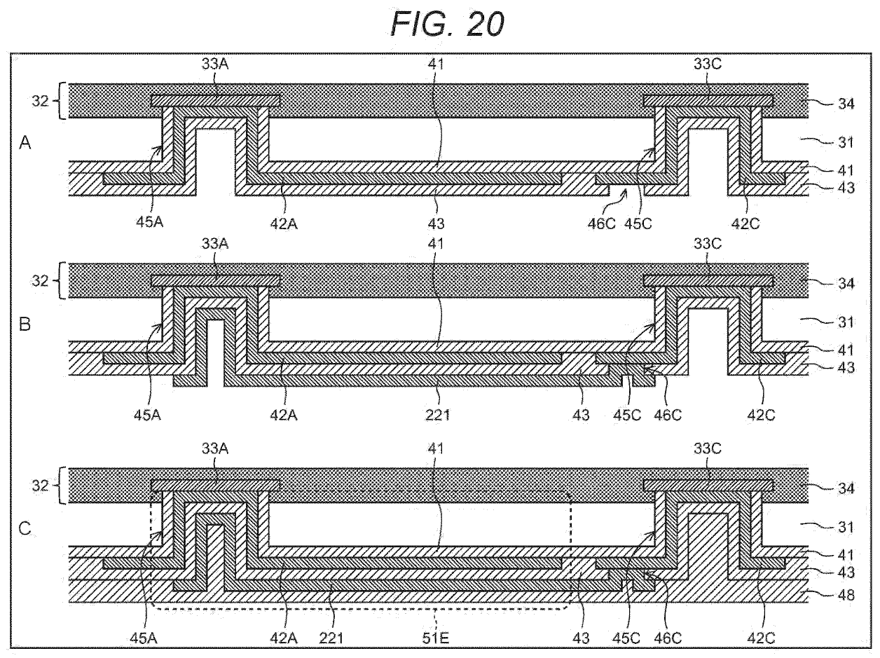

Next, a manufacturing method of the solid-state imaging device 1 including the capacitor 51E according to the fifth configuration example illustrated in FIG. 19 will be described with reference to FIG. 20.

A of FIG. 20 is the same as C of FIG. 4 in the capacitor 51A of the first configuration example described above. As illustrated in A of FIG. 20, the steps until the second interlayer insulating film 43 and the through hole 46C are formed are similar to the steps described in A of FIG. 3 to C of FIG. 4 of the first configuration example.

Next, as illustrated in B of FIG. 20, the second rewiring 221 is formed in a predetermined region on the second interlayer insulating film 43 and inside the through hole 46C. The second rewiring 221 is formed to extend also inside the through hole 45A. The material of the second rewiring 221 is also copper similarly to the first rewiring 42A. The method of forming the second rewiring 221 is also similar to that of the first rewiring 42A. The film thickness of the second rewiring 221 is, for example, about several μm to several tens of μm.

Next, as illustrated in C of FIG. 20, the protective film 48 is formed on an upper surface of the second rewiring 221 and the upper surface of the second interlayer insulating film 43 on which the second rewiring 221 is not formed. This step is similar to the step in B of FIG. 5 in the first configuration example.

Steps subsequent to C in FIG. 20 are similar to those in the first configuration example. That is, an insulating film opening is formed in a predetermined region of the protective film 48, and the solder bumps 47A and 47B are formed on the exposed second rewirings 44A and 44B, respectively.

Through the above steps, the logic substrate 12 including the capacitor 51E according to the fifth configuration example illustrated in FIG. 19 is manufactured. The logic substrate 12 is bonded to the sensor substrate 11 at an appropriate timing to complete the solid-state imaging device 1.

According to the manufacturing method of the solid-state imaging device 1 including the capacitor 51E according to the fifth configuration example, high electrostatic capacitance can be achieved as compared with the first configuration example by enlarging the area of the capacitance electrode. The area of the capacitance electrode can be enlarged without adding the number of steps as compared with the first configuration example.

### 14. Sixth Configuration Example of Capacitor

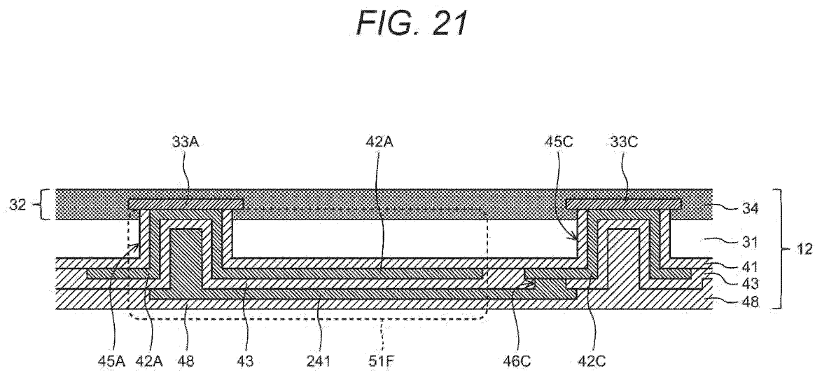

FIG. 21 is a cross-sectional view illustrating a detailed structure of a capacitor 51F according to a sixth configuration example, which is the capacitor 51 included in the solid-state imaging device 1 of the sixth embodiment.

In the capacitor 51F according to the sixth configuration example illustrated in FIG. 21, the second rewiring 221 is replaced with a second rewiring 241 as compared with the capacitor 51E according to the fifth configuration example illustrated in FIG. 19. The capacitor 51F is common to the capacitor 51E in that a planar capacitor and a cylindrical capacitor are connected in series.

However, in the cylindrical capacitor of the capacitor 51E according to the fifth configuration example illustrated in FIG. 19, the protective film 48 is embedded inside the second rewiring 221 formed along the inner wall of the through hole 45A. On the other hand, in the cylindrical capacitor of the capacitor 51F according to the sixth configuration example, the protective film 48 is not embedded in the through hole 45A. Instead of embedding the protective film 48, the second rewiring 241 is embedded in a plug shape. The plug shape is a columnar or conical shape. An upper surface of the second rewiring 241 embedded in the through hole 46C is also formed flat.

With the capacitor 51F according to the sixth configuration example configured as described above, since the area of the second rewiring 221 facing the first rewiring 42A is increased, high electrostatic capacitance can be achieved as compared with the first configuration example. Therefore, it is possible to increase the capacitance of the capacitive element for stabilizing the power supply voltage while suppressing the signal delay due to the parasitic capacitance of the rewiring.

Further, by embedding the second rewiring 241 in the through hole 45A in a plug shape, it is possible to obtain stable capacitance characteristics with less concern of disconnection of the second rewiring 241. Furthermore, since the protective film 48 is not embedded in the through hole 45A, a cavity or the like of the protective film 48 does not occur in the through hole 45A, and it is possible to suppress the occurrence of defects such as the destruction of the protective film 48 due to the expansion of the gas in the cavity.

### 15. Manufacturing Method of Capacitor According to Sixth Configuration Example

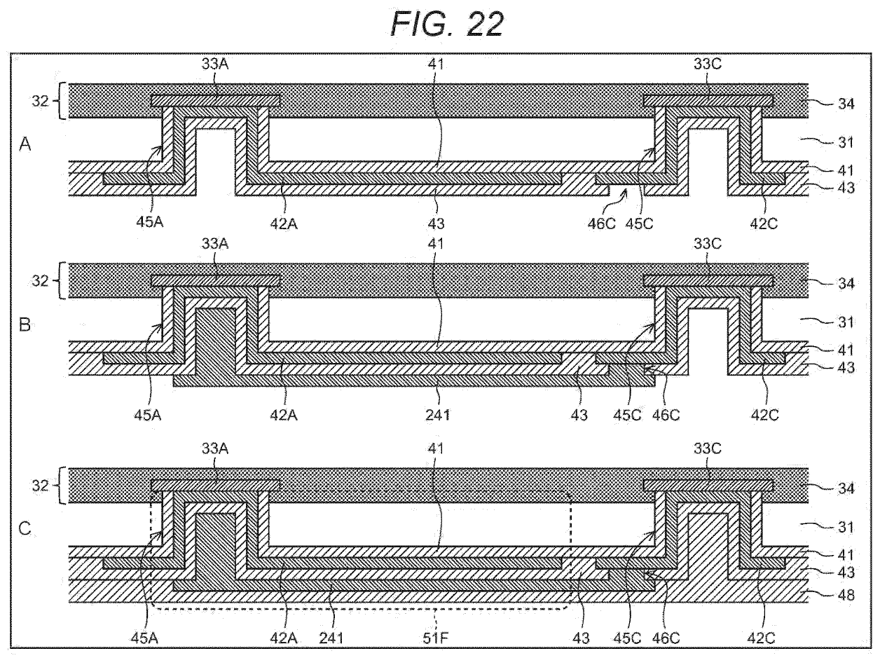

Next, a manufacturing method of the solid-state imaging device 1 including the capacitor 51F according to the sixth configuration example illustrated in FIG. 21 will be described with reference to FIG. 22.

A of FIG. 22 is the same as C of FIG. 4 in the capacitor 51A of the first configuration example described above. As illustrated in A of FIG. 22, the steps until the second interlayer insulating film 43 and the through hole 46C are formed are similar to the steps described in A of FIG. 3 to C of FIG. 4 of the first configuration example.

Next, as illustrated in B of FIG. 22, the second rewiring 241 is formed in a predetermined region on the second interlayer insulating film 43 and inside the through hole 46C. The second rewiring 241 is embedded in the through hole 45A in a plug shape. Furthermore, the upper surface of the second rewiring 241 embedded in the through hole 46C is also formed flat. The material of the second rewiring 241 is also copper similarly to the first rewiring 42A. A method with good coverage is employed to form the second rewiring 241.

Next, as illustrated in C of FIG. 22, the protective film 48 is formed on the upper surface of the second rewiring 241 and the upper surface of the second interlayer insulating film 43 on which the second rewiring 241 is not formed. This step is similar to the step in B of FIG. 5 in the first configuration example.

Steps subsequent to C in FIG. 22 are similar to those in the first configuration example. That is, an insulating film opening is formed in a predetermined region of the protective film 48, and the solder bumps 47A and 47B are formed on the exposed second rewirings 44A and 44B, respectively.

Through the above steps, the logic substrate 12 including the capacitor 51F according to the sixth configuration example illustrated in FIG. 21 is manufactured. The logic substrate 12 is bonded to the sensor substrate 11 at an appropriate timing to complete the solid-state imaging device 1.

According to the manufacturing method of the solid-state imaging device 1 including the capacitor 51E according to the sixth configuration example, high electrostatic capacitance can be achieved as compared with the first configuration example by enlarging the area of the capacitance electrode. Since the second rewiring material serving as a capacitive electrode is completely embedded in the through hole 45A in a plug shape, the second rewiring can be formed without worrying about a step covering property in the opening of the protective film 48 to be subsequently deposited.

### 16. Seventh Configuration Example of Capacitor

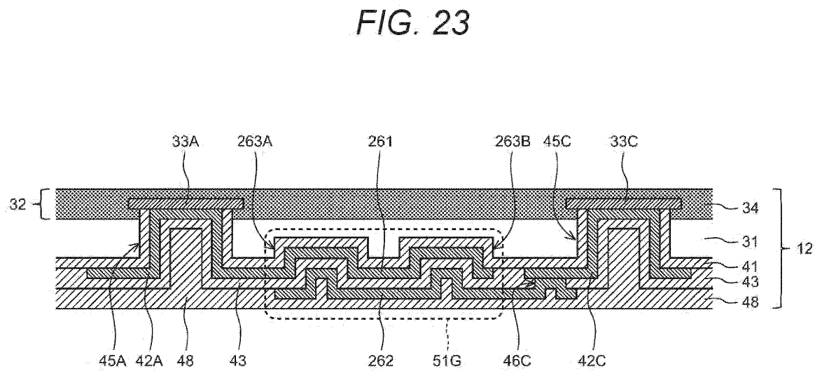

FIG. 23 is a cross-sectional view illustrating a detailed structure of a capacitor 51G according to a seventh configuration example, which is the capacitor 51 included in the solid-state imaging device 1 of the seventh embodiment.

In the capacitor 51G according to the seventh configuration example illustrated in FIG. 23, as compared with the capacitor 51A according to the first configuration example illustrated in FIG. 2, a first rewiring 261 and a second rewiring 262 constituting the pair of capacitance electrodes have uneven cross-sectional shapes. Specifically, grooves 263A and 263B dug to a predetermined depth are formed in a part of the silicon substrate 31 in a planar region where the capacitor 51G is formed, and the first rewiring 261 and the second rewiring 262 have a cross-sectional shape having a step at a deep position in a portion where the grooves 263A and 263B are formed and a step at a shallow position in a portion where the grooves 263A and 263B are not formed. As described above, the first rewiring 261 and the second rewiring 262 are formed in an uneven cross-sectional shape along the grooves 263A and 263B, whereby the facing area between the first rewiring 261 and the second rewiring 262 can be increased.

With the capacitor 51G according to the seventh configuration example configured as described above, since the facing area of the first rewiring 261 and the second rewiring 262 can be increased, the effective capacitor area is increased, and the electrostatic capacitance can be increased as compared with the first configuration example.

### 17. Manufacturing Method of Capacitor According to Seventh Configuration Example

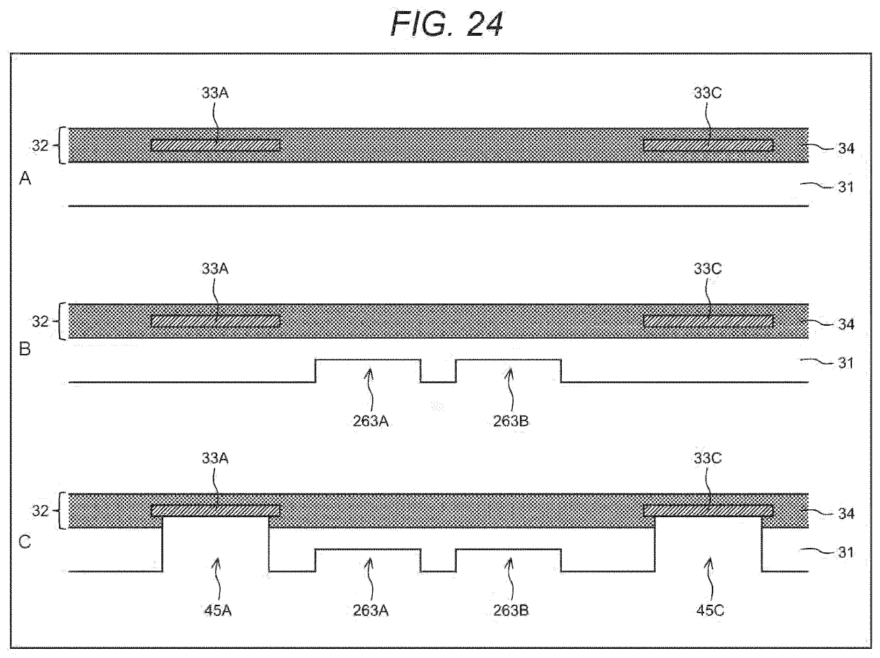

Next, a manufacturing method of the solid-state imaging device 1 including the capacitor 51G according to the seventh configuration example illustrated in FIG. 23 will be described with reference to FIGS. 24 to 26.

First, as illustrated in A of FIG. 24, the multilayer wiring layer 32 is formed on the first surface of the silicon substrate 31 on the sensor substrate 11 side. The multilayer wiring layer 32 includes a plurality of metal wiring layers (not illustrated) including at least two internal electrodes 33A and 33C and the interlayer insulating film 34 therebetween.

Next, as illustrated in B of FIG. 24, the grooves 263A and 263B are formed in a part of the silicon substrate 31 in a planar region where the capacitor 51G is formed.

Next, as illustrated in C of FIG. 24, the through holes 45A and 45C penetrating the silicon substrate 31 are formed at positions corresponding to the internal electrodes 33A and 33C, respectively. The through holes 45A and 45C are formed until reaching the internal electrodes 33A and 33C, respectively, and a part of upper surfaces of the internal electrodes 33A and 33C is exposed.

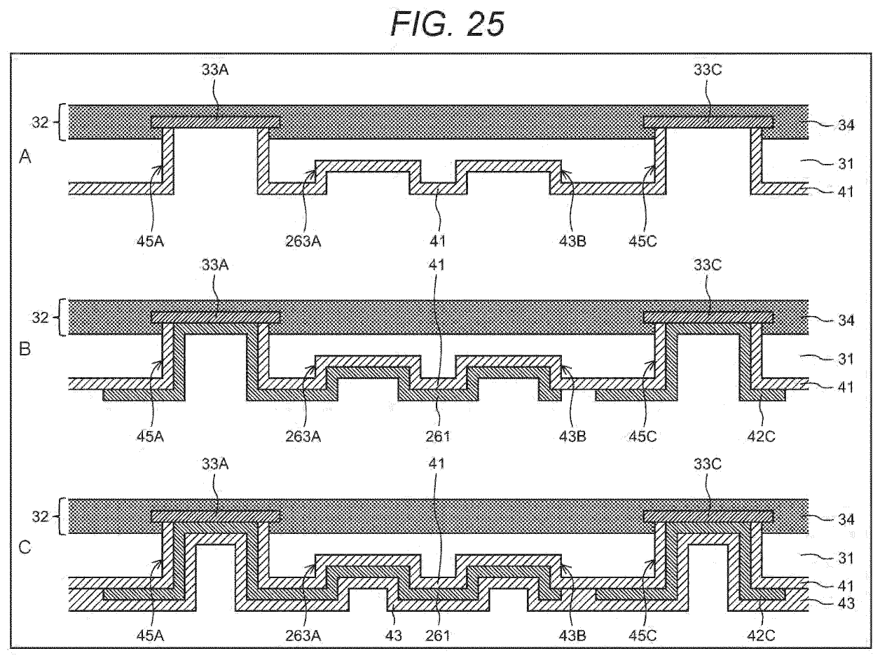

Next, as illustrated in A of FIG. 25, the first interlayer insulating film 41 is formed on the upper surface of the silicon substrate 31, the inner walls and bottom surfaces of the grooves 263A and 263B, and the side walls of the through holes 45A and 45C. The first interlayer insulating film 41 can be formed, for example, by forming the first interlayer insulating film 41 on the entire upper surface of the silicon substrate 31 including the grooves 263A and 263B and the bottom and side walls of the through holes 45A and 45C, and then dry-etching only the bottom surfaces of the through holes 45A and 45C using a lithography method. The first interlayer insulating film 41 is formed in an uneven cross-sectional shape along the grooves 263A and 263B.

Next, as illustrated in B of FIG. 25, the first rewiring 261 connected to the internal electrode 33A and the first rewiring 42C connected to the internal electrode 33C are simultaneously formed. The material of the first rewirings 261 and 42C is, for example, copper. In this case, for example, the first rewirings 261 and 42C can be formed by forming a resist material provided with an opening pattern in a predetermined region, and forming a copper film by an electrolytic plating method using the formed resist material as a mask. The film thickness of the first rewirings 261 and 42C is, for example, about several μm to several tens of μm. The first rewiring 261 is formed in an uneven shape along the grooves 263A and 263B.

Next, as illustrated in C of FIG. 25, the second interlayer insulating film 43 is formed on the upper surfaces of the first rewirings 261 and 42C and the upper surface of the first interlayer insulating film 41 on which the first rewirings 261 and 42C are not formed. As a material of the second interlayer insulating film 43, an organic material such as a solder resist, an inorganic material such as a silicon oxide film (SiO2 film), or the like can be used. The solder resist can be formed using a coating apparatus, and the silicon oxide film can be formed using, for example, CVD, ALD, or the like. The second interlayer insulating film 43 is formed so as to be deposited with a uniform film thickness inside the through holes 45A and 45C and the grooves 263A and 263B. The film thickness of the second interlayer insulating film 43 can be several nm to several tens of μm.

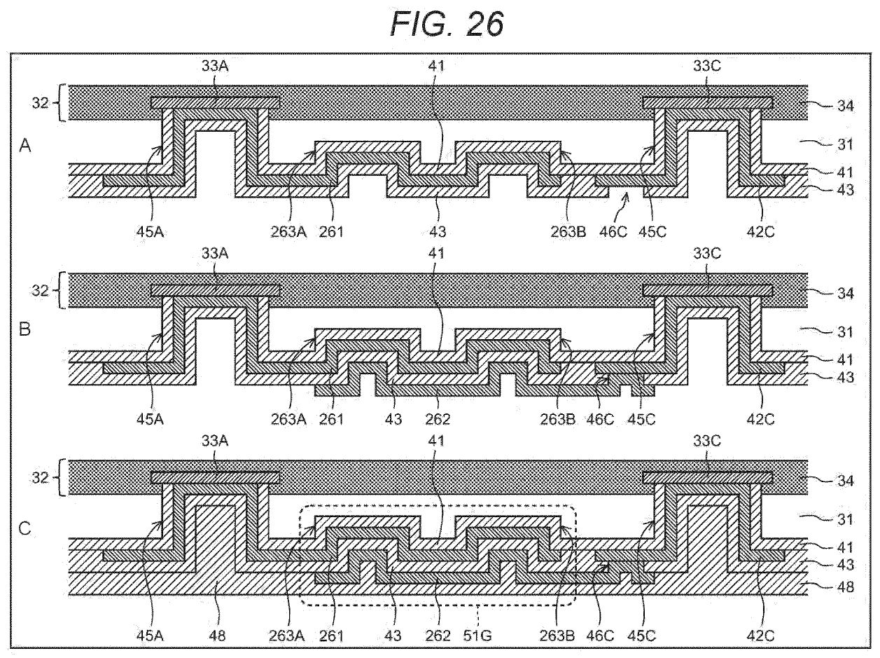

Next, as illustrated in A of FIG. 26, the through hole 46C penetrating the second interlayer insulating film 43 is formed in a predetermined region on the first rewiring 42C. In a case where the second interlayer insulating film 43 is a solder resist of a photosensitive material or the like, the through hole 46C can be formed by a lithography method. Furthermore, for example, in a case where the second interlayer insulating film 43 is a silicon oxide film, the through hole 46C can be formed by forming a resist pattern by a lithography method, and dry-etching the second interlayer insulating film 43 using the resist pattern as a mask. Note that, although not illustrated in A of FIG. 26, the through hole 46A (FIG. 1) is also formed on the first rewiring 42A on the internal electrode 33A side simultaneously with the through hole 46C.

Next, as illustrated in B of FIG. 26, the second rewiring 262 is formed in a predetermined region including the grooves 263A and 263B on the second interlayer insulating film 43 and inside the through hole 46C. The material of the second rewiring 262 is also copper similarly to the first rewiring 261. The method for forming the second rewiring 262 is also similar to the method for forming the first rewiring 261. The film thickness of the second rewiring 262 is, for example, about several μm to several tens of μm. Note that, although not illustrated in B of FIG. 26, the second rewiring 44A on the internal electrode 33A side is also formed simultaneously with the second rewiring 262. The second rewiring 262 is also formed in an uneven cross-sectional shape along the grooves 263A and 263B.

Next, as illustrated in C of FIG. 26, the protective film 48 is formed on an upper surface of the second rewiring 262 and the upper surface of the second interlayer insulating film 43 on which the second rewiring 262 is not formed. As a material of the protective film 48, for example, a solder resist which is an organic material is used. As the solder resist, it is desirable to use a photosensitive solder resist in order to provide an insulating film opening for arranging the solder bump 47 in the next step.

Steps subsequent to C in FIG. 26 are similar to those in the first configuration example. That is, an insulating film opening is formed in a predetermined region of the uppermost protective film 48, and the solder bumps 47A and 47B are formed on the exposed second rewirings 44A and 44B, respectively.

Through the above steps, the logic substrate 12 including the capacitor 51G according to the seventh configuration example illustrated in FIG. 23 is manufactured. The logic substrate 12 is bonded to the sensor substrate 11 at an appropriate timing to complete the solid-state imaging device 1.

According to the manufacturing method of the solid-state imaging device 1 including the capacitor 51G according to the seventh configuration example, it is possible to form the capacitor 51G having a large capacitor area and high electrostatic capacitance.

### 18. Eighth Configuration Example of Capacitor

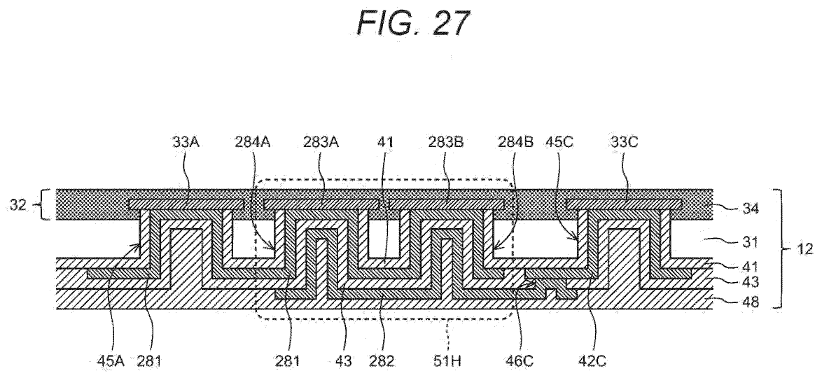

FIG. 27 is a cross-sectional view illustrating a detailed structure of a capacitor 51H according to an eighth configuration example, which is the capacitor 51 included in the solid-state imaging device 1 of the eighth embodiment.

The capacitor 51H according to the eighth configuration example illustrated in FIG. 27 is common to the capacitor 51G according to the seventh configuration example illustrated in FIG. 23 in that a first rewiring 281 and a second rewiring 282 constituting a pair of capacitance electrodes have uneven cross-sectional shapes along grooves 284A and 284B.

On the other hand, the capacitor 51H according to the eighth configuration example is different from the capacitor 51G according to the seventh configuration example illustrated in FIG. 23 in that the grooves 284A and 284B are not formed by digging a part of the silicon substrate 31 but are through holes penetrating the silicon substrate 31. In the multilayer wiring layer 32 in the region where the grooves 284A and 284B are formed, stopper films 283A and 283B functioning as stoppers during groove processing are formed in the same layer as the internal electrodes 33A and 33C.

With the capacitor 51H according to the eighth configuration example configured as described above, by setting the depth of the grooves 284A and 284B to the same depth as the through holes 45A and 45B, the step of the unevenness of the first rewiring 281 and the second rewiring 282 is increased, so that the facing area between the first rewiring 281 and the second rewiring 282 can be further increased as compared with the seventh configuration example. Since the effective capacitor area is increased as compared with the seventh configuration example, the electrostatic capacitance can be further increased.

### 19. Manufacturing Method of Capacitor According to Eighth Configuration Example

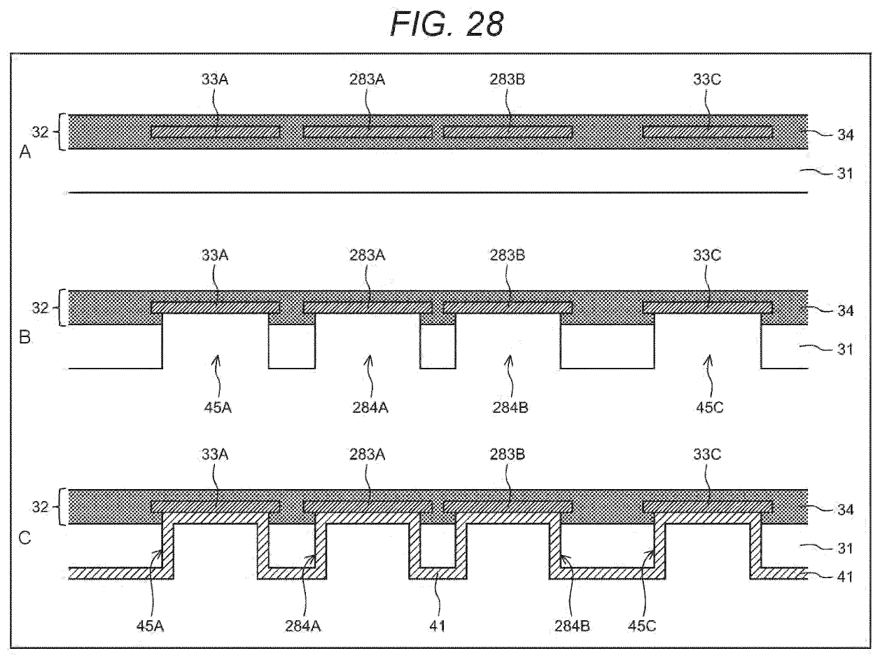

Next, a manufacturing method of the solid-state imaging device 1 including the capacitor 51H according to the eighth configuration example illustrated in FIG. 27 will be described with reference to FIGS. 28 to 30.

First, as illustrated in A of FIG. 28, the multilayer wiring layer 32 is formed on the first surface of the silicon substrate 31 on the sensor substrate 11 side. In the multilayer wiring layer 32, at least two internal electrodes 33A and 33C, the stopper films 283A and 283B, and the interlayer insulating film 34 are formed. The stopper films 283A and 283B can be formed by the same material as the internal electrodes 33A and 33C.

Next, as illustrated in B of FIG. 28, the through holes 45A and 45C penetrating the silicon substrate 31 are formed at positions corresponding to the internal electrodes 33A and 33C, and the grooves 284A and 284B penetrating the silicon substrate 31 are formed at positions corresponding to the stopper films 283A and 283B. The through holes 45A and 45C and the grooves 284A and 284B are simultaneously formed, the internal electrodes 33A and 33C serve as etching stoppers when forming the through holes 45A and 45C, and the stopper films 283A and 283B serve as etching stoppers when forming the grooves 284A and 284B.

Next, as illustrated in C of FIG. 28, the first interlayer insulating film 41 is formed on the entire upper surface of the silicon substrate 31, the bottom surfaces and the side walls of the through holes 45A and 45C, and the bottom surfaces and the side walls of the grooves 284A and 284B.

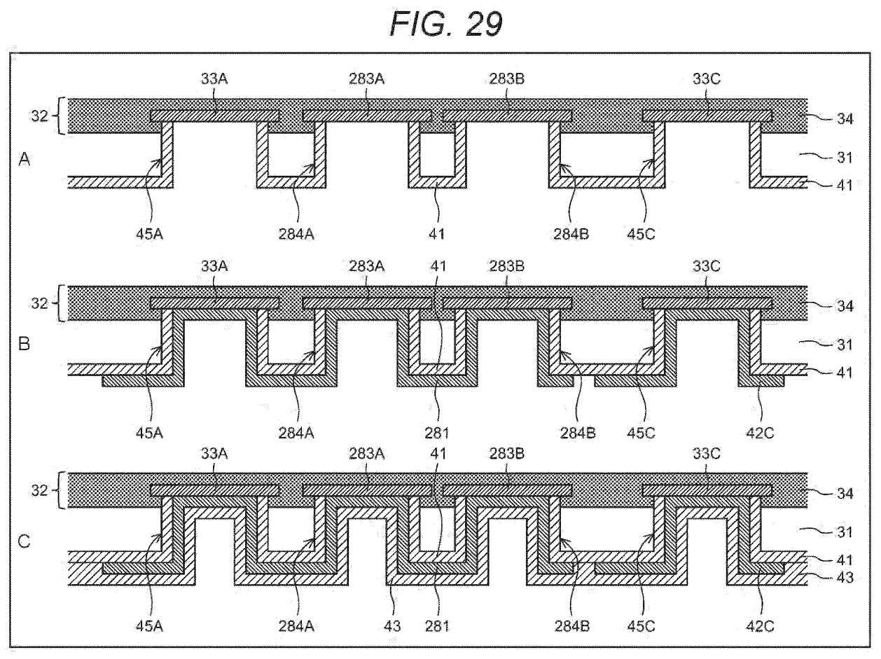

Next, as illustrated in A of FIG. 29, the first interlayer insulating film 41 on the bottom surfaces of the through holes 45A and 45C and on the bottom surfaces of the grooves 284A and 284B is removed using etch-back or the like.

Next, as illustrated in B of FIG. 29, the first rewiring 281 connected to the internal electrode 33A and the first rewiring 42C connected to the internal electrode 33C are simultaneously formed. This step is similar to the step described in B of FIG. 25 in the seventh configuration example. However, since the grooves 284A and 284B are formed at the same depth as the through hole 45A, the step of the unevenness of the cross-sectional shape of the first rewiring 42A is the same as the step of the through hole 45A, and is deeper than that of the seventh configuration example.

Next, as illustrated in C of FIG. 29, the second interlayer insulating film 43 is formed on the upper surfaces of the first rewirings 281 and 42C and the upper surface of the first interlayer insulating film 41 on which the first rewirings 281 and 42C are not formed. This step is similar to the step described in C of FIG. 25 in the seventh configuration example. The second interlayer insulating film 43 is also formed in an uneven cross-sectional shape along the grooves 284A and 284B.

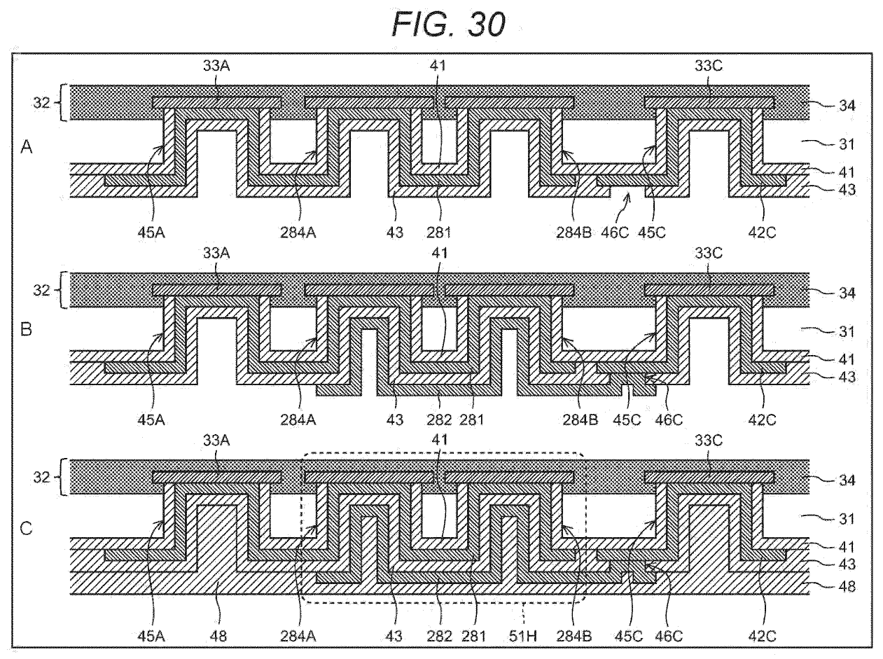

Next, as illustrated in A of FIG. 30, the through hole 46C penetrating the second interlayer insulating film 43 is formed in a predetermined region on the first rewiring 42C. In a case where the second interlayer insulating film 43 is a solder resist of a photosensitive material or the like, the through hole 46C can be formed by a lithography method. Furthermore, for example, in a case where the second interlayer insulating film 43 is a silicon oxide film, the through hole 46C can be formed by forming a resist pattern by a lithography method, and dry-etching the second interlayer insulating film 43 using the resist pattern as a mask. Note that, although not illustrated in A of FIG. 30, the through hole 46A (FIG. 1) is also formed on the first rewiring 42A on the internal electrode 33A side simultaneously with the through hole 46C.

Next, as illustrated in B of FIG. 30, the second rewiring 282 is formed in a predetermined region including the grooves 284A and 284B on the second interlayer insulating film 43 and inside the through hole 46C. The material of the second rewiring 282 is also copper similarly to the first rewiring 281. The method for forming the second rewiring 282 is also similar to the method for forming the first rewiring 281. The film thickness of the second rewiring 282 is, for example, about several μm to several tens of μm. Note that, although not illustrated in B of FIG. 30, the second rewiring 44A on the internal electrode 33A side is also formed simultaneously with the second rewiring 282. The second rewiring 282 is also formed in an uneven cross-sectional shape along the grooves 284A and 284B.

Next, as illustrated in C of FIG. 30, the protective film 48 is formed on an upper surface of the second rewiring 282 and the upper surface of the second interlayer insulating film 43 on which the second rewiring 282 is not formed. As a material of the protective film 48, for example, a solder resist which is an organic material is used. As the solder resist, it is desirable to use a photosensitive solder resist in order to provide an insulating film opening for arranging the solder bump 47 in the next step.

Steps subsequent to C in FIG. 30 are similar to those in the first configuration example. That is, an insulating film opening is formed in a predetermined region of the uppermost protective film 48, and the solder bumps 47A and 47B are formed on the exposed second rewirings 44A and 44B, respectively.

Through the above steps, the logic substrate 12 including the capacitor 51H according to the eighth configuration example illustrated in FIG. 27 is manufactured. The logic substrate 12 is bonded to the sensor substrate 11 at an appropriate timing to complete the solid-state imaging device 1.

According to the manufacturing method of the solid-state imaging device 1 including the capacitor 51H according to the eighth configuration example, it is possible to form the capacitor 51H having a large capacitor area and high electrostatic capacitance. Since the stopper films 283A and 283B serving as stoppers at the time of processing the grooves 284A and 284B are formed, the depths of the grooves 284A and 284B can be controlled with high accuracy, so that variations in capacitance can be suppressed, and a stable capacitance value can be obtained.

### 20. Ninth Configuration Example of Capacitor

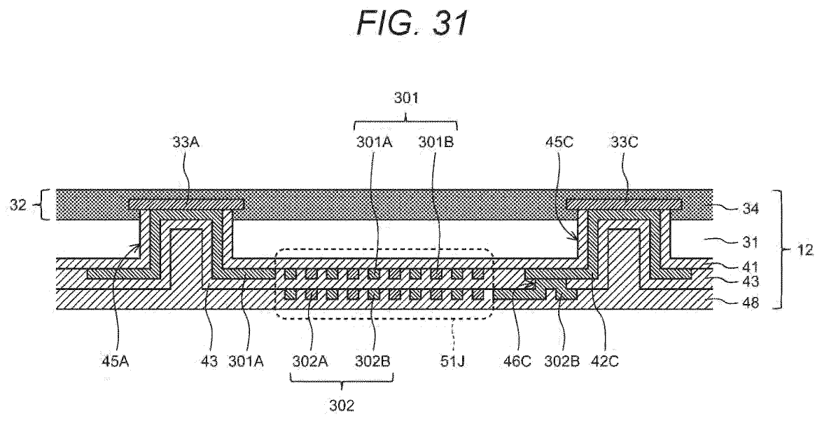

FIG. 31 is a cross-sectional view illustrating a detailed structure of a capacitor 51J according to a ninth configuration example, which is the capacitor 51 included in the solid-state imaging device 1 of the ninth embodiment.

In the capacitor 51J according to the ninth configuration example illustrated in FIG. 31, the planar shape of each of the first rewiring 301 and the second rewiring 302 constituting the pair of capacitance electrodes is formed in a comb shape. More specifically, the first rewiring 301 includes a first wiring 301A and a second wiring 301B capacitively coupled in the planar direction. The second rewiring 302 includes a first wiring 302A and a second wiring 302B capacitively coupled in the planar direction.

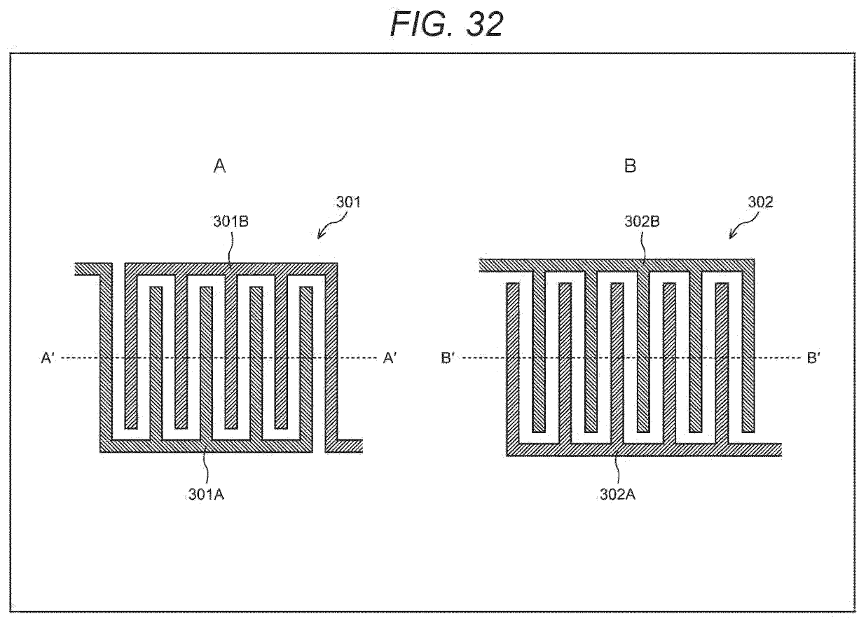

A of FIG. 32 is a plan view of the first wiring 301A and the second wiring 301B constituting the first rewiring 301. B of FIG. 32 is a plan view of the first wiring 302A and the second wiring 302B constituting the second rewiring 302.

The first wiring 301A and the second wiring 301B of the first rewiring 301 illustrated in A of FIG. 32 are each formed in a comb shape. A comb-shaped wiring of the second wiring 301B is arranged in gaps of a comb-shaped wiring of the first wiring 301A, and the comb-shaped wiring of the first wiring 301A and the comb-shaped wiring of the second wiring 301B are alternately arranged to face each other. Different potentials are supplied to the comb-shaped wiring of the first wiring 301A and the comb-shaped wiring of the second wiring 301B, and a capacitive element including the first wiring 301A and the second wiring 301B as capacitive electrodes is configured.

The first wiring 302A and the second wiring 302B of the second rewiring 302 illustrated in B of FIG. 32 are each formed in a comb shape. The comb-shaped wiring of the second wiring 302B is arranged in gaps of a comb-shaped wiring of the first wiring 302A, and the comb-shaped wiring of the first wiring 302A and the comb-shaped wiring of the second wiring 302B are alternately arranged to face each other. Different potentials are supplied to the comb-shaped wiring of the first wiring 302A and the comb-shaped wiring of the second wiring 302B, and a capacitive element including the first wiring 302A and the second wiring 302B as capacitive electrodes is configured.

Therefore, the first wiring 301A and the second wiring 301B of the first rewiring 301 are capacitively coupled in the planar direction, and the first wiring 302A and the second wiring 302B of the second rewiring 302 are capacitively coupled in the planar direction.

Furthermore, as is clear from the cross-sectional view of FIG. 31, the first wiring 301A and the second wiring 301B of the first rewiring 301, and the first wiring 302A and the second wiring 302B of the second rewiring 302 also constitute a capacitive element in the vertical direction (stacking direction).

With the capacitor 51J according to the ninth configuration example configured as described above, the first rewiring 301 and the second rewiring 302 function as capacitive elements in both the planar direction of the same layer and the vertical direction between different layers, whereby a capacitor with a high capacitance can be achieved.

### 21. Tenth Embodiment of Solid-State Imaging Device

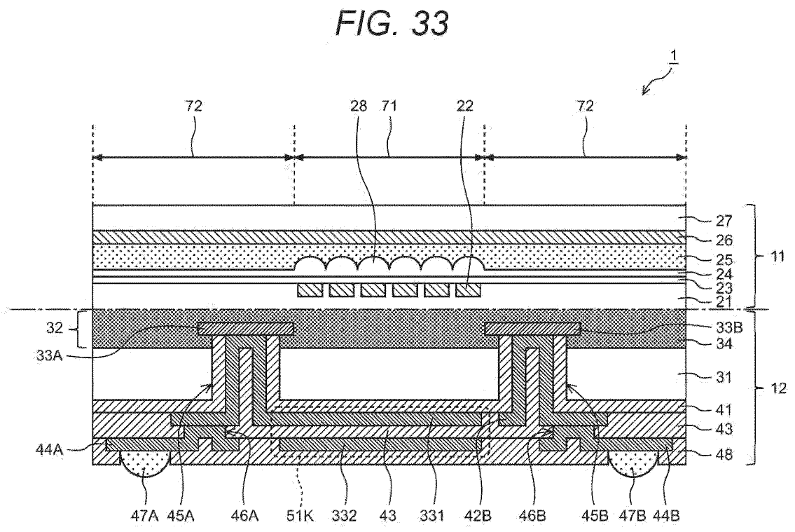

FIG. 33 is an overall configuration cross-sectional view of a tenth embodiment of a solid-state imaging device to which the present technology is applied.

A solid-state imaging device 1 illustrated in FIG. 33 is different in that the configuration of the capacitor 51 is changed from the capacitor 51A according to the first configuration example to a capacitor 51K according to the tenth configuration example, and is common in other points.

The capacitor 51K in FIG. 33 includes a first rewiring 331, another second rewiring 332 formed in the same layer as the second rewiring 44A, and the second interlayer insulating film 43 therebetween. As illustrated in FIG. 1, the capacitor 51A according to the first configuration example is formed only in a part of the pixel region 71 at the center of the chip region. On the other hand, the first rewiring 331 and the second rewiring 332 of the capacitor 51K are formed on the entire surface of the pixel region 71.

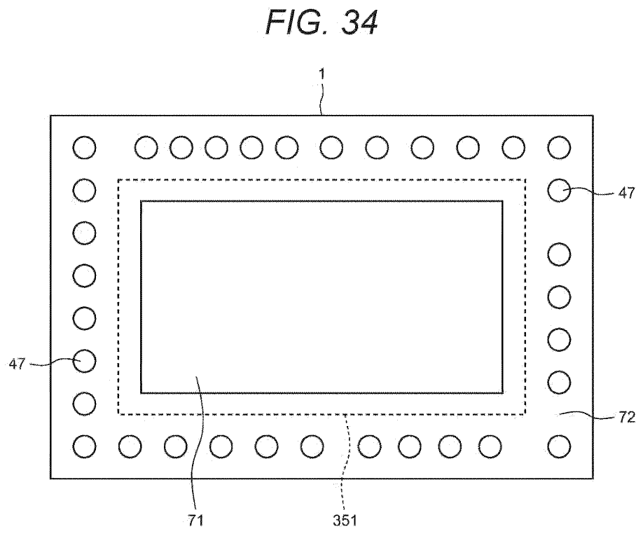

FIG. 34 is a plan view of the solid-state imaging device 1 according to the tenth embodiment. The plan view of FIG. 34 is a plan view of a back surface side on which solder bumps 47 and the like are formed.

In the plan view of FIG. 34, the solid-state imaging device 1 includes a pixel region 71 at the center of a rectangular chip region and a peripheral region 72 outside the pixel region. A plurality of solder bumps 47 is formed in the peripheral region 72.

In the plan view of FIG. 34, a capacitor region 351 indicated by a broken line outside the pixel region 71 represents a region where the first rewiring 331 and the second rewiring 332 of the capacitor 51K overlap. The capacitor region 351 includes the entire region of the pixel region 71 in plan view, and is formed to cover the entire lower portion of the pixel region 71 with a larger plane area than the pixel region 71.

Since the capacitor region 351 is arranged so as to cover the entire lower portion of the pixel region 71, it is possible to prevent infrared light (IR light) from entering from the back surface side of the solid-state imaging device 1. Furthermore, since it is possible to ensure a large area of the first rewiring 331 and the second rewiring 332 to be the capacitance electrodes, a high capacitance can be achieved.

Note that, in the above-described example, the first rewiring 331 and the second rewiring 332 constituting the capacitor 51K are formed by one flat metal film, but each of the first rewiring 331 and the second rewiring 332 may be divided into a plurality of regions with a gap shorter than the wavelength of light.

### 22. Summary of First to Tenth Embodiment

The solid-state imaging device 1 according to the first to tenth embodiments includes an internal electrode 33 formed on a first surface side (light incident surface side) of a silicon substrate 31, a through hole 45 formed at a position corresponding to the internal electrode 33 of the silicon substrate 31, a first rewiring 42 formed on a second surface side opposite to the first surface side of the silicon substrate 31 and connected to the internal electrode 33 via the through hole 45, a second rewiring 44 connected to the first rewiring 42 and formed on a side closer to a solder bump 47 than the first rewiring 42, and an interlayer insulating film 43 formed between the first rewiring 42 and the second rewiring 44.

The capacitors 51A to 51K are formed by using two rewiring layers of the first rewiring 42 and the second rewiring 44. For example, the capacitor 51A according to the first configuration example includes a first rewiring 42A connected to the internal electrode 33A as the first internal electrode 33, a second rewiring 44C connected to the internal electrode 33C as the second internal electrode 33, and an interlayer insulating film 43 formed therebetween. The power supply voltage is supplied from the solder bump 47A to the internal electrode 33A and the first rewiring 42A, and the internal electrode 33C and the second rewiring 44C are connected to the ground.

As described above, by forming the capacitor 51 using the two rewiring layers of the first rewiring 42 and the second rewiring 44, the capacitor 51 can be formed not in the multilayer wiring layer 32 formed on the first surface side of the silicon substrate 31 but on the second surface side on the external connection terminal side, so that there is no influence on high integration of the circuit formed in the multilayer wiring layer 32.

Furthermore, rewiring layer portions of two layers of the first rewiring 42 and the second rewiring 44 forming the capacitor 51 enable a configuration in which the second interlayer insulating film 43 is thinned, the high dielectric film 161 is provided, or the capacitance is increased, and on the other hand, rewiring layer portions of two layers of the first rewiring 42 and the second rewiring 44 other than the capacitor 51 can sufficiently ensure the film thickness of the second interlayer insulating film 43, so that it is possible to achieve both formation of a capacitive element by the two-layer rewiring layer and reduction of parasitic capacitance.

By stabilizing the potential by connecting the capacitor 51 to the internal electrode 33A connected to the power supply voltage, signal delay and jitter can be improved.

The capacitor 51 may employ a configuration in which two or more of the above-described first to tenth configuration examples are arbitrarily combined.

### 23. Three-Layer Stacked Configuration Example

In the above-described embodiment, a case has been described in which the solid-state imaging device 1 has a two-plate stacked structure in which two substrates of the sensor substrate 11 and the logic substrate 12 are stacked. However, the capacitor 51 described above can also be applied to the solid-state imaging device 1 having a stacked structure in which three or more substrates are stacked.

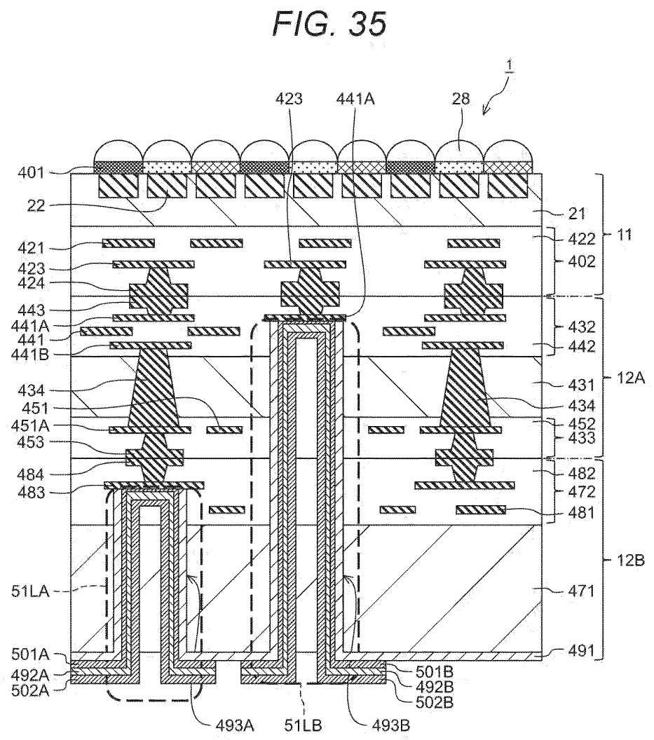

FIG. 35 illustrates a configuration example in which the capacitor 51 is formed in the solid-state imaging device 1 having a stacked structure in which three substrates are stacked.

The solid-state imaging device 1 illustrated in FIG. 35 is configured by stacking the sensor substrate 11 as a first substrate, a first logic substrate 12A as a second substrate, and a second logic substrate 12B as a third substrate in this order from the incident surface side of incident light.

In FIG. 35, an upper side of the solid-state imaging device 1 corresponds to a light incident surface side on which incident light is incident, and a lower side of the solid-state imaging device 1 corresponds to a back surface of the solid-state imaging device 1 which is a semiconductor chip. In FIG. 35, a joint surface between the sensor substrate 11 and the first logic substrate 12A and a joint surface between the first logic substrate 12A and the second logic substrate 12B are indicated by one-dot chain lines.

The sensor substrate 11 includes a silicon substrate 21. On the silicon substrate 21, photodiodes 22 as photoelectric conversion elements are formed in units of pixels. In the drawing, a color filter 401 and an on-chip lens 28 are formed for each pixel on the light incident surface side of the silicon substrate 21 on the upper side. In FIG. 35, the planarization film 23, the interlayer insulating film 25, the bonding resin 26, and the light-transmissive substrate 27 illustrated in FIG. 1 are omitted. The light-transmissive substrate 27 may be provided on the on-chip lens 28 via the bonding resin 26 as in the configuration illustrated in FIG. 1, or the light-transmissive substrate 27 may be omitted as in FIG. 35.

A wiring layer 402 including a plurality of layers of metal wirings 421 and an insulating layer 422 is formed on the circuit formation surface side of the silicon substrate 21, which is the lower side in the drawing, opposite to the light incident surface side. The number of layers of the metal wirings 121 is not limited. A plurality of junction electrodes 424 is formed on the joint surface with the first logic substrate 12A, which is a lower surface of the wiring layer 402. The junction electrodes 424 are connected to internal electrodes 423 provided in the same layer as the lowermost metal wirings 421 in the wiring layer 402. The internal electrodes 423 are formed by, for example, the same material as the metal wirings 421, but may be formed by a different material. Furthermore, the junction electrode 424 is metal-bonded (for example, Cu—Cu bonded) to junction electrodes 443 of the first logic substrate 12A, and electrically connects the sensor substrate 11 and the first logic substrate 12A. As a material of the metal wirings 421 and the junction electrodes 424, for example, copper (Cu), tungsten (W), aluminum (Al), gold (Au), or the like can be employed. In the present embodiment, the metal wirings 421 and the junction electrodes 424 are formed by copper. The insulating layer 422 is formed by, for example, a SiO2 film, a low-k film (low dielectric constant insulating film), a SiOC film, or the like. The insulating layer 422 may include a plurality of insulating films constituted by different materials.

The first logic substrate 12A includes a semiconductor substrate 431 using, for example, silicon (Si) as a semiconductor. The first logic substrate 12A has a wiring layer 432 on a front surface side on the sensor substrate 11 side of the semiconductor substrate 431, and a junction layer 433 on a back surface side on the second logic substrate 12B side of the semiconductor substrate 431. The wiring layer 432 includes a plurality of layers of metal wirings 441 and an insulating layer 442. The number of layers of the metal wirings 441 is not limited. A plurality of junction electrodes 443 is formed on the joint surface with the sensor substrate 11, which is an upper surface of the wiring layer 432. The junction electrodes 443 are metal-bonded to the junction electrodes 424 of the sensor substrate 11, and electrically connect the sensor substrate 11 and the first logic substrate 12A. The junction electrodes 443 are connected to an internal electrode 441A provided in the same layer as the uppermost metal wiring 441 in the wiring layer 432. In the same layer as the lowermost metal wiring 441 in the wiring layer 432, an internal electrode 441B connected to a through electrode (through-silicon via (TSV)) 434 penetrating the semiconductor substrate 431 is formed. The internal electrodes 441A and 441B are formed by, for example, the same material as the metal wirings 441, but may be formed by different materials. As a material of the metal wirings 441 and the junction electrodes 443, for example, copper (Cu), tungsten (W), aluminum (Al), gold (Au), or the like can be employed. In the present embodiment, the metal wirings 441 and the junction electrode 443 are formed by copper. The insulating layer 442 is formed by, for example, a SiO2 film, a low-k film (low dielectric constant insulating film), a SiOC film, or the like. The insulating layer 442 may include a plurality of insulating films constituted by different materials.

The junction layer 433 formed on the back surface side of the semiconductor substrate 431 on the second logic substrate 12B side includes one or more metal wirings 451 and an insulating layer 452. The number of layers of the metal wirings 451 is not limited. An internal electrode 451A provided in the same layer as the metal wirings 451 in the junction layer 433 is connected to the through electrode 434 and a junction electrode 453. The through electrode 434 is connected to the internal electrode 441B in the wiring layer 432 on the sensor substrate 11 side of the first logic substrate 12A, and electrically connects the wiring layer 432 of the first logic substrate 12A and the junction layer 433. The junction electrode 453 is metal-bonded to a junction electrode 484 of the second logic substrate 12B, and electrically connects the first logic substrate 12A and the second logic substrate 12B. The materials of the metal wirings 451, the internal electrode 451A, the insulating layer 252, and the junction electrode 453 are similar to those of the metal wirings 441, the internal electrode 441A, the insulating layer 442, and the junction electrodes 443 on the wiring layer 432 side.

The second logic substrate 12B has a semiconductor substrate 471 using, for example, silicon (Si) as a semiconductor. The second logic substrate 12B has a wiring layer 472 on a front surface side which is the first logic substrate 12A side of the semiconductor substrate 471. The wiring layer 472 includes a plurality of layers of metal wirings 481 and an insulating layer 482. The number of layers of the metal wirings 481 is not limited. A plurality of junction electrodes 484 is formed on the joint surface with the first logic substrate 12A, which is an upper surface of the wiring layer 472. The junction electrodes 484 are metal-bonded to the junction electrodes 453 of the first logic substrate 12A, and electrically connect the first logic substrate 12A and the second logic substrate 12B. The junction electrodes 484 are connected to the internal electrodes 483 provided in the same layer as the uppermost metal wiring 481 in the wiring layer 472. The internal electrodes 483 are formed by, for example, the same material as the metal wirings 481, but may be formed by a different material. As a material of the metal wirings 481 and the junction electrodes 484, for example, copper (Cu), tungsten (W), aluminum (Al), gold (Au), or the like can be employed. In the present embodiment, the metal wirings 481 and the junction electrodes 484 are formed by copper. The insulating layer 482 is formed by, for example, a SiO2 film, a low-k film (low dielectric constant insulating film), a SiOC film, or the like. The insulating layer 482 may include a plurality of insulating films constituted by different materials.

In the second logic substrate 12B, capacitors 51LA and 51LB which are MIM capacitors penetrating at least the semiconductor substrate 471 are formed. The capacitor 51LA includes a first rewiring 501A and a second rewiring 502A that are capacitance electrodes, and a second interlayer insulating film 492A therebetween. The capacitor 51LB includes a first rewiring 501B and a second rewiring 502B that are capacitance electrodes, and a second interlayer insulating film 492B therebetween. The capacitors 51LA and 51LB have a configuration in which a planar capacitor formed on a back surface side of the semiconductor substrate 471 and a cylindrical capacitor formed on a side surface and a bottom portion (an upper surface in FIG. 35) of a through hole 493 (493A or 493B) penetrating at least the semiconductor substrate 471 are connected in series. The capacitors 51LA and 51LB are electrically separated from the semiconductor substrate 471 by the first interlayer insulating film 491.

The capacitor 51LA penetrates the semiconductor substrate 471 and is connected to the internal electrode 483 in the wiring layer 472 of the second logic substrate 12B. The capacitor 51 LB penetrates the semiconductor substrate 471 and the wiring layer 472 of the second logic substrate 12B and the junction layer 433 and the semiconductor substrate 431 of the first logic substrate 12A, and is connected to the internal electrode 441A in the wiring layer 432 of the first logic substrate 12A. In the capacitor 51LB, since the area of the side surface of the through hole 493B is increased as compared with the capacitor 51LA, the electrostatic capacitance can be further increased.

The capacitors 51LA and 51LB are connected to the power supply voltage, the ground (GND), or the solder bump 47 (not illustrated) that inputs and outputs various signals (for example, pixel signals and control signals) on the back surface of the second logic substrate 12B. In FIG. 35, the second interlayer insulating film 43 and the protective film 48 covering the back surface of the solid-state imaging device 1 are not illustrated.

In the solid-state imaging device 1 having a stacked structure in which the above three substrates are stacked, whether to be connected to the internal electrode 483 in the wiring layer 472 of the second logic substrate 12B as in the capacitor 51LA or to be connected to the internal electrode 441A in the wiring layer 432 of the first logic substrate 12A as in the capacitor 51LB can be determined by, for example, the arrangement of an interface (IF) circuit that performs format conversion or the like of input and output signals. For example, in a case where the IF circuit is provided in the wiring layer 472 of the second logic substrate 12B, the configuration of the capacitor 51LA can be employed, and in a case where the IF circuit is provided in the wiring layer 432 of the first logic substrate 12A, the configuration of the capacitor 51LB can be employed.

In the solid-state imaging device 1 having a stacked structure in which the above three substrates are stacked, the capacitor 51L (51LA or 51LB) can be formed in both the through hole 493B connected to the internal electrode 441A of the first logic substrate 12A and the through hole 493A connected to the internal electrode 483 of the second logic substrate 12B, and the electrostatic capacitance can be increased by forming the deeper through hole 493.

FIG. 35 illustrates an example of a stacked structure in which three substrates are stacked, but it is of course possible to configure the capacitor 51L in the solid-state imaging device 1 having a stacked structure in which four or more substrates are stacked. In this case, the internal electrode connected to the external connection terminal via the capacitor 51L may be an internal electrode of any wiring layer of the four substrates.

### 24. 11th Configuration Example of Capacitor

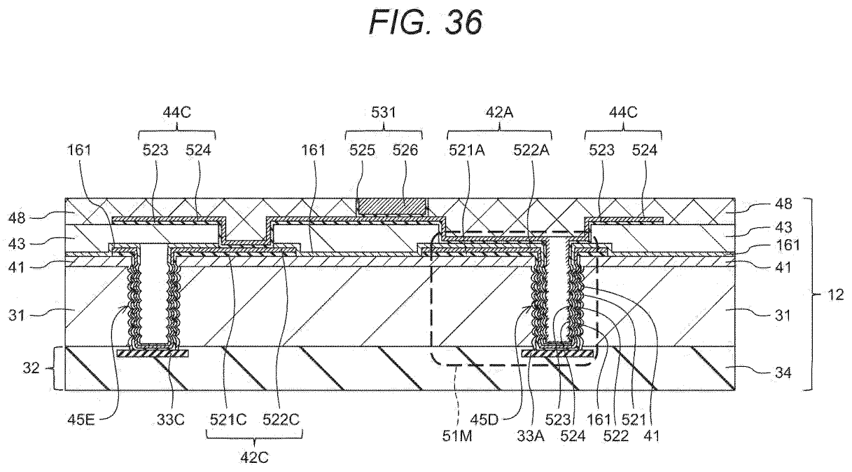

FIG. 36 is a cross-sectional view illustrating a detailed structure of a capacitor 51M according to an 11th configuration example, which is the capacitor 51 included in the solid-state imaging device 1 of the 11th embodiment.

In the 11th configuration example of FIG. 36, for example, as in the second configuration example of FIG. 2, only the configuration of the logic substrate 12 is illustrated in the solid-state imaging device 1 configured by stacking the sensor substrate 11 and the logic substrate 12. Note that, in the second configuration example in FIG. 2, the back surface of the solid-state imaging device 1 on which the solder bump 47, which is an external connection terminal, is formed is illustrated in the direction to be the lower side of the silicon substrate 31, but in the 11th configuration example in FIG. 36, the back surface of the solid-state imaging device 1 on which a pillar (land) 531, which is an external connection terminal instead of the solder bumps 47, is formed is illustrated in the direction to be the upper side of the silicon substrate 31 in FIG. 36. That is, the vertical direction in FIG. 36 is opposite to that in FIG. 2. In the 11th configuration example of FIG. 36, parts corresponding to the respective configuration examples described above are denoted by the same reference numerals, and description of the parts will be omitted as appropriate.

As illustrated in FIG. 36, the capacitor 51M according to the 11th configuration example includes a first rewiring 42A, a second rewiring 44C, and a high dielectric film 161 therebetween. The capacitor 51M has a configuration in which a planar capacitor formed on the back surface side of the silicon substrate 31 and a cylindrical capacitor formed on a side surface and a bottom portion of a through hole 45D penetrating the silicon substrate 31 are connected in series. The capacitor 51M is different from those of the other configuration examples described above in that the side surface (inner peripheral surface) of the through hole 45D is formed in a scallop shape, and the first rewiring 42A, the high dielectric film 161, and the second rewiring 44C on the side surface of the through hole 45D are also formed in a scallop shape accordingly. The scalloped shape means an uneven shape in which arc-shaped recesses are repeated in a plurality of stages.

That is, in the silicon substrate 31, the through hole 45 is formed corresponding to the internal electrode 33 formed in the multilayer wiring layer 32 on the front surface side. The through hole 45D is formed at a position corresponding to the internal electrode 33A, and a through hole 45E is formed at a position corresponding to the internal electrode 33C. Side surfaces of the through holes 45D and 45E have an uneven shape in which arc-shaped recesses are repeated in a plurality of stages.

A first interlayer insulating film 41 is formed on the side surface of the through hole 45D formed at a position corresponding to the internal electrode 33A and the back surface side of the silicon substrate 31. The first interlayer insulating film 41 electrically isolates the first rewiring 42A from the silicon substrate 31. The first rewiring 42A is formed on the back surface side of the silicon substrate 31 and the side surface of the through hole 45D, and is connected to the internal electrode 33A formed in the multilayer wiring layer 32 on the front surface side. The first rewiring 42A includes, for example, a seed metal 521A including a barrier metal and a Cu seed film, and a Cu wiring 522A. As a material of the barrier metal film, tantalum (Ta), titanium (Ti), tungsten (W), zirconium (Zr), a nitride film thereof, a carbonized film thereof, or the like can be used.

As in the third configuration example of FIG. 13, the high dielectric film 161 is formed not only in the region of the capacitor 51M but also on the entire upper surface of the silicon substrate 31. In a region other than the capacitor 51M, a second interlayer insulating film 43 is formed on the high dielectric film 161.

The second rewiring 44C is formed on the high dielectric film 161 in the region of the capacitor 51M, and is formed on the second interlayer insulating film 43 in the region other than the capacitor 51M. The second rewiring 44C includes, for example, a seed metal 523 including a barrier metal and a Cu seed film, and a Cu wiring 524. The material of the barrier metal is similar to those described above. The pillar 531 is formed and exposed in a partial region of the upper surface of the second rewiring 44C, and the other region is covered with the protective film 48. Furthermore, the second rewiring 44C is also connected to the first rewiring 42C connected to the internal electrode 33C.

The pillar 531 includes a seed metal 525 including a barrier metal for preventing diffusion of a metal material and a Cu seed film, and copper (Cu) 526 embedded inside the seed metal. As a material of the barrier metal, tantalum (Ta), titanium (Ti), tungsten (W), zirconium (Zr), ruthenium (Ru), a nitride film (for example, TaN or TiN) thereof, a carbonized film thereof, or the like can be used. In place of the copper (Cu) 526, a metal material such as tungsten (W), aluminum (Al), gold (Au), silver (Ag), or nickel (Ni) may be used for the formation.

The first rewiring 42C is formed on the side surface of the through hole 45E formed at the position corresponding to the internal electrode 33C and the back surface side (upper side in FIG. 36) of the silicon substrate 31 via the first interlayer insulating film 41. The first interlayer insulating film 41 electrically isolates the first rewiring 42C from the silicon substrate 31. The first rewiring 42C includes, for example, a seed metal 521C including a barrier metal and a Cu seed film, and a Cu wiring 522C. The material of the barrier metal is similar to those described above. The side surface of the through hole 45E has a scallop shape similarly to the through hole 45D, and the first interlayer insulating film 41, the first rewiring 42C, and the high dielectric film 161 are also formed in a scallop shape. Note that, although center portions of the through holes 45D and 45E are formed by cavities in which the second interlayer insulating film 43 or the protective film 48 is not embedded, the second interlayer insulating film 43 or the protective film 48 may be embedded as in the other configuration examples described above.

With the capacitor 51M according to the 11th configuration example configured as described above, the side surface of the through hole 45D is formed in a scallop shape, and the first rewiring 42A, the high dielectric film 161, and the second rewiring 44C are also formed in a scallop shape. Thus, it is possible to increase the facing area between the first rewiring 42A and the second rewiring 44C as compared with a case where the side surface of the through hole 45D is a smooth surface, and it is possible to increase the electrostatic capacitance. Therefore, it is possible to increase the capacitance of the capacitive element for stabilizing the power supply voltage while suppressing the signal delay due to the parasitic capacitance of the rewiring. That is, signal delay and jitter can be improved. Between the planar capacitor and the cylindrical capacitor, the electrostatic capacitance of the capacitor 51M increases on the cylindrical capacitor side close to the logic circuit (IF circuit) in the multilayer wiring layer 32 of the logic substrate 12, so that the signal waveform is more stable and can contribute to high-speed transmission.

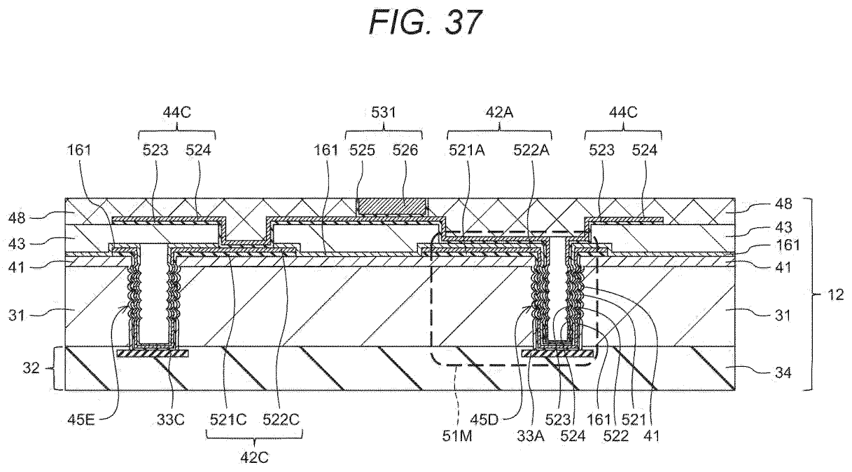

Note that, in the 11th configuration example of FIG. 36, an example has been described in which all side surfaces in the depth direction reaching the front surface (first surface) from the back surface (second surface) of the silicon substrate 31 are formed in a scallop shape in the through holes 45D and 45E formed in the silicon substrate 31. However, as illustrated in FIG. 37, only a part of the side surfaces of the through holes 45D and 45E in the depth direction, in other words, to a depth halfway from the back surface (second surface) toward the front surface (first surface) of the silicon substrate 31 may be formed in a scallop shape, and the side surface deeper than the depth may be formed as a smooth surface. Also in this case, the electrostatic capacitance can be increased as compared with the case where the entire side surface of the through hole 45D is a smooth surface.

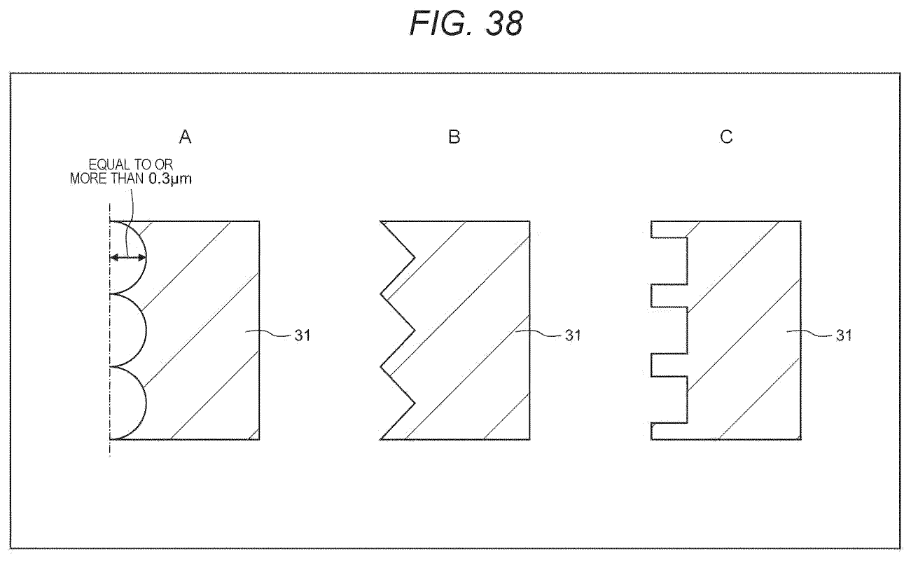

FIG. 38 is a cross-sectional view describing a modification of a side surface shape of the through hole 45D in which the capacitor 51M is formed.

In the 11th configuration example of FIG. 36, an example has been described in which the side surface of the through hole 45D has a scallop shape in which arc-shaped recesses are repeatedly formed in a plurality of stages as illustrated in A of FIG. 38. The side surface of the through hole 45D only needs to have a shape that can ensure a larger area than that in the case of a smooth surface, and may have, for example, a triangular shape as illustrated in B of FIG. 38 or a quadrangular uneven shape as illustrated in C of FIG. 38. The side surface of the through hole 45D only needs to have any uneven shape having a plurality of dug depths in a side surface direction (planar direction of the silicon substrate 31) perpendicular to the depth direction of the silicon substrate 31 in a cross-sectional view. For example, as illustrated in A of FIG. 38, the uneven shape of the side surface of the through hole 45D is formed to be a recess in which a dug depth in the side surface direction is equal to or more than 0.3 μm with respect to the smooth surface connecting apexes of the protrusion.

### 25. Manufacturing Method of Capacitor According to 11th Configuration Example

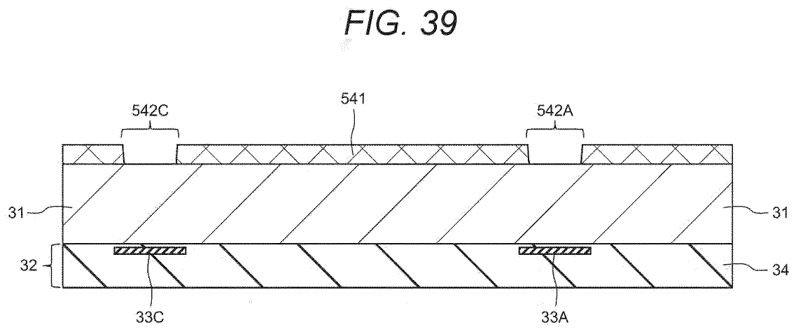

Next, a manufacturing method of the solid-state imaging device 1 including the capacitor 51M according to the 11th configuration example illustrated in FIG. 36 will be described with reference to FIGS. 39 to 46.

First, as illustrated in FIG. 39, a photoresist 541 is patterned on the back surface (second surface) of the silicon substrate 31 on the side opposite to the sensor substrate 11 side on which the multilayer wiring layer 32 is formed. In the photoresist 541, openings 542A and 542C are formed at positions corresponding to the two internal electrodes 33A and 33C, respectively.

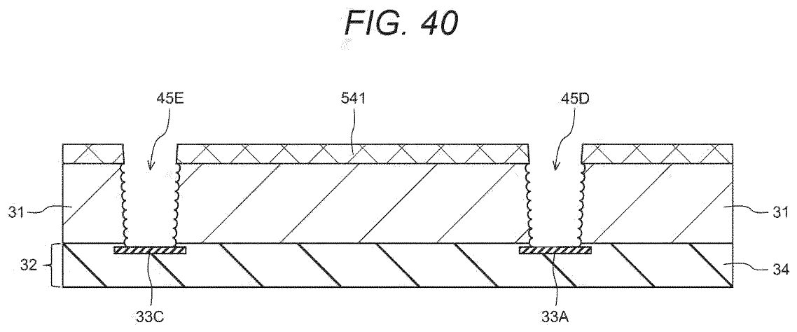

Next, as illustrated in FIG. 40, the silicon substrate 31 in the regions of the openings 542A and 542C is etched by a Bosch process on the basis of the patterned photoresist 541, thereby forming the through holes 45D and 45E whose side surfaces are formed in a scallop shape. The Bosch process is a dry etching technique of digging the silicon substrate 31 in the depth direction (vertical direction) by repeating three steps of (1) isotropic etching of silicon, (2) deposition of a protective film, and (3) anisotropic etching of Si (removal of the protective film on the bottom surface).

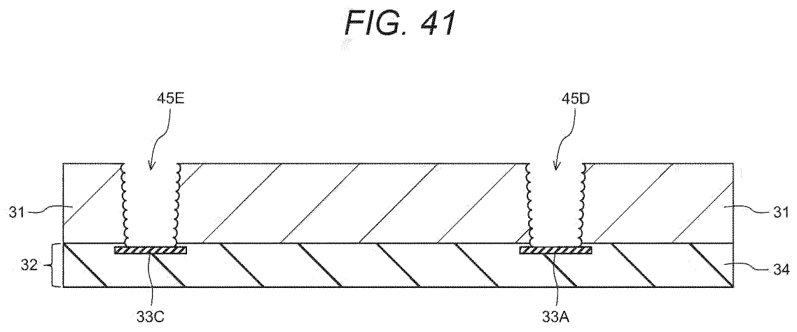

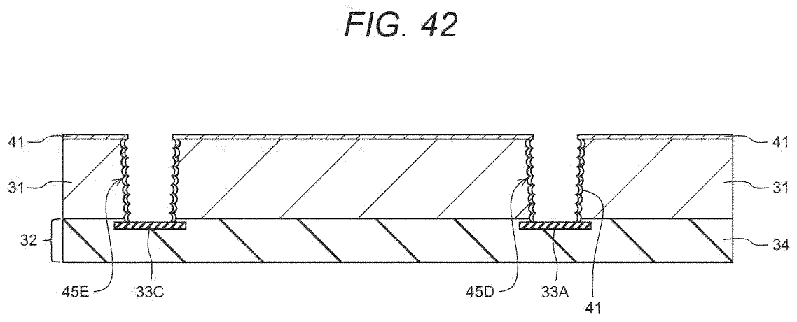

Next, after the photoresist 541 is removed as illustrated in FIG. 41, the first interlayer insulating film 41 is formed on the upper surface of the silicon substrate 31 and side walls of the through holes 45D and 45E as illustrated in FIG. 42. The first interlayer insulating film 41 can be formed, for example, by forming the first interlayer insulating film 41 on the entire upper surface of the silicon substrate 31 and the bottom surfaces and side walls of the through holes 45D and 45E and then etching back to remove only the bottom surfaces of the through holes 45D and 45E. As a material of the first interlayer insulating film 41, an organic material such as a solder resist, an inorganic material such as a silicon oxide film (SiO2 film), or the like can be used. The solder resist can be formed using a coating apparatus, and the silicon oxide film can be formed using, for example, chemical vapor deposition (CVD), atomic layer deposition (ALD), or the like.

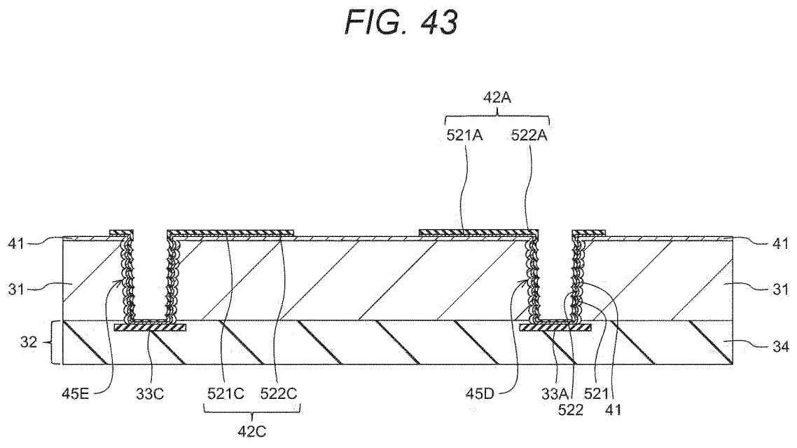

Next, as illustrated in FIG. 43, the first rewiring 42A connected to the internal electrode 33A and the first rewiring 42C connected to the internal electrode 33C are simultaneously formed. More specifically, the first rewiring 42A includes, for example, the seed metal 521A including a barrier metal using Ti and a Cu seed film, and the Cu wiring 522A. The first rewiring 42C includes, for example, the seed metal 521C including a barrier metal using Ti and a Cu seed film, and the Cu wiring 522C. The seed metals 521A and 521C can be formed by, for example, sputtering, and the Cu wirings 522A and 522C can be formed by, for example, electrolytic plating.

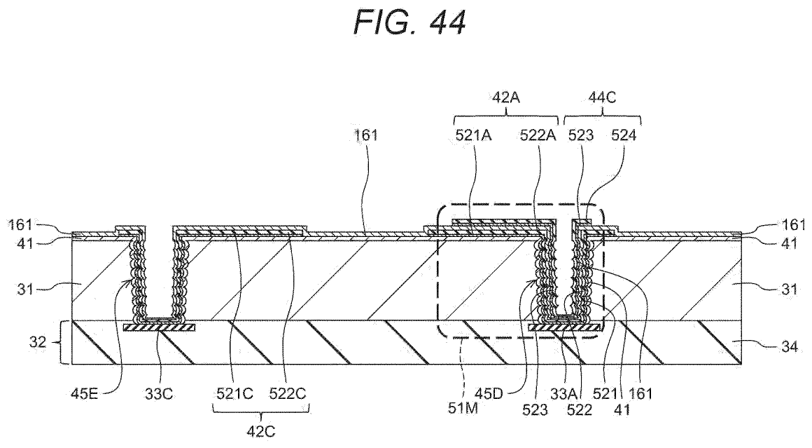

Next, as illustrated in FIG. 44, after the high dielectric film 161 is formed on the entire upper surface of the silicon substrate 31, the second rewiring 44C is formed above the first rewiring 42A. The high dielectric film 161 is formed on the upper surfaces of the first rewirings 42A and 42C in a region where the first rewirings 42A and 42C are formed, and is formed on the upper surface of the first interlayer insulating film 41 in a region where the first rewirings 42A and 42C are not formed. The second rewiring 44C includes, for example, a seed metal 523 including a barrier metal using Ti and a Cu seed film, and a Cu wiring 524. The method of forming the second rewiring 44C is similar to that of the first rewiring 42C. Thus, a capacitor 51M including the first rewiring 42A, the second rewiring 44C, and the high dielectric film 161 therebetween is formed.

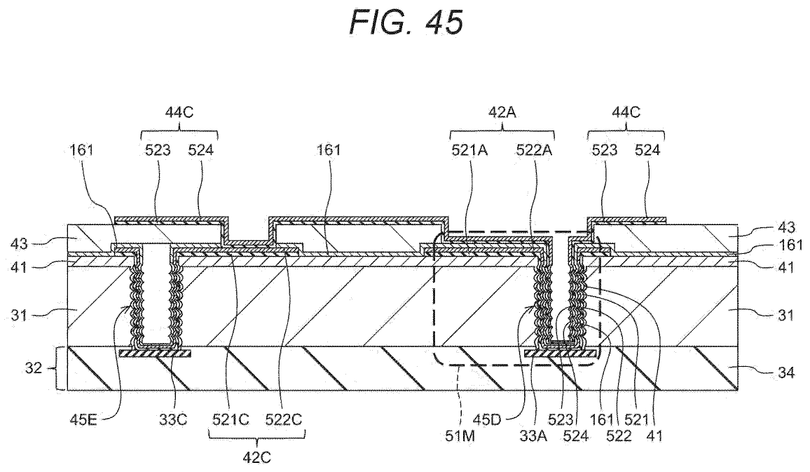

Next, as illustrated in FIG. 45, a second interlayer insulating film 43 is formed on the upper surface of the high dielectric film 161. As a material of the second interlayer insulating film 43, an organic material such as a solder resist, an inorganic material such as a silicon oxide film (SiO2 film), or the like can be used. This step is similar to the step in B of FIG. 4 in the first configuration example. Moreover, on the upper surface of the second interlayer insulating film 43, the seed metal 523 which is the second rewiring 44C other than the portion constituting the planar capacitor and the Cu wiring 524 are formed.

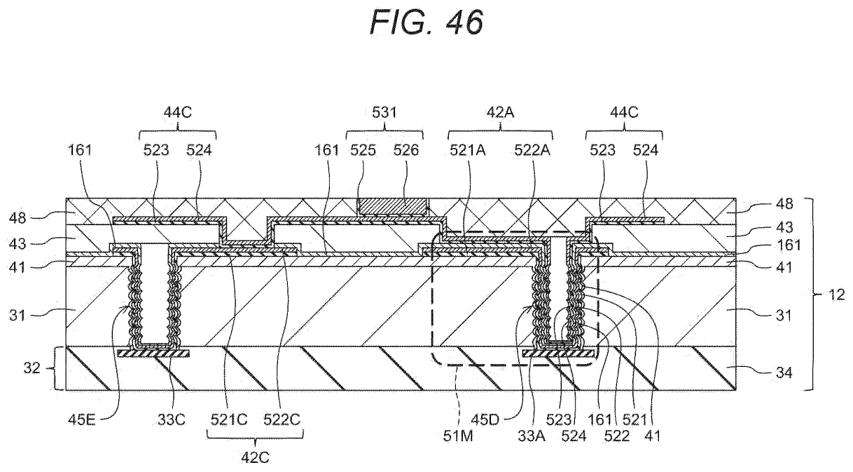

Next, as illustrated in FIG. 46, the pillar 531 which is an external connection terminal instead of the solder bumps 47 and a protective film 48 are formed, and the logic substrate 12 illustrated in FIG. 36 is completed. As a material of the protective film 48, for example, a photosensitive solder resist is used. The pillar 531 is formed, for example, by opening a partial region of the protection film 48 and stacking and increasing a metal material by electroless plating. The metal material of the pillar 531 is preferably Cu, but may be a metal material other than Cu, such as Ni or Au. Surfaces (upper surfaces) of the pillar 531 and the protective film 48 are planarized by CMP.

Through the above steps, the logic substrate 12 including the capacitor 51M according to the 11th configuration example illustrated in FIG. 36 is manufactured. The logic substrate 12 is bonded to the sensor substrate 11 at an appropriate timing to complete the solid-state imaging device 1.

According to the manufacturing method of the solid-state imaging device 1 including the capacitor 51M according to the 11th configuration example, it is possible to manufacture the capacitor 51 having increased electrostatic capacitance as compared with the case where the entire side surface of the through hole 45D is a smooth surface.

### 26. 12th Configuration Example of Capacitor

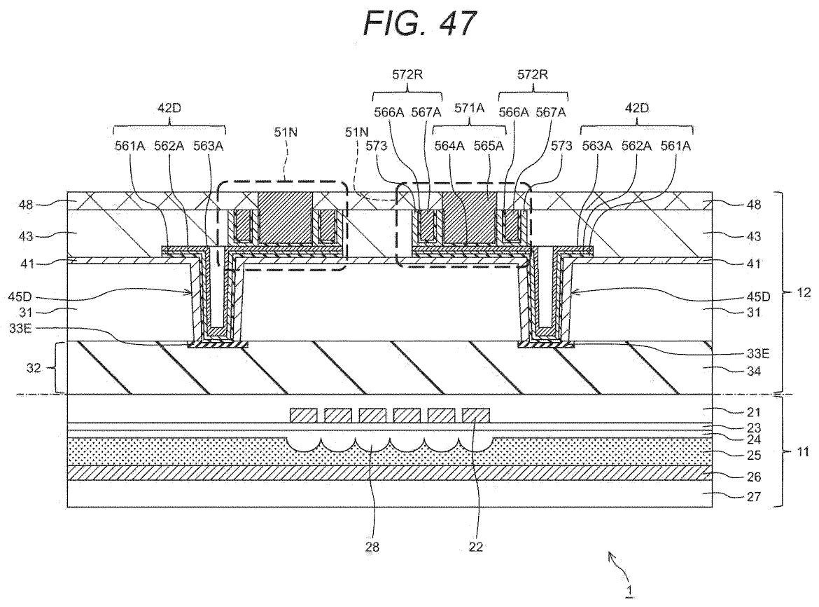

FIG. 47 is a cross-sectional view of a solid-state imaging device 1 according to a 12th embodiment.

A solid-state imaging device 1 illustrated in FIG. 47 is a chip size package type CMOS solid-state imaging device configured by stacking a sensor substrate 11 and a logic substrate 12. The sensor substrate 11 and the logic substrate 12 are joined by a surface indicated by a one-dot chain line. However, FIG. 47 illustrates that the sensor substrate 11 is disposed on the lower side and the logic substrate 12 is disposed on the upper side, and the vertical direction of the solid-state imaging device 1 is opposite to that in FIG. 1.

Since the configuration of the sensor substrate 11 is similar to that in FIG. 1, the description thereof will be omitted. The interlayer insulating film 25, the bonding resin 26, and the light-transmissive substrate 27 of the sensor substrate 11 may be omitted. The logic substrate 12 includes a capacitor 51N which is a capacitor 51 according to the 12th configuration example.

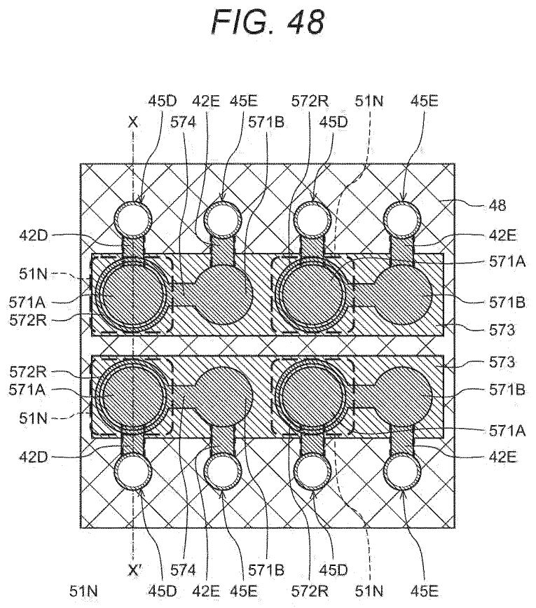

FIG. 48 is a plan view of the vicinity of capacitors 51N as viewed from the back surface side of the solid-state imaging device 1. FIG. 47 corresponds to a cross-sectional view taken along line X-X′ in FIG. 48. Note that, in the plan view of FIG. 48, a part of the second interlayer insulating film 43, the protective film 48, and the like is omitted in order to facilitate description of the structure of the capacitor 51N.

As illustrated in FIG. 47, the capacitor 51N according to the 12th configuration example is a ring capacitor constituted by a pillar 571A, a ring wiring 572R surrounding the periphery of the pillar, and a high dielectric film 573 therebetween. The capacitor 51N is an MIM capacitor, the pillar 571A corresponds to a first electrode of the MIM capacitor, the ring wiring 572R corresponds to a second electrode of the MIM capacitor, and the high dielectric film 573 corresponds to an insulating film of the MIM capacitor. The high dielectric film 573 is, for example, a film having a relative permittivity higher than that of the SiO2 film, and is a material having a relative permittivity εr larger than 3.8 (εr>3.8). As a specific material of the high dielectric film 573, a material similar to that of the high dielectric film 161 of each configuration example described above can be used, and for example, a tantalum oxide film, an aluminum oxide film, a hafnium oxide film, a titanium oxide film, a zirconium oxide film, a niobium oxide film, a silicon nitride film, or a stacked film of two or more thereof can be used. Note that the insulating film between the pillar 571A and the ring wiring 572R is preferably the high dielectric film 573, but of course, may be formed by an organic material such as a solder resist or an inorganic material such as a silicon oxide film (SiO2 film).

The pillar 571A is formed using, for example, a metal material such as copper (Cu), tungsten (W), aluminum (Al), gold (Au), silver (Ag), or nickel (Ni). In the present embodiment, when copper is used, the pillar 571A includes a seed metal 564A including a barrier metal for preventing diffusion of a metal material and a Cu seed film, and copper (Cu) 565A. As a material of the barrier metal, tantalum (Ta), titanium (Ti), tungsten (W), zirconium (Zr), ruthenium (Ru), a nitride film (for example, TaN or TiN) thereof, a carbonized film thereof, or the like can be used.

The pillar 571A is connected to a first rewiring 42D and is connected to an internal electrode 33E under the through hole 45D via the first rewiring 42D. The first rewiring 42D is formed on the back surface side (upper side in FIG. 47) of the silicon substrate 31 and the side surface (inner peripheral surface) of the through hole 45D, and is connected to the internal electrode 33E formed in the multilayer wiring layer 32 on the front surface side. The first rewiring 42D includes, for example, a barrier metal 561A, a Cu seed film 562A, and a Cu wiring 563A. As the material of the first rewiring 42D, other materials may be used similarly to the first rewiring 42A described above.

The ring wiring 572R can also use the metal material exemplified for the pillar 571A, and may be of the same material as or a different material from the pillar 571A. In the present embodiment, if the same material is used, the ring wiring 572R includes a seed metal 566A including a barrier metal and a Cu seed film, and copper (Cu) 567A.

As illustrated in FIG. 48, the ring wiring 572R is formed in a circular shape around the circular pillar 571A via the high dielectric film 573 having a predetermined film thickness (width). However, the planar shape of the ring wiring 572R conforms to the planar shape of the pillar 571A, and for example, in a case where the planar shape of the pillar 571A is a hexagonal polygonal shape, the planar shape of the ring wiring 572R is also a hexagonal polygonal shape. The ring wiring 572R is a wiring that annularly surrounds the pillar 571A, and is connected to another adjacent pillar 571B via a first rewiring 574. The pillar 571A is connected to the internal electrode 33E (FIG. 47) under the through hole 45D via the first rewiring 42D, and the pillar 571B is connected to the internal electrode 33E under the through hole 45E via the first rewiring 42E. The high dielectric film 573 is also formed on an outer periphery of the ring wiring 572R and the pillar 571B. With the structure in which the ring wiring 572R annularly surrounds the pillar 571A, it is possible to increase the facing area and increase the electrostatic capacitance.

When the pillar 571A is a first pillar 571A and another adjacent pillar 571B is a second pillar 571B, different potentials are supplied to the first pillar 571A and the second pillar 571B. For example, the power supply voltage is supplied to the first pillar 571A, and the ground (GND) is supplied to the second pillar 571B. Thus, the capacitor 51N that is a ring capacitor can have electrostatic capacitance. Note that, since the first pillar 571A and the second pillar 571B are external connection terminals, various signals such as pixel signals and control signals may be input and output.

As illustrated in the cross-sectional view of FIG. 47, a second interlayer insulating film 43 is formed on the upper surface of the first rewiring 42D and the upper surface of the first interlayer insulating film 41 other than the region where the capacitor 51N is formed. The second interlayer insulating film 43 is formed by, for example, a SiO2 film, a low-k film (low dielectric constant insulating film), a SiOC film, a SiN film, a SiON film, or the like. The second interlayer insulating film 43 is preferably constituted by an insulating film having a higher insulating property than the SiO2 film, for example, a SiN film, a SiON film, or the like. The outermost surface other than the pillars 571 (571A and 571B) are covered with the protective film 48. That is, only the pillars 571 which are external connection terminals are exposed, and the entire back surface of the solid-state imaging device 1 other than the pillars 571 is covered with the protective film 48. As a material of the protective film 48, for example, a solder resist which is an organic material is used.

As described above, the capacitor 51N according to the 12th configuration example includes, on the back surface side (second surface side) of the silicon substrate 31, the first pillar 571A as the first electrode, the ring wiring 572R as the second electrode surrounding the periphery of the first electrode, and the high dielectric film 573 as the insulating film therebetween. Since the configurations of the planar capacitor and the cylindrical capacitor depend on the position of the through hole and the position of the rewiring, there is a possibility that the electrostatic capacitance cannot be increased due to the relationship of the design layout, and there is a possibility that the effect of high-speed transmission cannot be sufficiently obtained. With the capacitor 51N having the ring capacitor configuration, the capacitor can be formed on any rewiring, and the degree of freedom in design can be increased. A capacitor having a necessary capacitance can be arranged without limiting the circuit design of the rewiring.

Since the high dielectric film 573 is formed only at the portion of the ring wiring 572R forming the capacitor 51N, warpage of the chip can also be suppressed. Since the portion other than the portion of the ring wiring 572R is covered with the second interlayer insulating film 43 in which metal is hardly diffused, the semiconductor element has high reliability.

The first pillar 571A as the first electrode is an external connection terminal, and the ring wiring 572R as the second electrode is connected to the second pillar 571B as an adjacent external connection terminal via the first rewiring 574. The first pillar 571A is connected to the internal electrode 33E of the multilayer wiring layer 32 via the first rewiring 42D. In a lower layer of the ring wiring 572R as the second electrode, the first rewiring 42D is formed via the high dielectric film 573, and the ring wiring 572R, the first rewiring 42D, and the high dielectric film 573 therebetween also constitute a capacitor in the vertical direction.

### 27. Manufacturing Method of Capacitor According to 12th Configuration Example

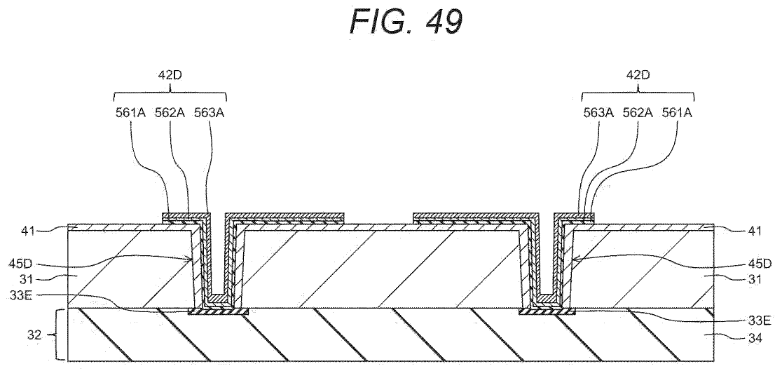

Next, a manufacturing method of the solid-state imaging device 1 including the capacitor 51M according to the 12th configuration example illustrated in FIGS. 47 and 48 will be described with reference to FIGS. 49 to 57.

As illustrated in FIG. 49, the steps until the through hole 45D is formed at the position connected to the internal electrode 33E of the multilayer wiring layer 32 and the first rewiring 42D connected to the internal electrode 33E is formed on the back surface side (upper side in FIG. 49) of the silicon substrate 31 and inside the through hole 45D are created as in the 11th configuration example described above. The first rewiring 42D includes, for example, a barrier metal 561A, a Cu seed film 562A, and a Cu wiring 563A. After the barrier metal 561A and the Cu seed film 562A are formed by, for example, sputtering, and the Cu wiring 563A is formed by, for example, electrolytic plating, the barrier metal 561A, the Cu seed film 562A, and the Cu wiring 563A in regions other than a desired region are removed by wet etching or the like, thereby bringing into a state illustrated in FIG. 49.

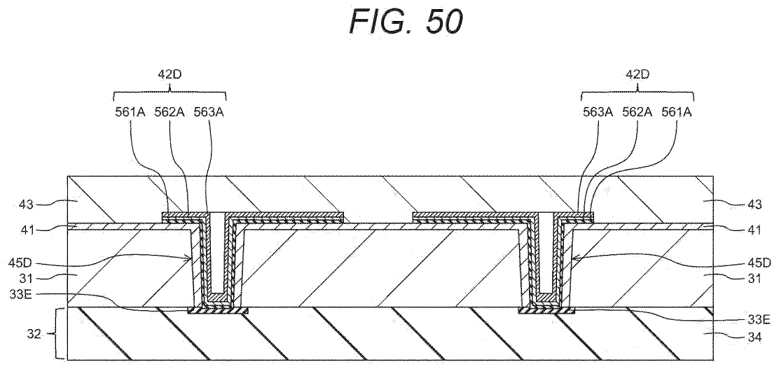

Next, as illustrated in FIG. 50, the second interlayer insulating film 43 as an isolation film is formed on the upper surfaces of the first rewiring 42D and the first interlayer insulating film 41. As a material of the second interlayer insulating film 43, an organic material such as a solder resist, an inorganic material such as a SiO2 film, a SiN film, or a SiON film, or the like can be used. A SiN film and a SiON film having higher insulation properties than the SiO2 film are preferable. The SiO2 film, the SiN film, the SiON film, and the like can be formed using, for example, CVD, ALD, or the like.

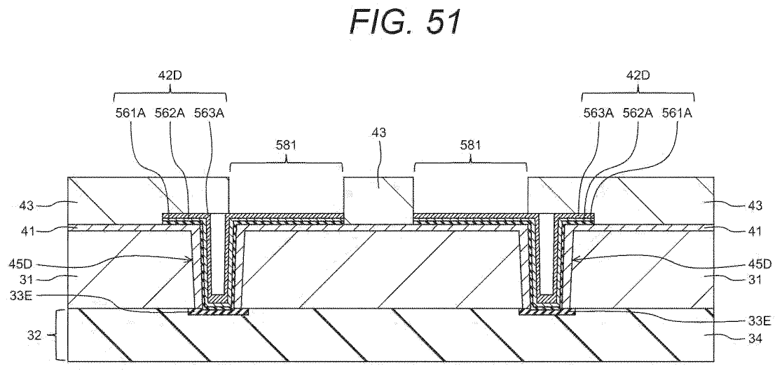

Next, as illustrated in FIG. 51, the second interlayer insulating film 43 in a region 581 where the capacitor 51N on the first rewiring 42D is formed is removed by dry etching until the first rewiring 42D is exposed.

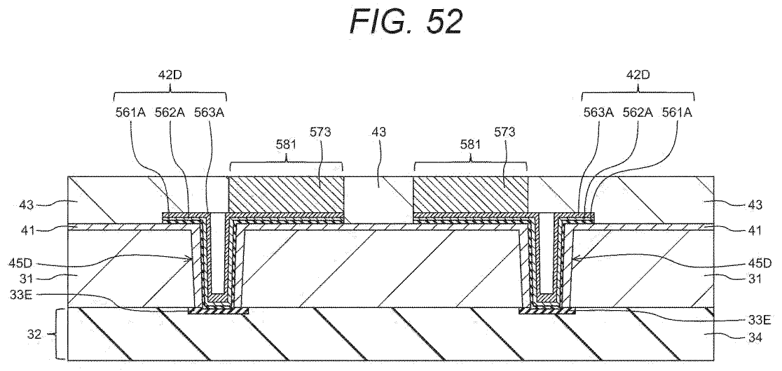

Next, as illustrated in FIG. 52, after the high dielectric film 573 is embedded in the formed region 581, a necessary amount is etched back. The high dielectric film 573 is assumed to be a film having a relative permittivity higher than that of the SiO2 film, and is, for example, a material having a relative permittivity εr larger than 3.8 (ϵr>3.8).

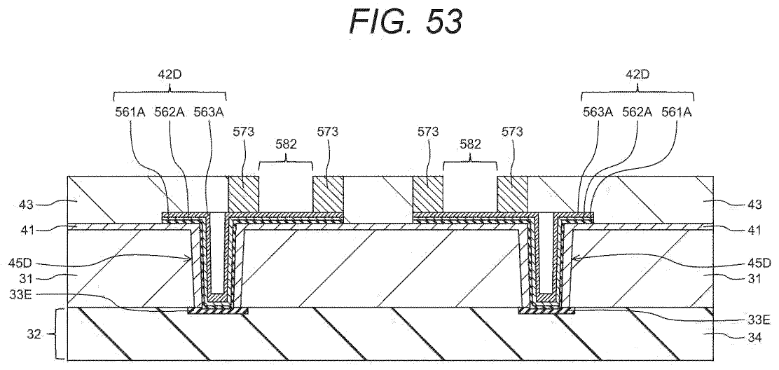

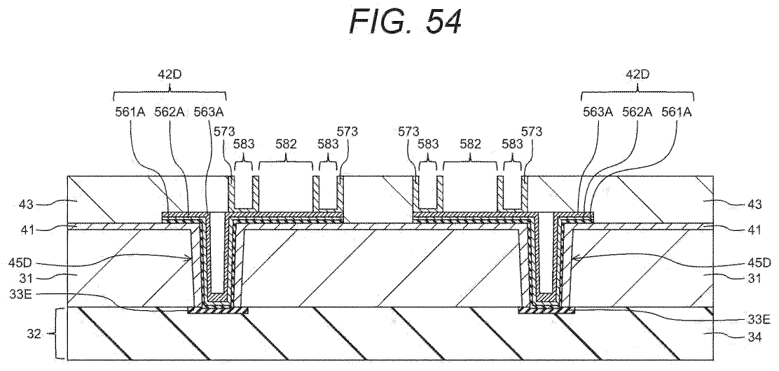

Next, as illustrated in FIG. 53, the high dielectric film 573 in a region 582 to be the pillar 571A is removed by dry etching, and then as illustrated in FIG. 54, the high dielectric film 573 in a region 583 to be the ring wiring 572R is removed by dry etching. The dry etching of the high dielectric film 573 is performed by masking a region other than the etching target region with a photoresist. In the region 582 to be the pillar 571A, the high dielectric film 573 is removed until the first rewiring 42D is exposed, but in the region 583 to be the ring wiring 572R, the high dielectric film 573 is removed so as to remain on the first rewiring 42D with a predetermined film thickness. The high dielectric film 573 remaining in the state of FIG. 54 finally becomes an insulating film between the pillar 571A of the capacitor 51N and the ring wiring 572R.

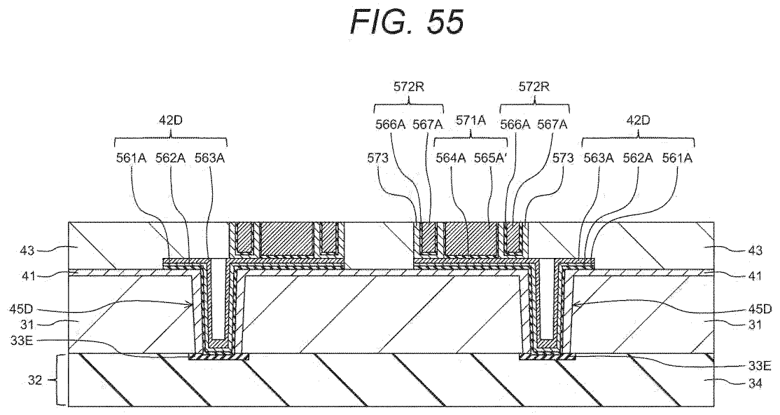

Next, as illustrated in FIG. 55, the pillar 571A including the seed metal 564A including a barrier metal and a Cu seed film and copper 565A′ is formed in the region 582, and the ring wiring 572R including the seed metal 566A including a barrier metal and a Cu seed film and the copper 567A is formed in the region 583. As a material of the barrier metal, for example, Ta, TaN, Ti, TiN, Ru, or the like can be used. The barrier metal and the Cu seed film are formed by sputtering, for example, and embedding of copper is performed by electrolytic plating. After embedding the copper, the unnecessary metal on the top surface is removed and planarized by CMP.

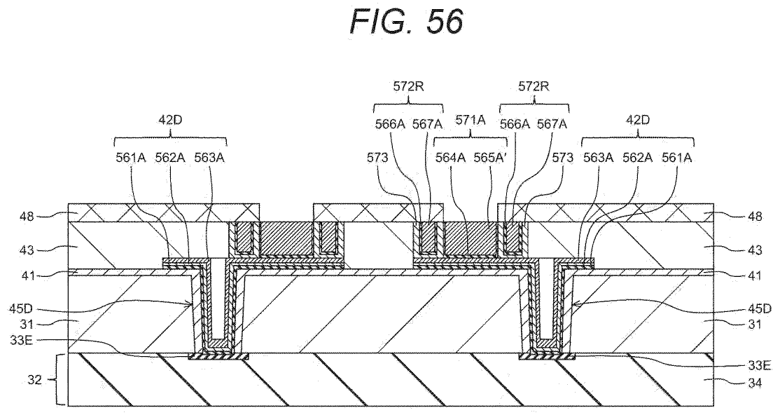

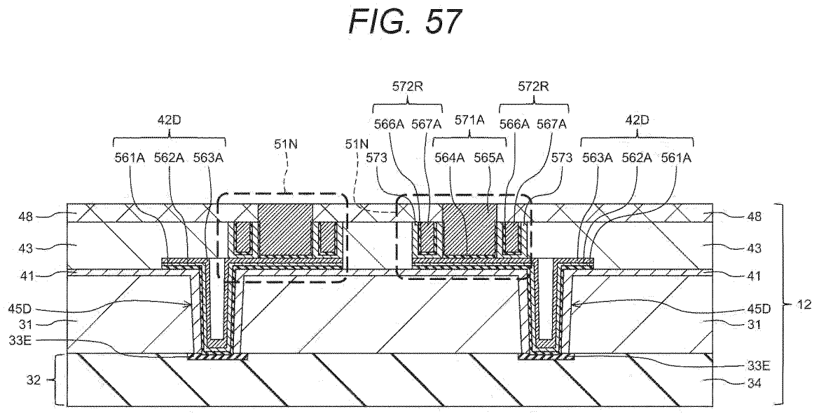

Next, as illustrated in FIG. 56, the protective film 48 is formed and masked in a region excluding an upper surface of the pillar 571A, and then as illustrated in FIG. 57, copper is further stacked on an upper portion of the copper 565A′ by electroless plating. Upper surfaces of the copper 565A and the protective film 48 formed by stacking are planarized by CMP. As a material of the protective film 48, for example, a photosensitive solder resist is used. The metal material of the pillar 531 is preferably Cu, but may be a metal material other than Cu, such as Ni or Au.

Through the above steps, the logic substrate 12 including the capacitors 51N according to the 12th configuration example illustrated in FIG. 47 is manufactured. The logic substrate 12 is bonded to the sensor substrate 11 at an appropriate timing to complete the solid-state imaging device 1.

According to the manufacturing method of the solid-state imaging device 1 including the capacitor 51N according to the 12th configuration example, the capacitor 51 having a necessary capacitance can be formed on any rewiring.

### 28. First Modification of 12th Configuration Example

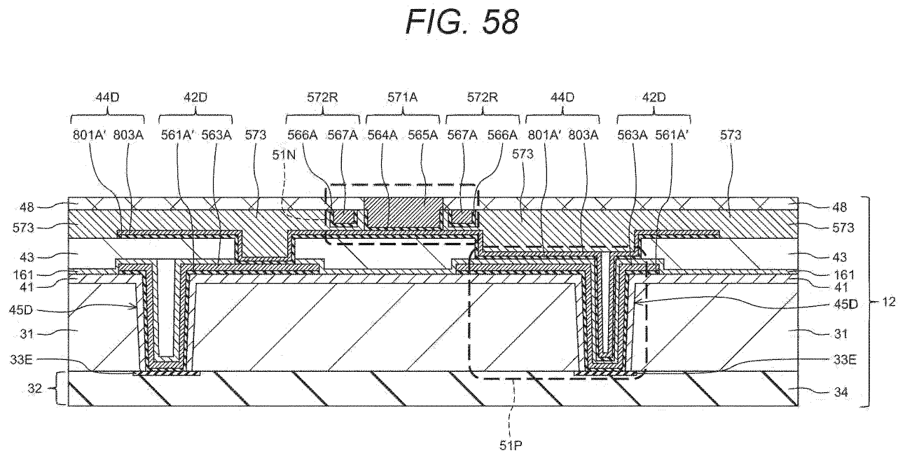

FIG. 58 is a cross-sectional view illustrating a detailed structure of a first modification of the capacitor 51N according to the 12th configuration example.

In FIG. 58, parts corresponding to those in the 12th configuration example illustrated in FIG. 47 are denoted by the same reference numerals, and description of the parts will be omitted as appropriate, and different parts will be described.

A first modification illustrated in FIG. 58 includes both a capacitor 51N having the ring capacitor configuration illustrated in FIG. 47 and a capacitor 51P including a combination of the planar capacitor and the cylindrical capacitor described in FIG. 19.

The capacitor 51P having the planar capacitor and the cylindrical capacitor includes a first rewiring 42D, a second rewiring 44D, and a high dielectric film 161 therebetween. The first rewiring 42D is illustrated by three layers of the barrier metal 561A, the Cu seed film 562A, and the Cu wiring 563A in FIG. 47 described above, but in FIG. 58, stacking of the barrier metal 561A and the Cu seed film 562A is represented by one layer of a seed metal 561A′. Similarly to the substrate structure of the third configuration example illustrated in FIG. 13, the high dielectric film 161 is formed on the entire back surface side of the silicon substrate 31.

Specifically, in the region where the first rewiring 42D is formed, the high dielectric film 161 is formed on the upper surface of the first rewiring 42D, and in the region where the first rewiring 42D is not formed, the high dielectric film is formed on the upper surface of the first interlayer insulating film 41. The second interlayer insulating film 43 is formed on the high dielectric film 161 except for the planar capacitor region of the capacitor 51P. The second rewiring 44D includes a seed metal 801A′ that is a stack of a barrier metal and a Cu seed film, and a Cu wiring 803A.

The second rewiring 44D is connected to the capacitor 51N having a ring capacitor configuration, and is connected to the first rewiring 42D formed in the through hole 45D different from the through hole 45D in which the cylindrical capacitor of the capacitor 51P is formed. The potential of the pillar 571A which is one capacitance electrode of the capacitor 51N and the potential of the second rewiring 44D which is one capacitance electrode of the capacitor 51P are the same potential, and the potential of the ring wiring 572R which is the other capacitance electrode of the capacitor 51N and the potential of the first rewiring 42D which is the other capacitance electrode of the capacitor 51P are the same potential. In the capacitor 51N having a ring capacitor configuration, the high dielectric film 573 is formed as an insulating film sandwiched between the pair of capacitance electrodes. The high dielectric film 573 is formed not only between the pillar 571A and the ring wiring 572R and between the second rewiring 44D and the ring wiring 572R, but also on the entire upper surface of the silicon substrate 31 including the upper side of the second rewiring 44D and the second interlayer insulating film 43. An upper surface of the high dielectric film 573 and an upper surface of the ring wiring 572R are covered with the protective film 48, and only the upper surface of the pillar 571A, which is the external connection terminal, is exposed.

As described above, the capacitor 51M according to the 12th configuration example can be used together with the capacitor 51P including the planar capacitor and the cylindrical capacitor. Thus, since the electrostatic capacitance can be further increased, higher speed transmission can be performed.

### 29. Manufacturing Method of Capacitor According to First Modification of 12th Configuration Example

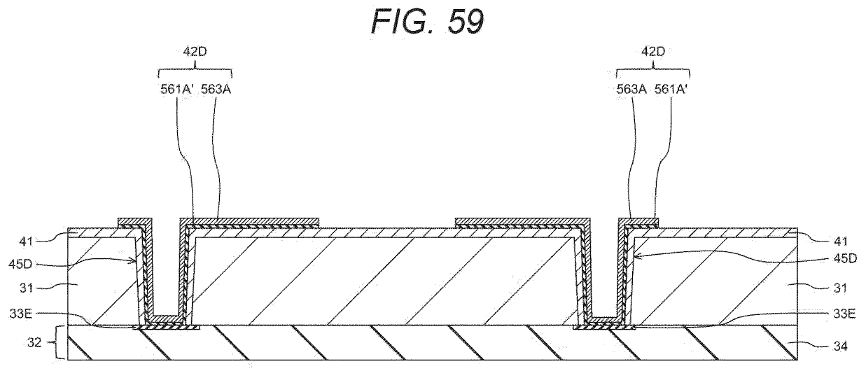

Next, a manufacturing method of the solid-state imaging device 1 including the capacitors 51N and 51P according to the first modification of the 12th configuration example illustrated in FIG. 58 will be described with reference to FIGS. 59 to 68.

As illustrated in FIG. 59, the steps until the through hole 45D is formed at the position connected to the internal electrode 33E of the multilayer wiring layer 32 and the first rewiring 42D connected to the internal electrode 33E is formed on the back surface side (upper side in FIG. 59) of the silicon substrate 31 and inside the through hole 45D are created as in the 11th configuration example described above. The first rewiring 42D includes, for example, the seed metal 561A′ and the Cu wiring 563A.

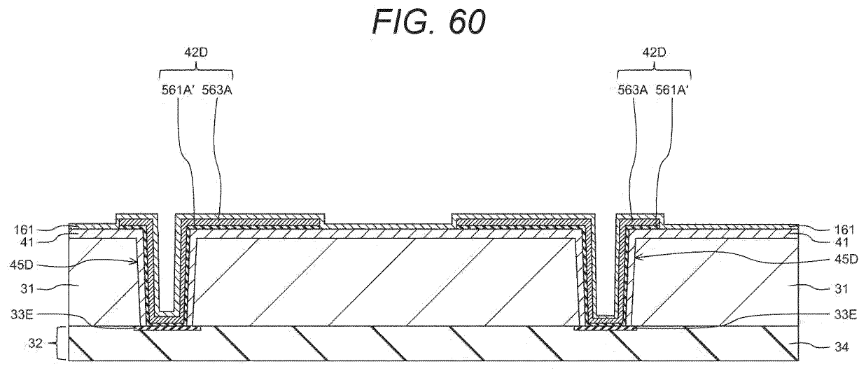

Next, as illustrated in FIG. 60, the high dielectric film 161 is formed on the entire upper surface of the silicon substrate 31. The high dielectric film 161 is formed on the upper surface of the first rewiring 42D in a region where the first rewiring 42D is formed, and is formed on the upper surface of the first interlayer insulating film 41 in a region where the first rewiring 42D is not formed.

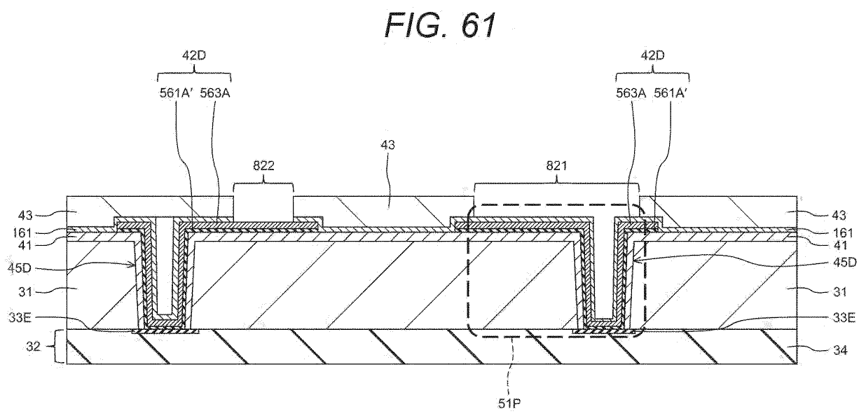

Next, as illustrated in FIG. 61, after the second interlayer insulating film 43 is formed on the upper surface of the high dielectric film 161, the second interlayer insulating film 43 in a region 821 to be the capacitor 51P and a region 822 where the second rewiring 44D and the first rewiring 42D are connected is removed. In the region 822 where the second rewiring 44D and the first rewiring 42D are connected, the high dielectric film 161 is also etched. As a material of the second interlayer insulating film 43, an organic material such as a solder resist, an inorganic material such as a silicon oxide film (SiO2 film), or the like can be used. In a case where the material of the second interlayer insulating film 43 is a solder resist having photosensitivity, the second interlayer insulating film 43 in the regions 821 and 822 can be removed by a lithography method.

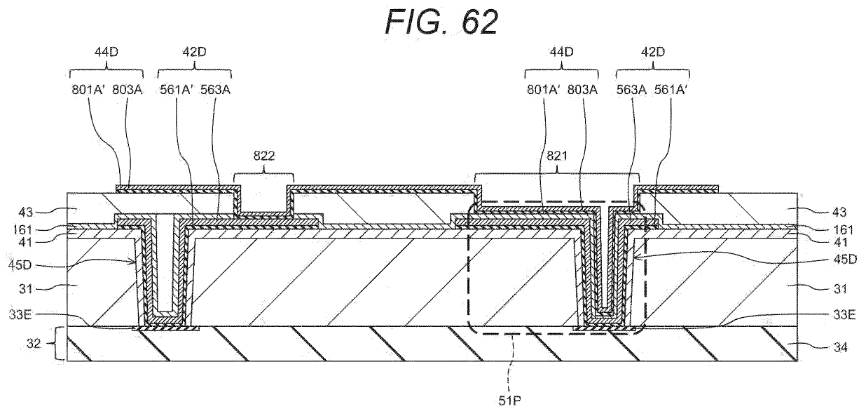

Next, as illustrated in FIG. 62, the second rewiring 44D is formed in a predetermined region on the second interlayer insulating film 43 including the region 821 and the region 822. The second rewiring 44D includes a seed metal 801A′ that is a stack of a barrier metal and a Cu seed film, and a Cu wiring 803A.

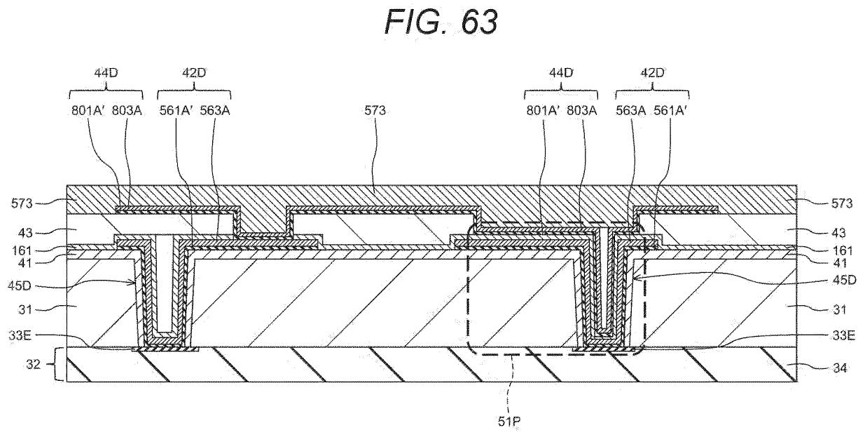

Next, as illustrated in FIG. 63, the high dielectric film 573 is formed on upper surfaces of the second rewiring 44D and the second interlayer insulating film 43. The high dielectric film 573 can be formed by using, for example, CVD, ALD, sputtering, or the like.

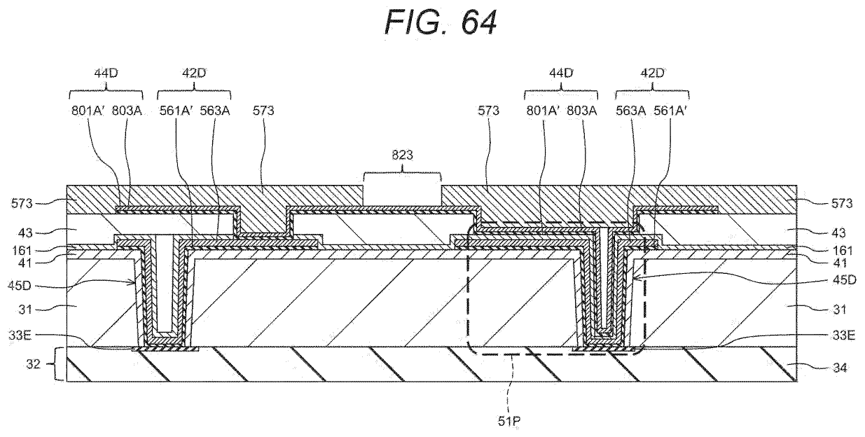

Next, as illustrated in FIG. 64, the second interlayer insulating film 43 in the region 823 where the capacitor 51N on the second rewiring 44D is formed is removed by dry etching until the second rewiring 44D is exposed.

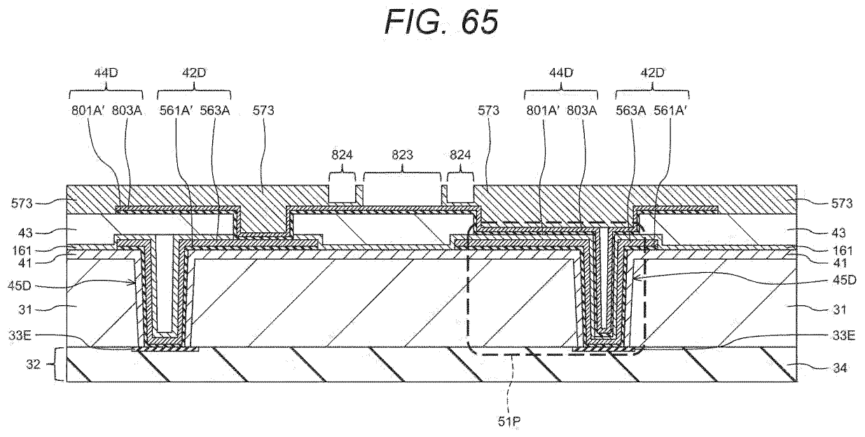

Next, as illustrated in FIG. 65, the high dielectric film 573 in the region 824 to be the ring wiring 572R around the region 823 to be the pillar 571A is removed by dry etching. In the region 823 to be the pillar 571A, the high dielectric film 573 is removed until the second rewiring 44D is exposed, but in the region 824 to be the ring wiring 572R, the high dielectric film 573 is removed so as to remain with a predetermined film thickness on the second rewiring 44D. The high dielectric film 573 remaining in the state of FIG. 65 finally becomes an insulating film between the pillar 571A of the capacitor 51N and the ring wiring 572R.

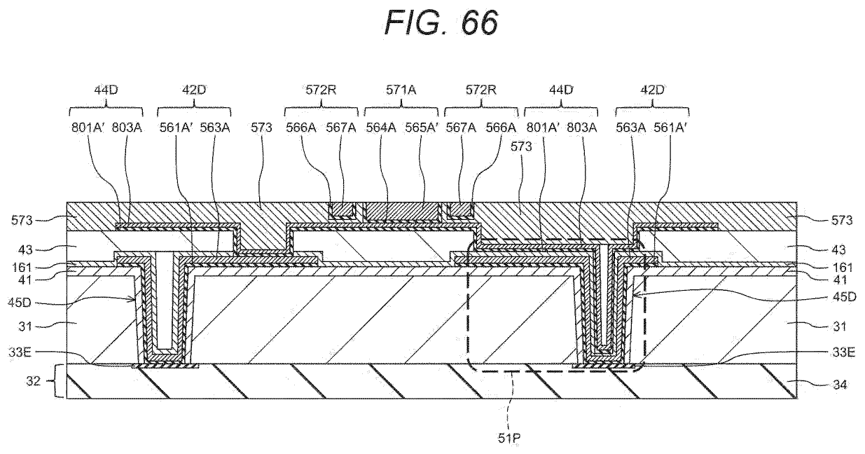

Next, as illustrated in FIG. 66, the pillar 571A including the seed metal 564A including a barrier metal and a Cu seed film and copper 565A′ is formed in the region 823, and the ring wiring 572R including the seed metal 566A including a barrier metal and a Cu seed film and the copper 567A is formed in the region 824. As a material of the barrier metal, for example, Ta, TaN, Ti, TiN, Ru, or the like can be used. The barrier metal and the Cu seed film are formed by sputtering, for example, and embedding of copper is performed by electrolytic plating. After embedding the copper, the unnecessary metal on the top surface is removed and planarized by CMP.

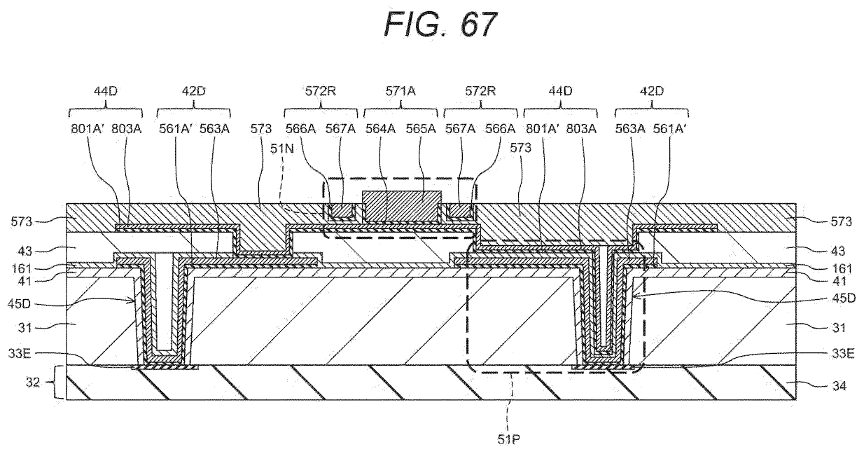

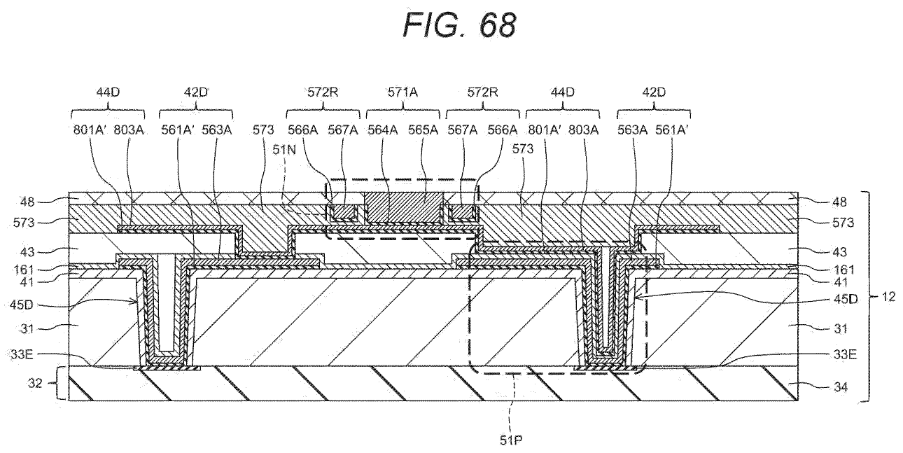

Next, as illustrated in FIG. 67, the pillar 571A is formed by the copper 565A obtained by further stacking copper on the upper portion of copper 565A′ by electroless plating, and the seed metal 564A. Thereafter, as illustrated in FIG. 68, after the protective film 48 is formed in a region other than the pillar 571A, the upper surfaces of the pillar 571A and the protective film 48 are planarized by CMP. In the manufacturing method of the 12th configuration example described with reference to FIGS. 56 and 57, the protective film 48 is formed first and then copper is stacked by electroless plating, but as illustrated in FIGS. 67 and 68, the protective film 48 may be formed after copper is stacked. Copper may be stacked by electroless plating or by a semi-additive method.

Through the above steps, the logic substrate 12 including the capacitors 51N and 51P according to the first modification of the 12th configuration example illustrated in FIG. 58 is manufactured. The logic substrate 12 is bonded to the sensor substrate 11 at an appropriate timing to complete the solid-state imaging device 1.

### 30. Second Modification of 12th Configuration Example

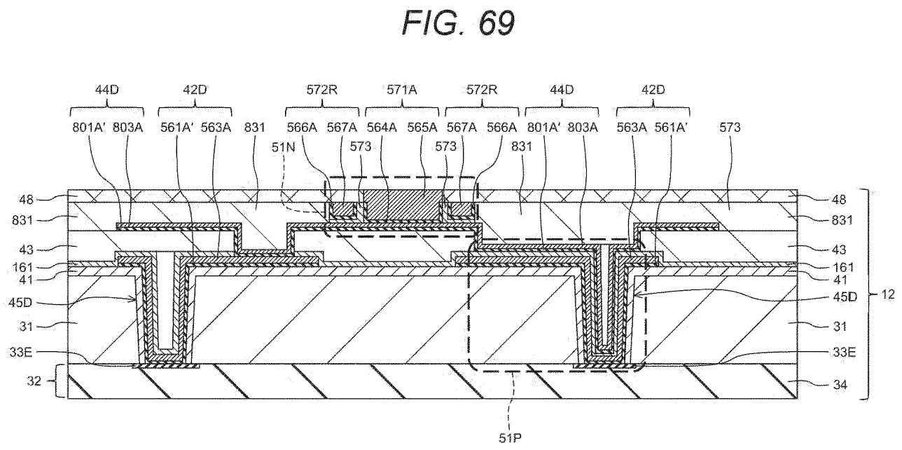

FIG. 69 is a cross-sectional view illustrating a detailed structure of a second modification of the capacitor 51N according to the 12th configuration example.

In FIG. 69, parts corresponding to those of the first modification illustrated in FIG. 58 are denoted by the same reference numerals, and description of the parts will be omitted as appropriate, and different parts will be described.

The second modification illustrated in FIG. 69 is common to the first modification illustrated in FIG. 58 in that both the capacitor 51N having the ring capacitor configuration illustrated in FIG. 47 and the capacitor 51P including the combination of the planar capacitor and the cylindrical capacitor described in FIG. 19 are provided. A difference from the first modification illustrated in FIG. 58 is that a part of the high dielectric film 573 is replaced with a third interlayer insulating film 831. That is, in the first modification illustrated in FIG. 58, the high dielectric film 573 is formed not only between the pillar 571A and the ring wiring 572R and between the second rewiring 44D and the ring wiring 572R, but also on the entire upper surface of the silicon substrate 31 including the upper side of the second rewiring 44D and the second interlayer insulating film 43. On the other hand, in the second modification of FIG. 69, the high dielectric film 573 is formed only between the pillar 571A and the ring wiring 572R and between the second rewiring 44D and the ring wiring 572R, which are regions constituting the capacitor 51N, and the third interlayer insulating film 831 is formed on the upper surfaces of the other second rewiring 44D and the second interlayer insulating film 43. As the third interlayer insulating film 831, the same type of material as that of the second interlayer insulating film 43 can be used. The third interlayer insulating film 831 and the second interlayer insulating film 43 may be formed by the same material or different materials.

As described above, the capacitor 51M according to the 12th configuration example can be used together with the capacitor 51P including the planar capacitor and the cylindrical capacitor. Thus, since the electrostatic capacitance can be further increased, higher speed transmission can be performed.

### 31. Manufacturing Method of Capacitor According to Second Modification of 12th Configuration Example

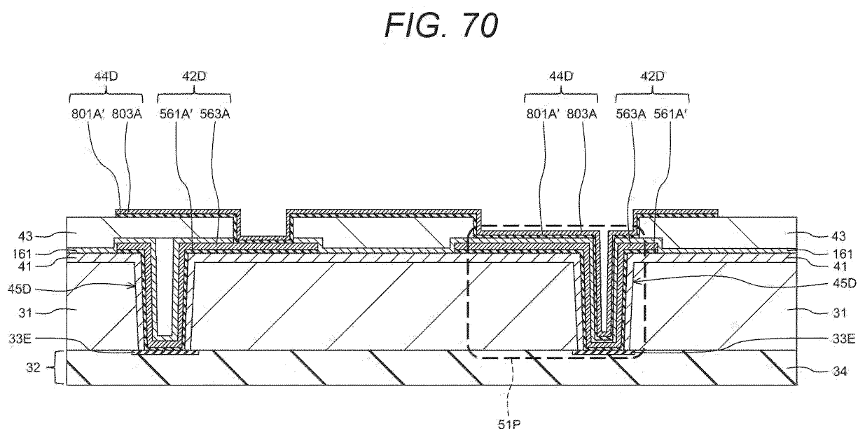

Next, a manufacturing method of the solid-state imaging device 1 including the capacitors 51N and 51P according to the second modification of the 12th configuration example illustrated in FIG. 69 will be described with reference to FIGS. 70 to 75.

The steps until the second rewiring 44D illustrated in FIG. 70 is formed are similar to those in the first modification described above. FIG. 70 is the same state as FIG. 62 of the first modification.

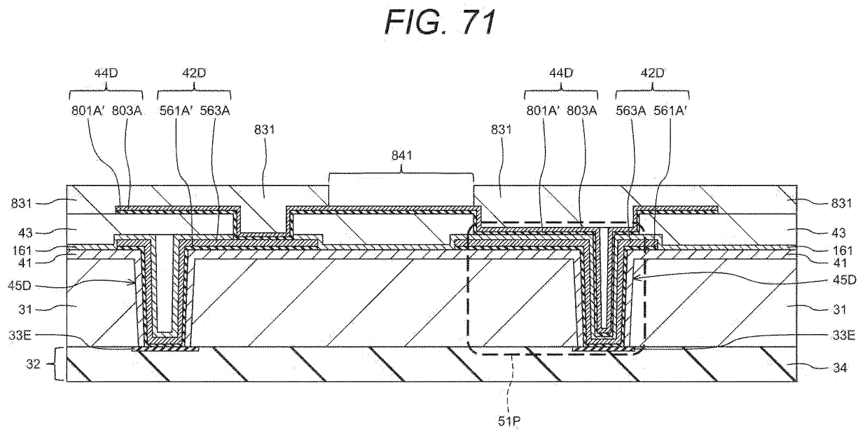

Next, as illustrated in FIG. 71, the third interlayer insulating film 831 is formed on the upper surfaces of the second rewiring 44D and the second interlayer insulating film 43. The third interlayer insulating film 831 can be a SiO2 film, a SiN film, a SiON film, or the like formed using, for example, CVD, ALD, or the like. Thereafter, the third interlayer insulating film 831 in the region 841 where the capacitor 51N on the second rewiring 44D is formed is removed by dry etching until the second rewiring 44D is exposed.

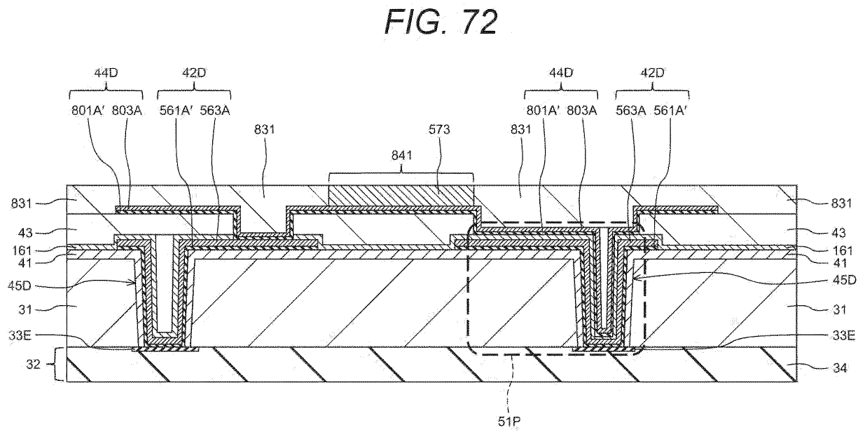

Next, as illustrated in FIG. 72, after the high dielectric film 573 is embedded in the opened region 841, the entire upper surface is planarized by CMP. The high dielectric film 573 can be, for example, a tantalum oxide film, an aluminum oxide film, a hafnium oxide film, a titanium oxide film, a zirconium oxide film, a niobium oxide film, a silicon nitride film, or the like, or may be a stacked film of two or more thereof. The high dielectric film 573 can be formed by using, for example, CVD, ALD, sputtering, or the like.

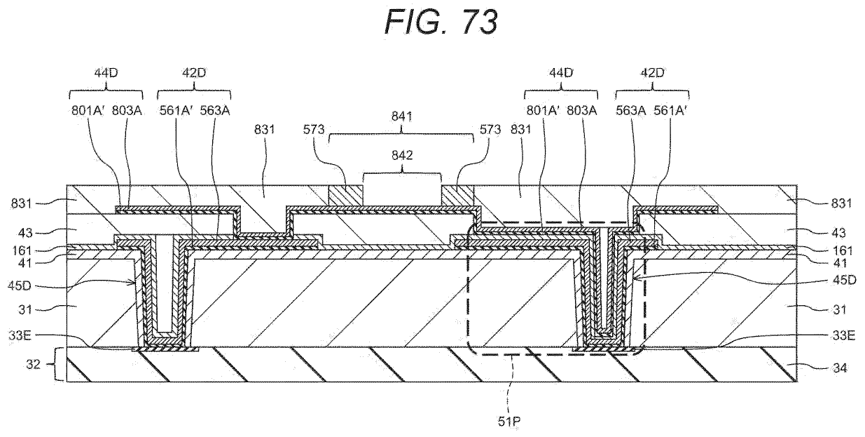

Next, as illustrated in FIG. 73, the high dielectric film 573 in the region 842 to be the pillar 571A is removed by dry etching until the second rewiring 44D is exposed.

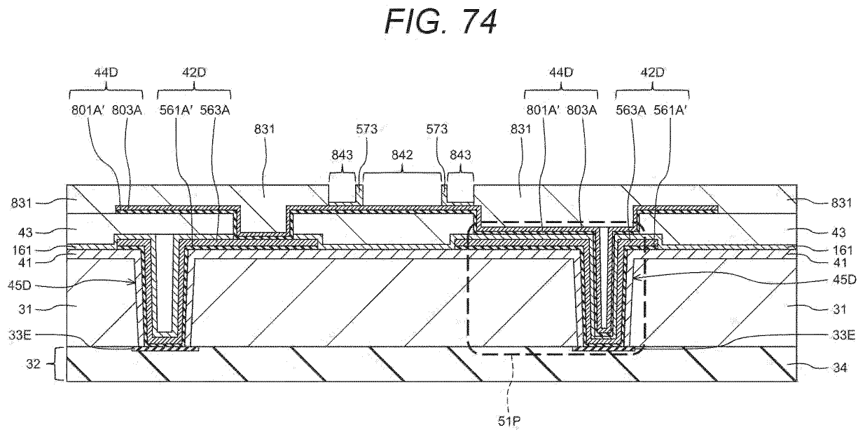

Next, as illustrated in FIG. 74, the high dielectric film 573 in the region 843 to be the ring wiring 572R around the region 842 to be the pillar 571A is removed by dry etching. In the region 842 to be the pillar 571A, the high dielectric film 573 is removed until the second rewiring 44D is exposed, but in the region 843 to be the ring wiring 572R, the high dielectric film 573 is removed so as to remain on the second rewiring 44D with a predetermined film thickness. The high dielectric film 573 remaining in the state of FIG. 74 finally becomes an insulating film between the pillar 571A of the capacitor 51N and the ring wiring 572R.

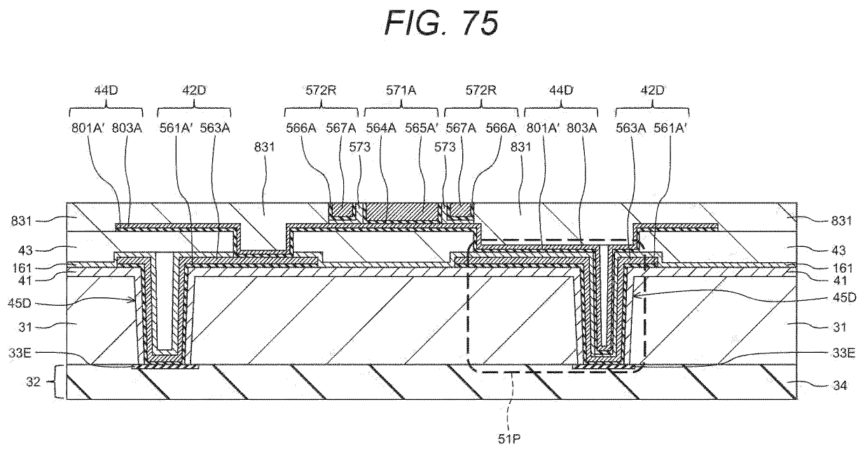

Next, as illustrated in FIG. 75, the pillar 571A including the seed metal 564A including a barrier metal and a Cu seed film and copper 565A′ is formed in the region 842, and the ring wiring 572R including the seed metal 566A including a barrier metal and a Cu seed film and the copper 567A is formed in the region 843. As a material of the barrier metal, for example, Ta, TaN, Ti, TiN, Ru, or the like can be used. The barrier metal and the Cu seed film are formed by sputtering, for example, and embedding of copper is performed by electrolytic plating. After embedding the copper, the unnecessary metal on the top surface is removed and planarized by CMP.

The steps of forming the pillar 571A by stacking copper on the copper 565A′ and forming the protective film 48 in the region other than the pillar 571A in FIG. 75 and subsequent drawings are similar to the steps described with reference to FIGS. 56 and 57 or the steps described with reference to FIGS. 67 and 68, and thus are omitted.

Through the above steps, the logic substrate 12 including the capacitors 51N and 51P according to the second modification of the 12th configuration example illustrated in FIG. 69 is manufactured. The logic substrate 12 is bonded to the sensor substrate 11 at an appropriate timing to complete the solid-state imaging device 1.

### 32. Third Modification of 12th Configuration Example

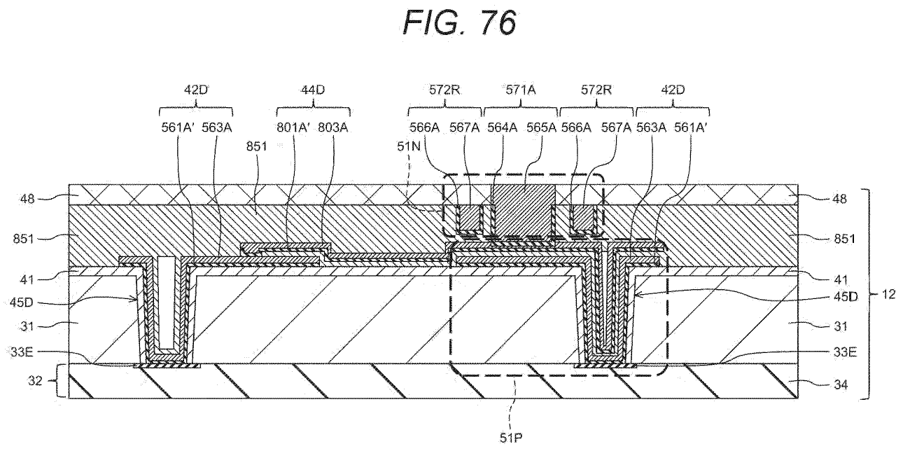

FIG. 76 is a cross-sectional view illustrating a detailed structure of a third modification of the capacitor 51N according to the 12th configuration example.

In FIG. 76, parts corresponding to those of the first modification illustrated in FIG. 58 are denoted by the same reference numerals, and description of the parts will be omitted as appropriate, and different parts will be described.

The third modification illustrated in FIG. 76 is common to the first modification illustrated in FIG. 58 in that both the capacitor 51N having the ring capacitor configuration illustrated in FIG. 47 and the capacitor 51P including the combination of the planar capacitor and the cylindrical capacitor described in FIG. 19 are provided. The difference from the first modification illustrated in FIG. 58 is that the high dielectric film 161, the second interlayer insulating film 43, and the high dielectric film 573 of the first modification are replaced with a high dielectric film 851. As the high dielectric film 851, the same type of material as the high dielectric film 161 or the high dielectric film 573 can be used. The high dielectric film 161 or the high dielectric film 573 may be formed by the same material or may be formed by a different material. Furthermore, in the first modification illustrated in FIG. 58, the capacitor 51N and the capacitor 51P are formed in different regions in plan view, but in the third modification of FIG. 76, they are formed in a region partially overlapping in plan view. This is because the capacitor 51N may be formed at any position on the second rewiring 44D, and only needs to be electrically connected to the second rewiring 44D.

As described above, the capacitor 51M according to the 12th configuration example can be used together with the capacitor 51P including the planar capacitor and the cylindrical capacitor. Thus, since the electrostatic capacitance can be further increased, higher speed transmission can be performed.

### 33. Manufacturing Method of Capacitor According to Third Modification of 12th Configuration Example

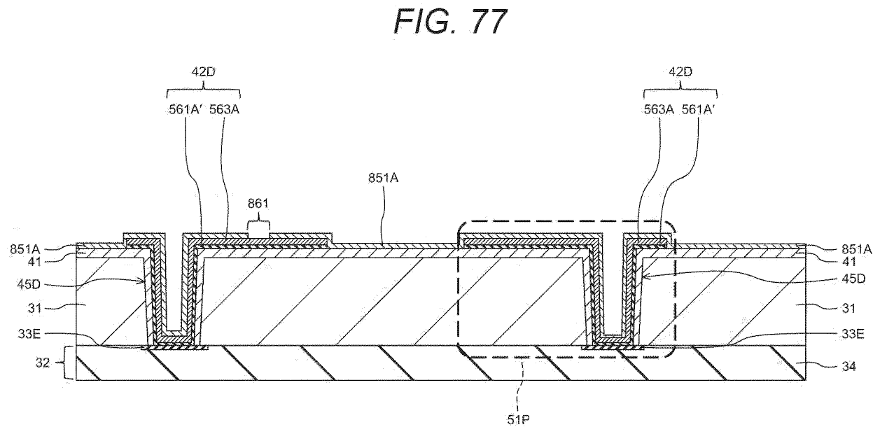

Next, a manufacturing method of the solid-state imaging device 1 including the capacitors 51N and 51P according to the third modification of the 12th configuration example illustrated in FIG. 76 will be described with reference to FIGS. 77 to 80.

As illustrated in FIG. 77, the steps until the first rewiring 42D connected to the internal electrode 33E is formed on the back surface side (upper side in FIG. 77) of the silicon substrate 31 and inside the through hole 45D are created as in the second modification described above. After the high dielectric film 851A is formed on the entire upper surface of the silicon substrate 31 including the upper surface of the first rewiring 42D, the high dielectric film 851A in a region 861 where the second rewiring 44D and the first rewiring 42D are connected is removed by etching. The high dielectric film 851A is formed to have a film thickness similar to that of the high dielectric film 161 of the second modification.

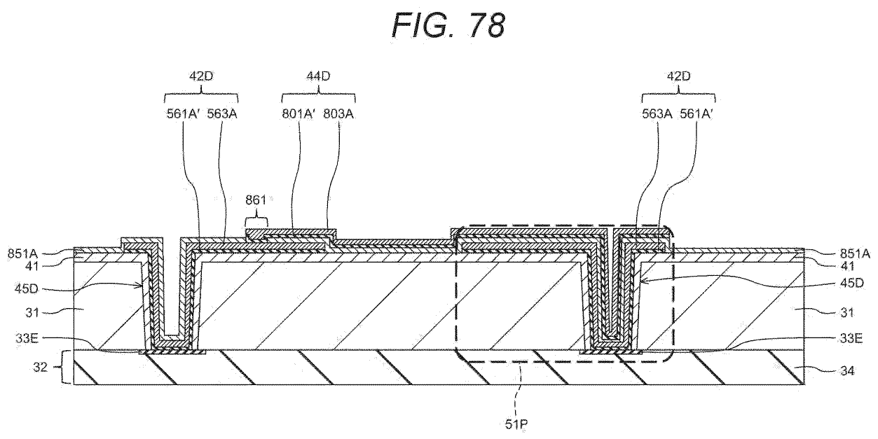

Next, as illustrated in FIG. 78, the second rewiring 44D is formed in the region 861 where the first rewiring 42D is exposed and a predetermined region on the high dielectric film 851A. The second rewiring 44D includes a seed metal 801A′ that is a stack of a barrier metal and a Cu seed film, and a Cu wiring 803A.

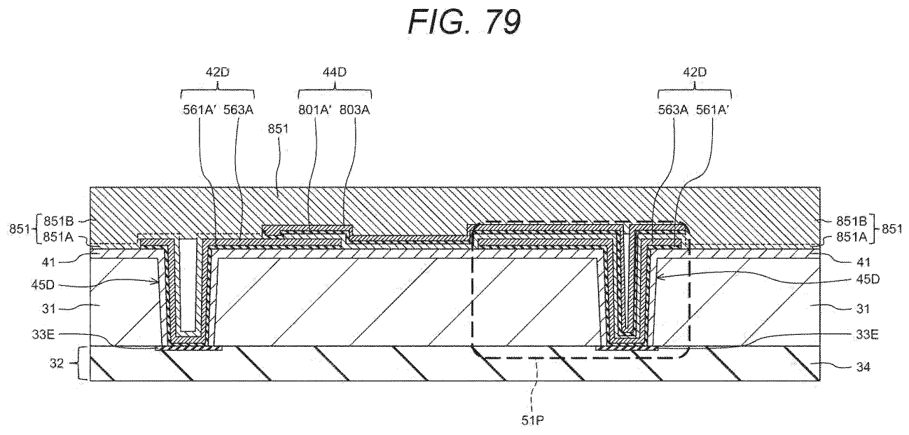

Next, as illustrated in FIG. 79, a high dielectric film 851B is formed on the upper surfaces of the second rewiring 44D and the high dielectric film 851A by CVD, ALD, sputtering, or the like to have a film thickness similar to that of the high dielectric film 573 of the first modification. The high dielectric film 851B having this film thickness and the high dielectric film 851A constituting the insulating film of the capacitor 51P constitute the high dielectric film 851 of FIG. 76.

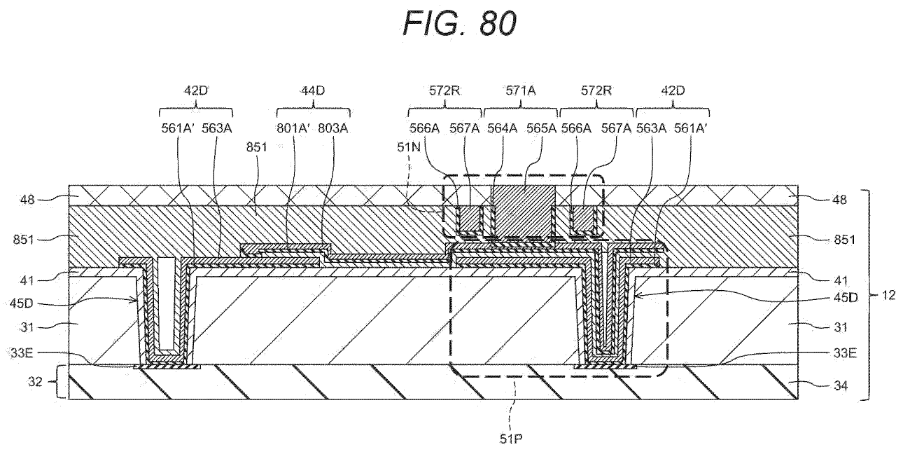

Thereafter, as illustrated in FIG. 80, the capacitor 51N having a ring capacitor configuration and the protective film 48 are formed. Since the method of forming the capacitor 51N and the protective film 48 is similar to that of the above-described 12th configuration example and the first and second modifications, the description thereof is omitted.

### <Comparison of First to Third Modifications

The first modification of FIG. 58, the second modification of FIG. 69, and the third modification of FIG. 76 are common in that both the capacitor 51N having the ring capacitor configuration illustrated in FIG. 47 and the capacitor 51P including the combination of the planar capacitor and the cylindrical capacitor described in FIG. 19 are provided.

On the other hand, the difference is that the thick film between the first interlayer insulating film 41 and the protective film 48 on the back surface of the silicon substrate 31 includes two layers of the second interlayer insulating film 43 and the high dielectric film 573 in the first modification of FIG. 58, includes two layers of the second interlayer insulating film 43 and the third interlayer insulating film 831 in the second modification of FIG. 69, and includes the high dielectric film 851 in the third modification of FIG. 76.

In the first modification, since it is not necessary to limit the high dielectric film 573 to a partial region in the region of the capacitor 51N having the ring capacitor configuration and the other regions in plan view, the manufacturing process is simplified, and the manufacturing cost can be suppressed.

On the other hand, in the second modification, it is necessary to separately form the high dielectric film 573 and the third interlayer insulating film 831 in the region of the capacitor 51N having the ring capacitor configuration and the other regions in plan view, but by minimizing the region of the high dielectric film 573, warpage of the entire chip due to the high dielectric film can be suppressed, and reliability can be improved.

The third modification is a modification of the arrangement of the capacitor 51N having the ring capacitor configuration. It is an example in which the high dielectric film 851 is not divided into the region of the capacitor 51N and the other regions as in the first modification, but they may be divided as in the second modification.

### 34. 13th Configuration Example of Capacitor

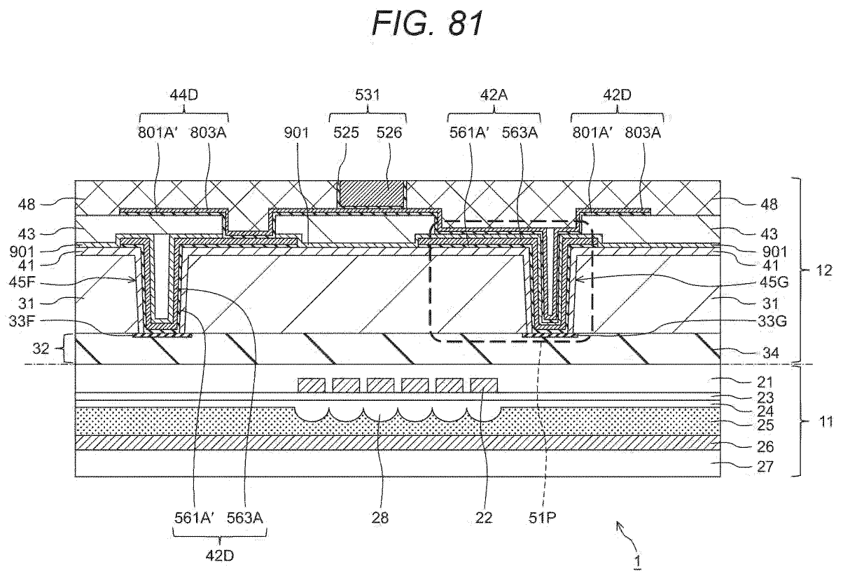

FIG. 81 is a cross-sectional view of a solid-state imaging device 1 according to a 13th embodiment.

A solid-state imaging device 1 illustrated in FIG. 81 is a chip size package type CMOS solid-state imaging device configured by stacking a sensor substrate 11 and a logic substrate 12. The sensor substrate 11 and the logic substrate 12 are joined by a surface indicated by a one-dot chain line. However, FIG. 81 illustrates that the sensor substrate 11 is disposed on the lower side and the logic substrate 12 is disposed on the upper side, and the vertical direction of the solid-state imaging device 1 is opposite to that in FIG. 1. A pillar (land) 531, which is an external connection terminal instead of the solder bumps 47, is formed on the back surface side of the solid-state imaging device 1 on the upper side in FIG. 81.

Since the configuration of the sensor substrate 11 is similar to that in FIG. 1, the description thereof will be omitted. The interlayer insulating film 25, the bonding resin 26, and the light-transmissive substrate 27 of the sensor substrate 11 may be omitted. The logic substrate 12 includes a capacitor 51P including the combination of the planar capacitor and the cylindrical capacitor illustrated in FIG. 58.

The capacitor 51P includes a first rewiring 42D, a second rewiring 44D, and a high dielectric film 901 therebetween. In FIG. 81, the first rewiring 42D includes a seed metal 561A′ that is a stack of a barrier metal 562A and a Cu seed film 561A, and a Cu wiring 563A. The first rewiring 42D is formed on the back surface side (upper side in FIG. 81) of the silicon substrate 31 and a side surface (inner peripheral surface) and a bottom portion of the through hole 45G on the right side in FIG. 81, and is connected to the internal electrode 33G under the through hole 45G. The high dielectric film 901 is, for example, a high dielectric film having a relative permittivity higher than that of a SiO2 film, but may be a SiO2 film. The material of the high dielectric film 901 is similar to that of the high dielectric films 161 and 573 of the 12th configuration example illustrated in FIG. 58 described above. The high dielectric film 901 is formed on the entire back surface side of the silicon substrate 31, similarly to the high dielectric film 161 of the 12th configuration example. That is, the high dielectric film 901 is formed on the upper surface of the first rewiring 42D in the region where the first rewiring 42D is formed, and is formed on the upper surface of the first interlayer insulating film 41 in the region where the first rewiring 42D is not formed. The second interlayer insulating film 43 is formed on the high dielectric film 901 except for the planar capacitor region of the capacitor 51P. The second rewiring 44D includes a seed metal 801A′ that is a stack of a barrier metal and a Cu seed film, and a Cu wiring 803A.

The pillar 531 is formed and exposed in a partial region of the upper surface of the second rewiring 44D, and the other region is covered with the protective film 48. The pillar 531 includes a seed metal 525 including a barrier metal for preventing diffusion of a metal material and a Cu seed film, and copper (Cu) 526 embedded inside the seed metal. As a material of the barrier metal, tantalum (Ta), titanium (Ti), tungsten (W), zirconium (Zr), ruthenium (Ru), a nitride film (for example, TaN or TiN) thereof, a carbonized film thereof, or the like can be used. In place of the copper (Cu) 526, a metal material such as tungsten (W), aluminum (Al), gold (Au), silver (Ag), or nickel (Ni) may be used for the formation.

The first rewiring 42D formed on the side surface and the bottom portion of the through hole 45F on the left side in FIG. 81 is connected to the internal electrode 33F under the through hole 45F. The first rewiring 42D connects the front surface side and the back surface side of the silicon substrate 31, and is also connected to the pillar 531 via the second rewiring 44D to electrically connect the pillar 531 and the internal electrode 33F.

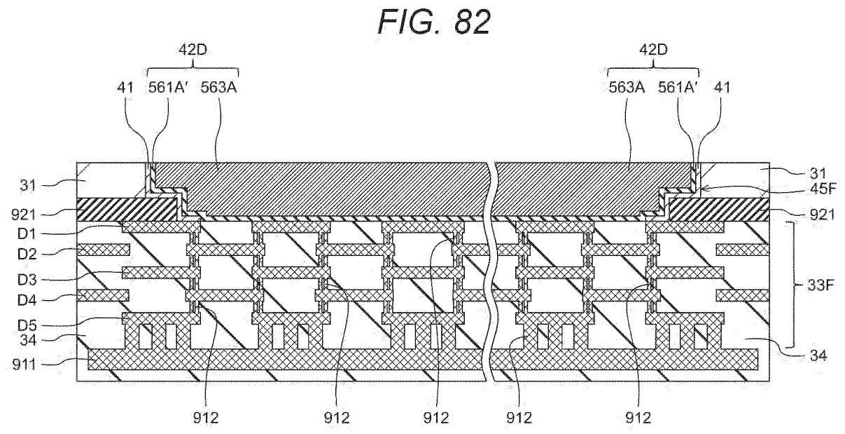

The internal electrode 33F under the through hole 45F on the left side in FIG. 81 has, for example, a multilayer wiring structure illustrated in FIG. 82.

FIG. 82 is a cross-sectional view illustrating a first configuration example of the internal electrode 33F in FIG. 81, and is an enlarged cross-sectional view of the vicinity of the internal electrode 33F.

The multilayer wiring layer 32 in FIG. 81 includes a plurality of metal wiring layers 911 and an interlayer insulating film 34 therebetween. The internal electrode 33F has a multilayer wiring structure in which lattice pattern wirings D1 to D5 are stacked in a substrate depth direction (vertical direction in FIG. 82) between the metal wiring layer 911 closest to the silicon substrate 31 in the multilayer wiring layer 32 and the silicon substrate 31, and the upper and lower portions are connected by a contact wiring 912.

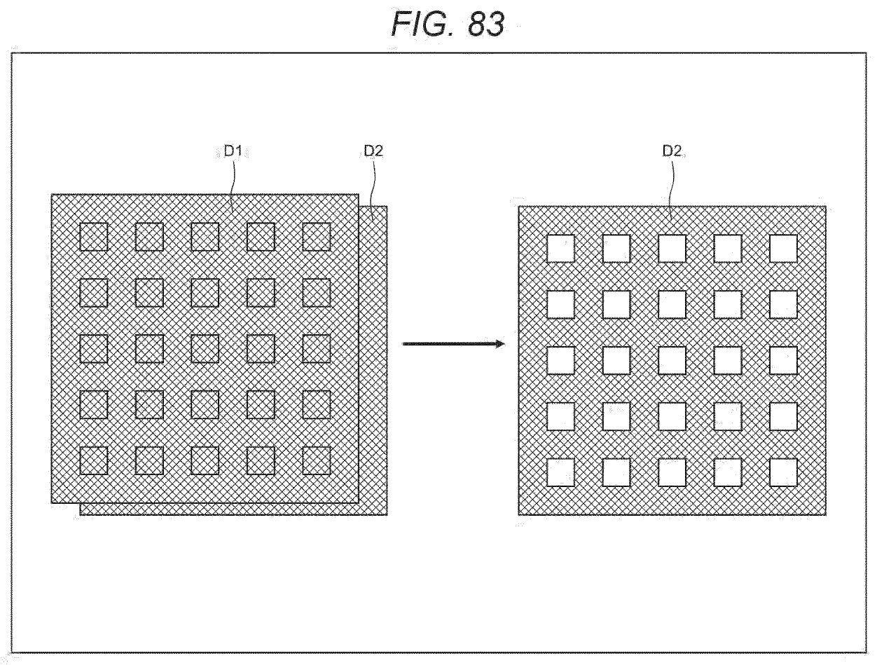

As illustrated in the plan view of FIG. 83, each of the lattice pattern wirings D1 to D5 has a lattice-like pattern shape, and is arranged so that the positions of openings are staggered (alternately shifted) between the adjacent lattice pattern wirings Dx (any one of x=1 to 5). FIG. 83 is a diagram illustrating a relationship between the lattice pattern wiring D1 and the lattice pattern wiring D2 among the lattice pattern wirings D1 to D5. The positions of the openings of the lattice pattern wirings D3 and D5 are arranged at the same position as the lattice pattern wiring D1, and the positions of the openings of the lattice pattern wiring D4 are arranged at the same positions as those of the lattice pattern wiring D2.

In FIG. 82, among the lattice pattern wirings D1 to D5, an upper surface (first surface) of the lattice pattern wiring D1 closest to the silicon substrate 31 is connected to the first rewiring 42D (the seed metal 561A′ and the Cu wiring 563A) formed at the bottom portion of the through hole 45F, thereby electrically connecting the internal electrode 33F and the first rewiring 42D.

The first interlayer insulating film 41 that electrically isolates the silicon substrate 31 from the first rewiring 42D is formed on the side surface of the through hole 45F. A shallow Trench Isolation (STI) 921 is formed between the silicon substrate 31 and the internal electrode 33F around the planar region connected to the first rewiring 42D, and electrically isolates them.

As described above, in the solid-state imaging device 1 according to the 13th embodiment, the internal electrode 33F has the multilayer wiring structure in which the plurality of lattice pattern wirings Dx is arranged so that the positions of the openings are staggered. Thus, the internal electrode 33F can be connected to the first rewiring 42D with low resistance.

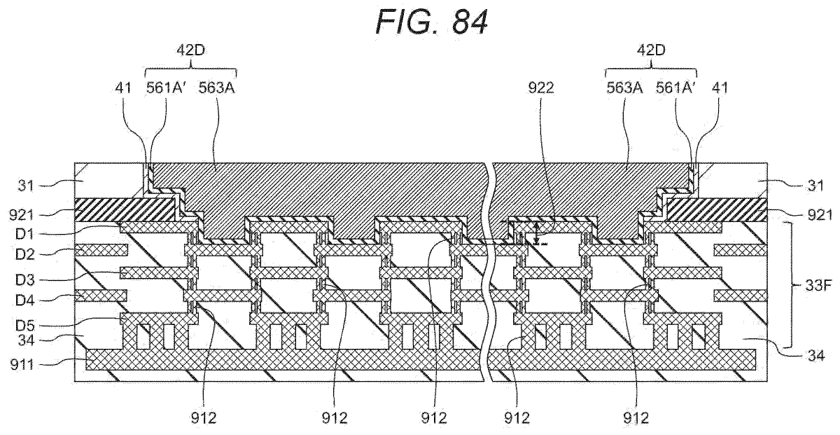

FIG. 84 is a cross-sectional view illustrating a second configuration example of the internal electrode 33F in FIG. 81, and is an enlarged cross-sectional view of the vicinity of the internal electrode 33F.

In the internal electrode 33F of the first configuration example illustrated in FIG. 82, the bottom portion of the first rewiring 42D (the seed metal 561A′ and the Cu wiring 563A) is formed as a plane, and the first rewiring 42D is connected only to the upper surface of the lattice pattern wiring D1 closest to the silicon substrate 31.

On the other hand, in the second configuration example of FIG. 84, the first rewiring 42D is embedded up to an upper surface of the lattice pattern wiring D2 through the opening of the lattice pattern wiring D1, whereby the bottom portion of the first rewiring 42D is formed in an uneven shape. The depth 922 of the protrusion as compared with the case where the bottom portion of the first rewiring 42D of the first configuration example has a planar shape is formed to be, for example, about 200 nm. The first rewiring 42D is connected at the upper surface of the lattice pattern wiring D1, the side surface of the opening, and the upper surface of the lattice pattern wiring D2, and can increase the connection area between the internal electrode 33F and the first rewiring 42D.

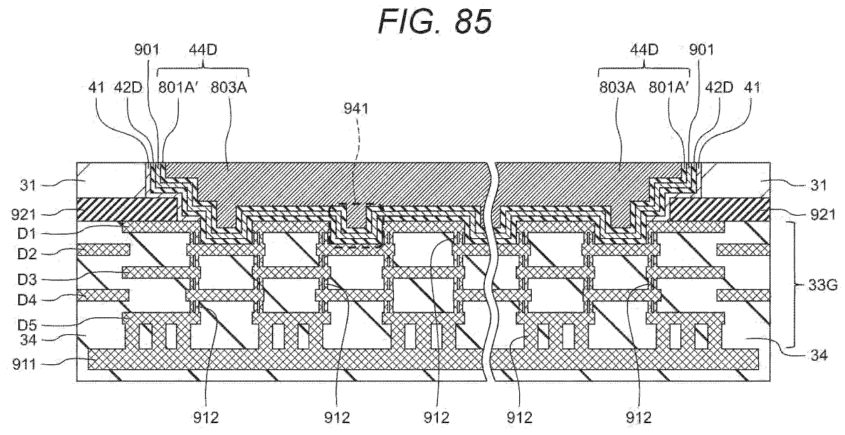

FIG. 85 is a cross-sectional view illustrating a first configuration example of the internal electrode 33G on the right side of FIG. 81 to which the first rewiring 42D of the capacitor 51P including the cylindrical capacitor is connected, and is an enlarged cross-sectional view of the vicinity of the internal electrode 33G.

As in the second configuration example of the internal electrode 33F illustrated in FIG. 84, the internal electrode 33G of the first configuration example illustrated in FIG. 85 has a configuration in which the lattice pattern wirings D1 to D5 and the lattice pattern wiring Dx vertically adjacent to each other are connected by the contact wiring 912, and is connected to the metal wiring layer 911 in the multilayer wiring layer 32.

The first rewiring 42D includes the seed metal 561A′ and the Cu wiring 563A as illustrated in FIG. 81, but is represented by one layer in FIG. 85. The high dielectric film 901 is formed on the upper surface of the first rewiring 42D, and the second rewiring 44D including the seed metal 801A′ and the Cu wiring 803A is formed on the upper surface of the high dielectric film 901.

The second rewiring 44D, the high dielectric film 901, and the first rewiring 42D are embedded up to the upper surface of the lattice pattern wiring D2 through the opening of the lattice pattern wiring D1, thereby being formed in an uneven shape. The second rewiring 44D, the high dielectric film 901, and the first rewiring 42D dug below the upper surface of the lattice pattern wiring D1 are hereinafter referred to as cylinder capacitor protrusions 941 of the capacitors 51P. The first rewiring 42D is connected to the upper surface of the lattice pattern wiring D1, the side surface of the opening, and the upper surface of the lattice pattern wiring D2.

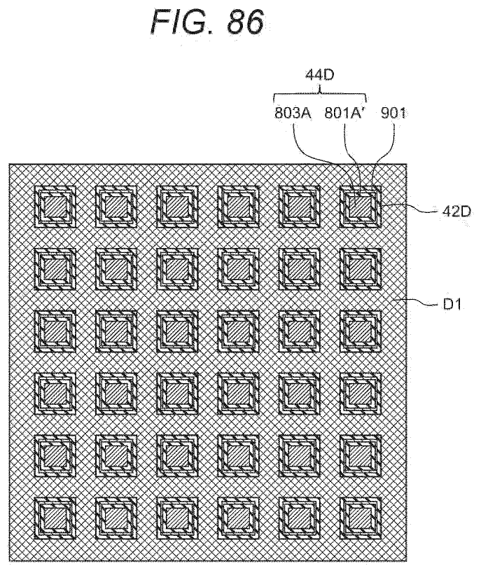

FIG. 86 illustrates a plan view as viewed in a plane passing through the lattice pattern wiring D1 in the cross-sectional view of FIG. 85.

The internal electrode 33G of the first configuration example also has the multilayer wiring structure, so that the connection area with the first rewiring 42D of the capacitor 51P including the combination of the planar capacitor and the cylindrical capacitor can be increased, and the low resistance can be achieved.

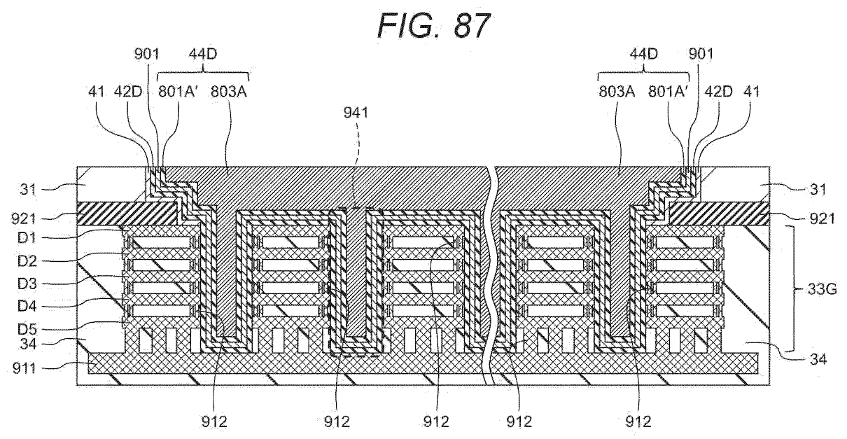

FIG. 87 is a cross-sectional view illustrating a second configuration example of the internal electrode 33G on the right side of FIG. 81 to which the first rewiring 42D of the capacitor 51P is connected, and is an enlarged cross-sectional view of the vicinity of the internal electrode 33G.

In the internal electrode 33G of the first configuration example illustrated in FIG. 85, the lattice pattern wirings D1 to D5 having a lattice-like pattern shape are arranged so that the positions of the openings are staggered (alternately shifted) between the adjacent upper and lower lattice pattern wirings Dx (any one of x=1 to 5). Then, the cylinder capacitor protrusion 941 of the capacitor 51P is embedded up to the upper surface of the lattice pattern wiring D2 through the opening of the lattice pattern wiring D1.

On the other hand, the internal electrodes 33G of the second configuration example illustrated in FIG. 87 are arranged so that the positions of all the openings of the lattice-shaped pattern shapes of the lattice pattern wirings D1 to D5 coincide with each other and overlap each other when viewed in plan view. Then, the cylinder capacitor protrusion 941 of the capacitor 51P is embedded up to the upper surface of the metal wiring layer 911 through all the openings of the lattice pattern wirings D1 to D5. The first rewiring 42D is connected to the upper surface of the lattice pattern wiring D1, the side surface of the opening portion of the lattice pattern wirings D1 to D5, and the upper surface of the metal wiring layer 911. A depth 923 of the cylinder capacitor protrusion 941 as compared with the case where the bottom portion of the first rewiring 42D has a planar shape is formed to be, for example, about 0.1 to 10 μm.

The internal electrode 33G of the second configuration example also has the multilayer wiring structure, so that the connection area with the first rewiring 42D of the capacitor 51P including the combination of the planar capacitor and the cylindrical capacitor can be increased, and the low resistance can be achieved.

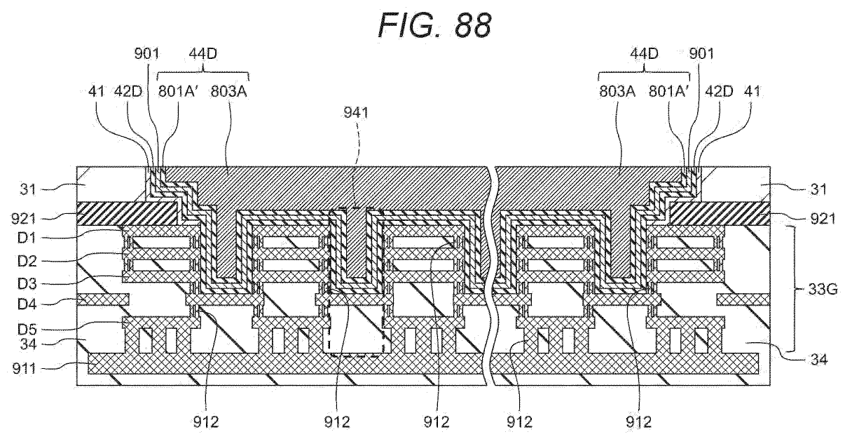

FIG. 88 is a cross-sectional view illustrating a third configuration example of the internal electrode 33G on the right side of FIG. 81 to which the first rewiring 42D of the capacitor 51P is connected, and is an enlarged cross-sectional view of the vicinity of the internal electrode 33G.

The internal electrode 33G of the third configuration example illustrated in FIG. 88 has a structure in which the lattice pattern wirings D1 to D5 illustrated in FIG. 85 are staggered and a structure in which all the lattice pattern wirings D1 to D5 illustrated in FIG. 87 are arranged at the same positions are combined. That is, the lattice pattern wirings D1 to D3 are arranged so that the openings of the lattice pattern wirings Dx are at the same positions, and the lattice pattern wirings D4 and D5 are arranged so that the openings of the lattice pattern wirings Dx are staggered. The lattice pattern wiring D5 has the same arrangement as the lattice pattern wirings D1 to D3 in plan view. The cylinder capacitor protrusion 941 of the capacitor 51P is embedded up to the upper surface of the lattice pattern wiring D4 through the openings of the lattice pattern wirings D1 to D3. The first rewiring 42D is connected to the upper surface of the lattice pattern wiring D1, the side surfaces of the openings of the lattice pattern wirings D1 to D3, and the upper surface of the lattice pattern wiring D4.

In this manner, by arranging the positions of the openings of the lattice pattern wirings D1 to D5 to be staggered or to coincide with each other, the cylinder capacitor protrusion 941 of the capacitor 51P can be embedded to any depth of the multilayer wiring structure having the lattice pattern wirings D1 to D5. The example of FIG. 88 is an example in which the cylinder capacitor protrusion 941 of the capacitor 51P is embedded up to the upper surface of the lattice pattern wiring D4 with the pattern arrangement of the lattice pattern wirings D1 to D3 at the same positions, but it goes without saying that a configuration of embedding up to the upper surface of the lattice pattern wiring D3 or a configuration of embedding up to the upper surface of the lattice pattern wiring D5 is also possible.

The internal electrode 33G of the third configuration example also has the multilayer wiring structure, so that the connection area with the first rewiring 42D of the capacitor 51P including the combination of the planar capacitor and the cylindrical capacitor can be increased, and the low resistance can be achieved.

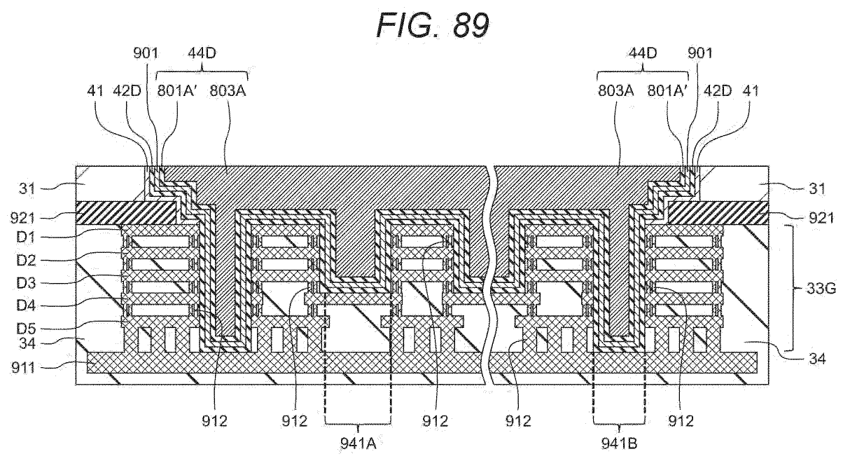

FIG. 89 is a cross-sectional view illustrating a fourth configuration example of the internal electrode 33G on the right side of FIG. 81 to which the first rewiring 42D of the capacitor 51P is connected, and is an enlarged cross-sectional view of the vicinity of the internal electrode 33G.

The capacitor 51P has a plurality of cylinder capacitor protrusions 941 having different diameters and depths, and the internal electrode 33G of the fourth configuration example illustrated in FIG. 89 has a structure electrically connected to the plurality of cylinder capacitor protrusions 941 having different diameters and depths at a plurality of depth positions.

Specifically, the capacitor 51P includes a first cylinder capacitor protrusion 941A having a first diameter and a depth, and a second cylinder capacitor protrusion 941B having a second diameter and a depth different from the first diameter and the depth. The diameter of the first cylinder capacitor protrusion 941A is larger than the diameter of the second cylinder capacitor protrusion 941B, and the depth of the first cylinder capacitor protrusion 941A is shallower than the depth of the second cylinder capacitor protrusion 941B. The first cylinder capacitor protrusion 941A is embedded up to the upper surface of the lattice pattern wiring D4 through the openings of the lattice pattern wirings D1 to D3. The first rewiring 42D of the first cylinder capacitor protrusion 941A is connected to the upper surface of the lattice pattern wiring D1, the side surfaces of the opening portions of the lattice pattern wirings D1 to D3, and the upper surface of the lattice pattern wiring D4. The second cylinder capacitor protrusion 941B is embedded up to the upper surface of the metal wiring layer 911 through the openings of the lattice pattern wirings D1 to D5. The first rewiring 42D of the second cylinder capacitor protrusion 941B is connected to the upper surface of the lattice pattern wiring D1, the side surfaces of the opening portions of the lattice pattern wirings D1 to D5, and the upper surface of the metal wiring layer 911.

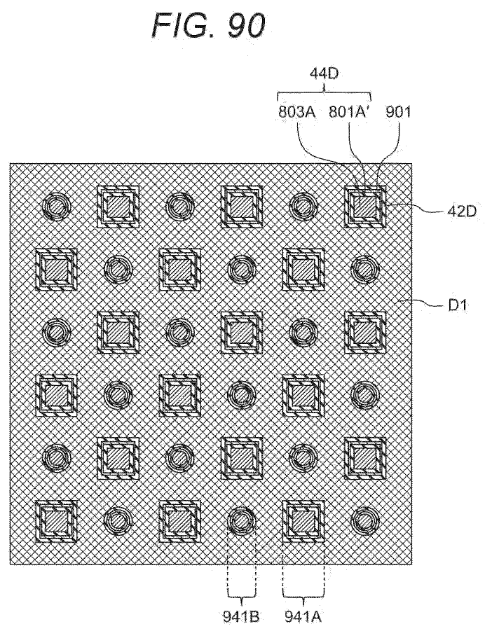

FIG. 90 illustrates a plan view of the internal electrode 33G of FIG. 89 as viewed from a plane passing through the lattice pattern wiring D1.

The first cylinder capacitor protrusion 941A is formed in a rectangular planar shape, and the second cylinder capacitor protrusion 941B is formed in a circular planar shape. The first cylinder capacitor protrusion 941A and the second cylinder capacitor protrusion 941B can be alternately arranged, for example, as illustrated in FIG. 90. However, the first cylinder capacitor protrusion 941A and the second cylinder capacitor protrusion 941B do not necessarily need to be arranged alternately, and may be arranged randomly, and the ratio of the number of first cylinder capacitor protrusions 941A and the number of second cylinder capacitor protrusions 941B is also arbitrary.

As described above, the capacitor 51P has the plurality of cylinder capacitor protrusions 941 (941A and 941B) having different diameters, depths, and planar shapes, and the internal electrode 33G of the fourth configuration example can have a multilayer wiring structure electrically connected to the plurality of cylinder capacitor protrusions 941 at predetermined depth positions. The internal electrode 33G according to the first configuration example to the fourth configuration example can increase the connection area of the capacitor 51P with the first rewiring 42D to achieve low resistance.

### <35. Cross-Sectional View of Extraction Electrode Connection of Cylinder-Type MIM Capacitor>

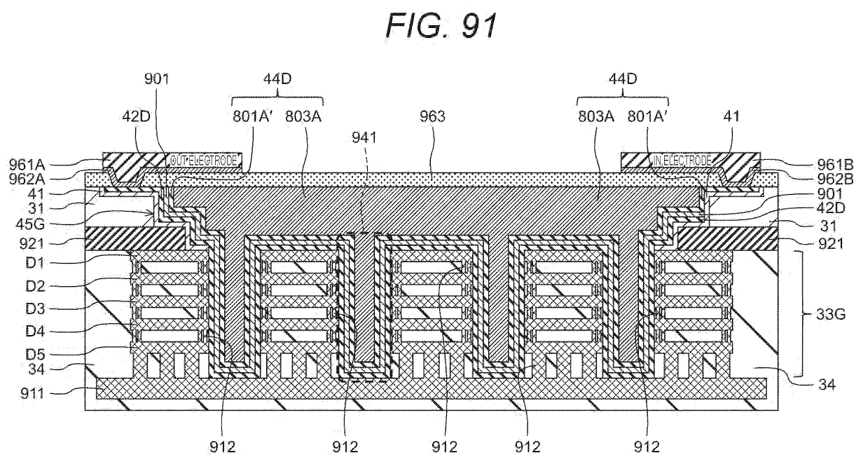

FIG. 91 is a cross-sectional view of a cylinder-type MIM capacitor.

In FIG. 91, parts corresponding to those in FIG. 87 described above are denoted by the same reference numerals, and description of the parts will be omitted as appropriate.

FIG. 91 is a cross-sectional view of a cylinder-type MIM capacitor in which a planar capacitor formed on the silicon substrate 31 is omitted in the capacitor 51P constituted by a combination of a planar capacitor and a cylinder-type capacitor. The first rewiring 42D is connected to a first electrode (OUT electrode) 961A on the silicon substrate 31, and the second rewiring 44D is connected to a second electrode (IN electrode) 961B on the silicon substrate 31.

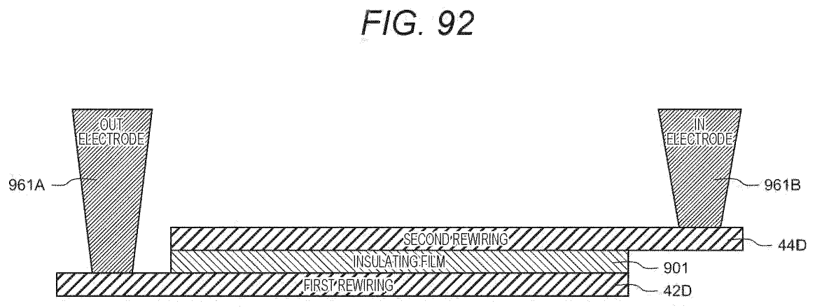

FIG. 92 is a simplified conceptual diagram of the cylinder-type MIM capacitor of FIG. 91.

As illustrated in FIG. 92, the cylinder-type MIM capacitor in FIG. 91 has an MIM structure of the first rewiring 42D, the high dielectric film (insulating film) 901, and the second rewiring 44D. The first electrode (OUT electrode) 961A is an extraction electrode of the first rewiring 42D formed outside the through hole 45G with the high dielectric film 901 interposed therebetween, and the second electrode (IN electrode) 961B is an extraction electrode of the second rewiring 44D formed inside the through hole 45G with the high dielectric film 901 interposed therebetween.

Similarly to FIG. 87, the cylinder-type MIM capacitor of FIG. 91 has a structure in which the cylinder capacitor protrusion 941 is embedded until reaching the upper surface of the metal wiring layer 911 through all the openings of the lattice pattern wirings D1 to D5. The first electrode 961A is connected to the first rewiring 42D via a seed metal 962A on the upper surface of the silicon substrate 31, and the second electrode 961B is connected to the second rewiring 44D via the seed metal 962B on the upper surface of the silicon substrate 31. A region other than the connection point between the first electrode 961A and the first rewiring 42D and the connection point between the second electrode 961B and the second rewiring 44D is covered with, for example, a protective film 963 using a solder resist which is an organic material.

### <36. Manufacturing Method of Cylinder-Type MIM Capacitor>

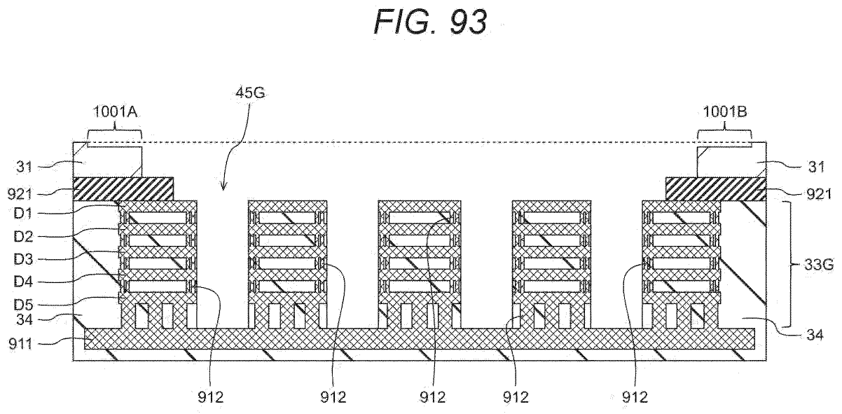

Next, a manufacturing method of the cylinder-type MIM capacitor illustrated in FIG. 91 will be described with reference to FIGS. 93 to 99.

First, as illustrated in FIG. 93, the through hole 45G is formed from the back surface side opposite to the front surface side of the silicon substrate 31 on which the internal electrode 33G of the multilayer wiring structure is formed. The interlayer insulating film 34 in the opening portions of the lattice pattern wirings D1 to D5 of the internal electrode 33G of the multilayer wiring structure is also etched as a part of the through hole 45G until the metal wiring layer 911 is exposed. Furthermore, trenches 1001A and 1001B dug by a predetermined depth are formed outside the through hole 45G. The trench 1001A is a region to be a connection point between the first electrode 961A and the first rewiring 42D, and the trench 1001B is a region to be a connection point between the second electrode 961B and the second rewiring 44D.

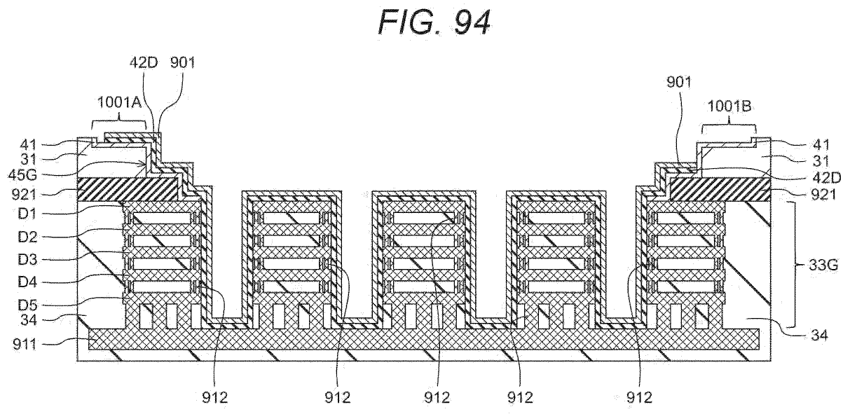

Next, as illustrated in FIG. 94, the first interlayer insulating film 41, the first rewiring 42D, and the high dielectric film 901 are sequentially formed in the formed through hole 45G and trenches 1001 (1001A and 1001B). The first interlayer insulating film 41 is formed by, for example, forming a film on the entire surface including the through hole 45G and the trench 1001 using CVD or the like, and then etching so as to leave the side surface and the upper surface of the STI 921 and the side surface and the upper surface of the silicon substrate 31. Similarly, the first rewiring 42D and the high dielectric film 901 are patterned on the side surface and the bottom portion of the through hole 45G (including the inside of the internal electrode 33G). As illustrated in FIG. 94, the first rewiring 42D and the high dielectric film 901 are formed up to the inside of the trench 1001A on the first electrode 961A side, but are not formed in the trench 1001B on the second electrode 961B side. On the second electrode 961B side, the first rewiring 42D and the high dielectric film 901 extend to the side surface of the through hole 45G, and are insulated by the first interlayer insulating film 41. A region where the first rewiring 42D and the high dielectric film 901 are not formed remains partially inside the trench 1001A on the first electrode 961A side.

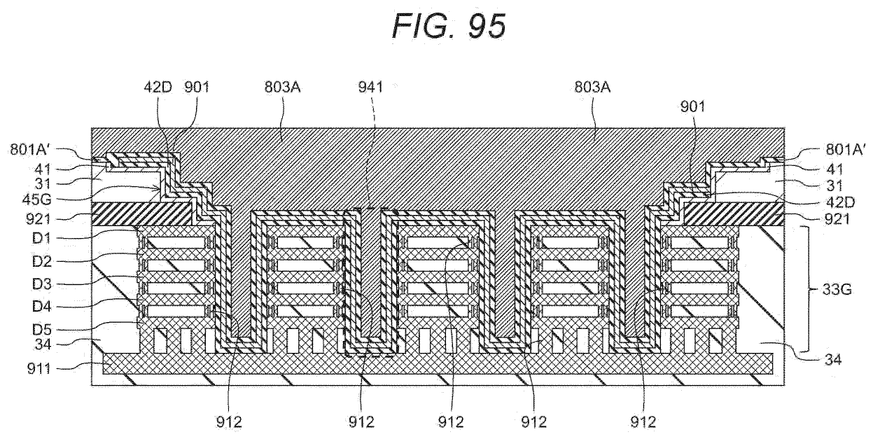

Next, as illustrated in FIG. 95, the seed metal 801A′ and the Cu wiring 803A are formed on the high dielectric film 901. The seed metal 801A′ is formed by, for example, sputtering, and the Cu wiring 803A can be formed by, for example, electrolytic plating until the silicon substrate 31 has a predetermined film thickness. The seed metal 801A′ and the Cu wiring 803A are also embedded in the openings of the lattice pattern wirings D1 to D5 in the internal electrode 33G, thereby forming the cylinder capacitor protrusion 941.

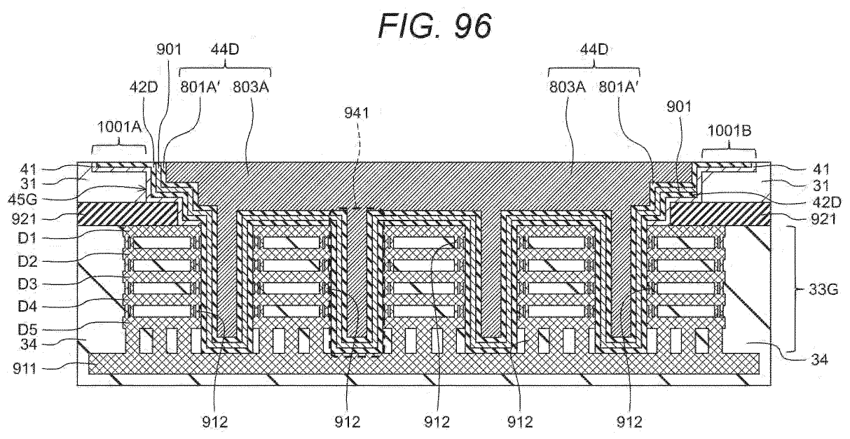

Next, as illustrated in FIG. 96, the entire back surface side of the silicon substrate 31 is removed and planarized by CMP to a level at which the high dielectric film 901 formed in the trench 1001A on the first electrode 961A side is removed. Thus, the first rewiring 42D is exposed in the trench 1001A on the first electrode 961A side, and the seed metal 801A′ of the second rewiring 44D is exposed in the trench 1001B on the second electrode 961B side.

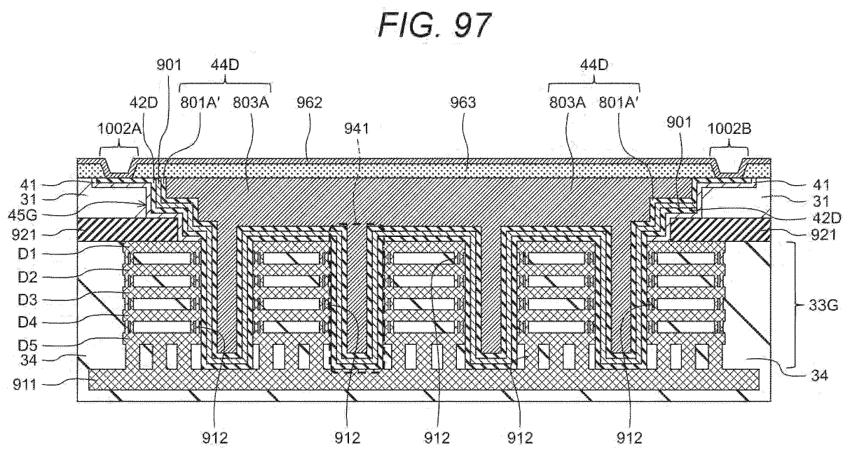

Next, as illustrated in FIG. 97, after the protective film 963 is formed on the entire back surface side of the silicon substrate 31 using a photosensitive solder resist or the like, a region 1002A to be a connection point between the first electrode 961A and the first rewiring 42D and a region 1002B to be a connection point between the second electrode 961B and the second rewiring 44D are opened. Then, the seed metal 962 is formed on the opened regions 1002A and 1002B and the upper surface of the protective film 963 by sputtering, for example.

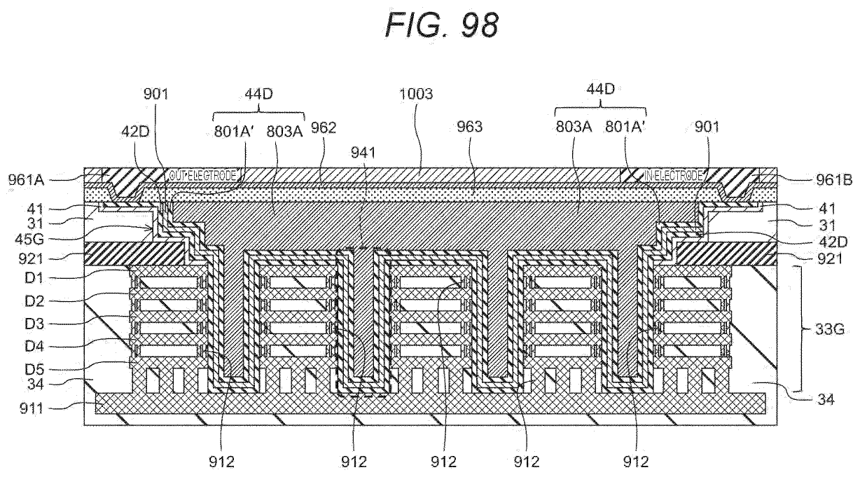

Next, as illustrated in FIG. 98, the first electrode 961A and the second electrode 961B are formed. Specifically, after a photoresist 1003 is patterned by a lithography method so as to open a region where the first electrode 961A and the second electrode 961B are formed, Cu is stacked on the opened region by, for example, electrolytic plating, whereby the first electrode 961A and the second electrode 961B are formed.

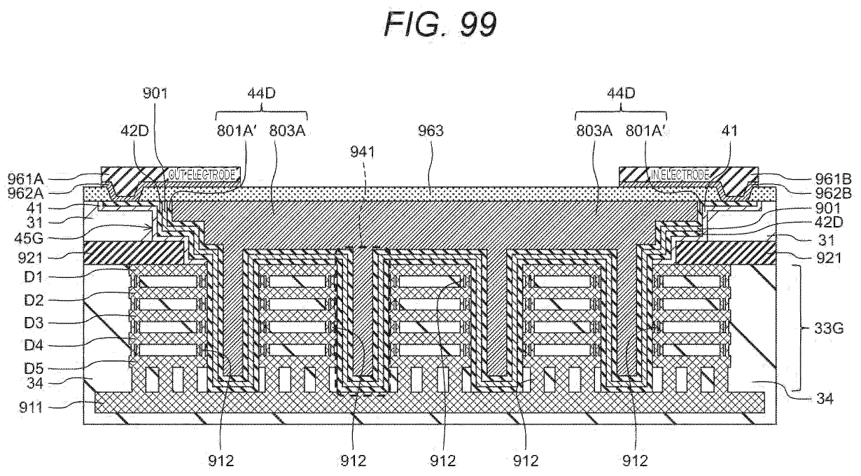

Finally, as illustrated in FIG. 99, the photoresist 1003 and the seed metal 962 formed in a region other than the regions of the first electrode 961A and the second electrode 961B are removed by wet etching or the like, whereby the cylinder-type MIM capacitor illustrated in FIG. 91 is completed.

The cylinder-type MIM capacitor illustrated in FIG. 91 can be manufactured as described above.

### <37. Cross-Sectional View of Extraction Electrode Connection of Cylinder-Type MIM Two-Layer Capacitor>

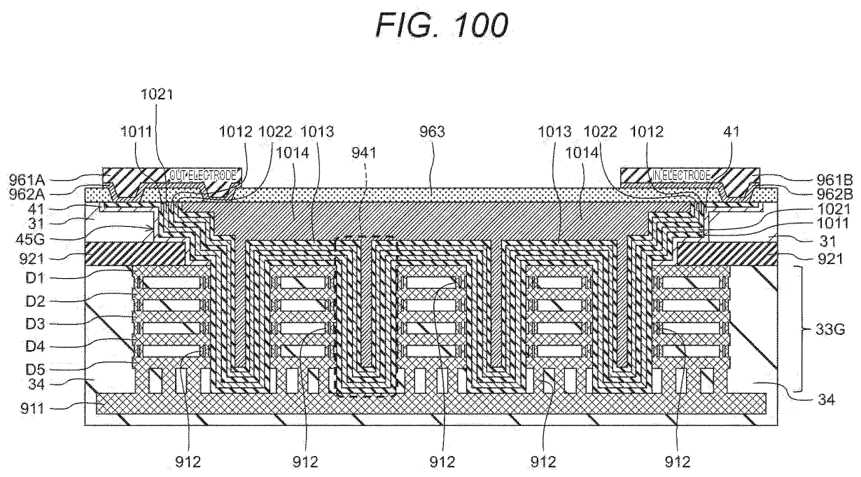

FIG. 100 is a cross-sectional view of a cylinder-type MIM two-layer capacitor in which the cylinder-type MIM is multilayered into two layers.

In FIG. 100, parts corresponding to those of the cylinder-type MIM capacitor illustrated in FIG. 91 are denoted by the same reference numerals, and description of the parts will be omitted as appropriate.

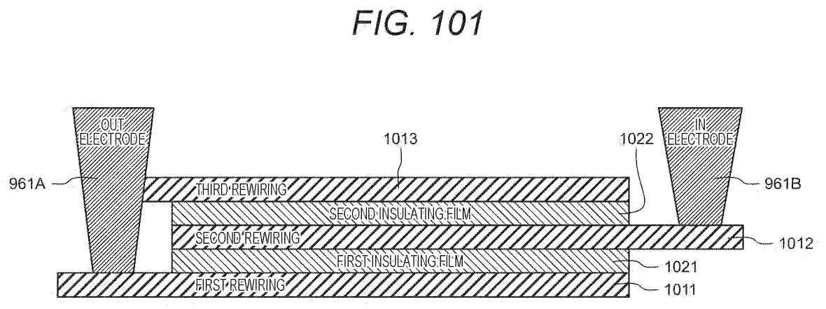

As illustrated in the simplified conceptual diagram of FIG. 101, the cylinder-type MIM two-layer capacitor of FIG. 100 has a two-layer MIM structure in which a first rewiring 1011, a high dielectric film 1021 as a first insulating film, a second rewiring 1012, a high dielectric film 1022 as a second insulating film, and a third rewiring 1013 are stacked in this order. The first rewiring 1011 and the third rewiring 1013 are connected to the first electrode (OUT electrode) 961A, and the second rewiring 1012 is connected to the second electrode (IN electrode) 961B.

As described above, in the cylinder-type MIM capacitor, the MIM structure can be multilayered by connecting the odd number of rewirings (the first rewiring 1011 and the third rewiring 1013) to the first electrode 961A and connecting the even number of rewirings (the second rewirings 1012) to the second electrode 961B. The MIM structure may have three or more layers.

Returning to FIG. 100, the cylinder-type MIM two-layer capacitor has a structure in which the cylinder capacitor protrusion 941 is embedded until reaching the upper surface of the metal wiring layer 911 through all the openings of the lattice pattern wirings D1 to D5, similarly to FIG. 87. The first electrode 961A is connected to the first rewiring 1011 and the embedded Cu 1014 via the seed metal 962A on the upper surface of the silicon substrate 31, and the embedded Cu 1014 is connected to the third rewiring 1013. The second electrode 961B is connected to the second rewiring 1012 via the seed metal 962B on the upper surface of the silicon substrate 31. A region other than the connection point between the first electrode 961A and the first rewiring 1011 and the embedded Cu 1014 and the connection point between the second electrode 961B and the second rewiring 1012 is covered with, for example, the protective film 963 using a solder resist which is an organic material.

### <38. Manufacturing Method of Cylinder-Type MIM Two-Layer Capacitor>

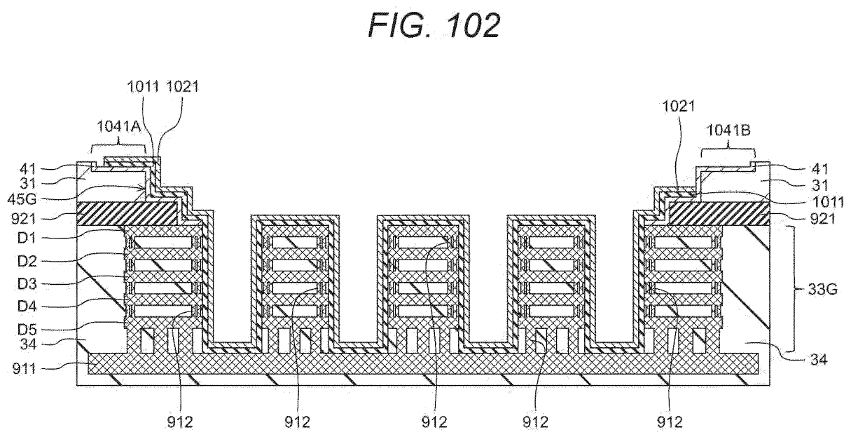

Next, a manufacturing method of the cylinder-type MIM two-layer capacitor illustrated in FIG. 100 will be described with reference to FIGS. 102 to 107.

First, as illustrated in FIG. 102, the steps until the through hole 45G and trenches 1041 (1041A and 1041B) are formed in the silicon substrate 31 and the first interlayer insulating film 41, the first rewiring 1011, and the high dielectric film 1021 are sequentially formed in the formed through hole 45G and trench 1041 are similar to those of the cylinder-type MIM capacitor of FIG. 91 described with reference to FIGS. 93 and 94.

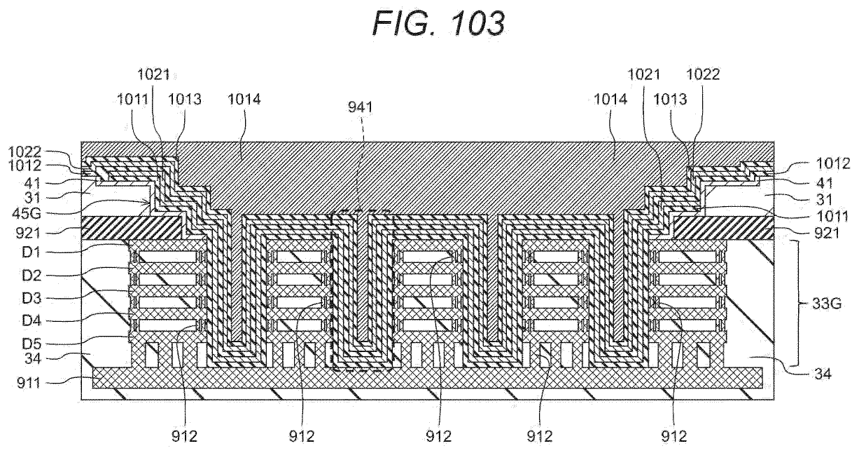

Next, as illustrated in FIG. 103, the second rewiring 1012, the high dielectric film 1022, and the third rewiring 1013 are formed in this order on the upper layer of the high dielectric film 1021, and then the embedded Cu 1014 is stacked on the silicon substrate 31 until a predetermined film thickness is obtained. Electroplating may be performed using the third rewiring 1013 as a seed metal. The first rewiring 1011, the high dielectric film 1021, the second rewiring 1012, the high dielectric film 1022, the third rewiring 1013, and the embedded Cu 1014 are also embedded in the openings of the lattice pattern wirings D1 to D5 in the internal electrode 33G, thereby forming the cylinder capacitor protrusion 941.

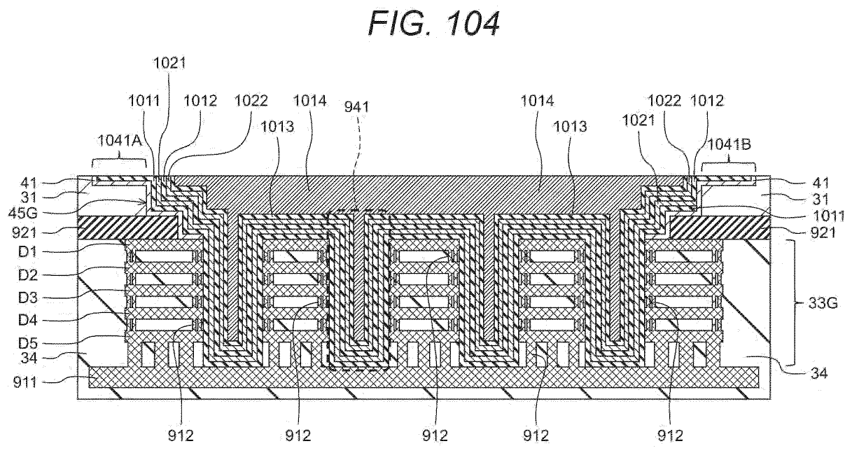

Next, as illustrated in FIG. 104, the entire back surface side of the silicon substrate 31 is removed and planarized by CMP to a level at which the high dielectric film 1021 formed in the trench 1041A on the first electrode 961A side is removed. Thus, the first rewiring 1011 is exposed in the trench 1041A on the first electrode 961A side, and the second rewiring 1012 is exposed in the trench 1041B on the second electrode 961B side.

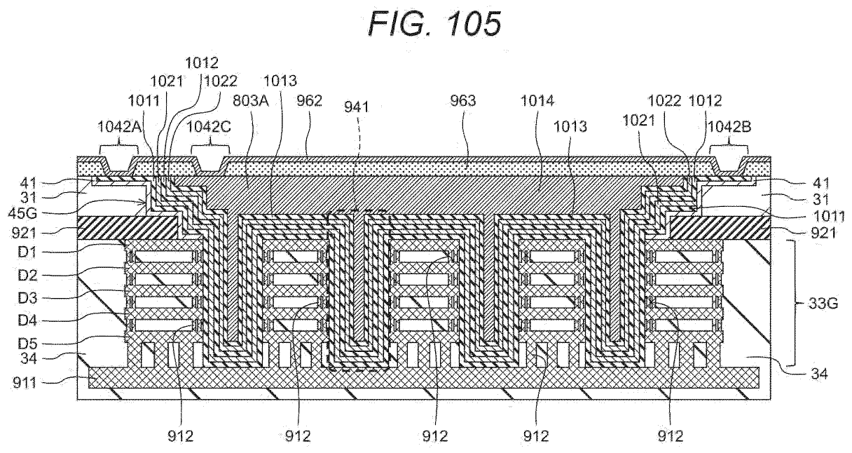

Next, as illustrated in FIG. 105, after the protective film 963 is formed on the entire back surface side of the silicon substrate 31 using a photosensitive solder resist or the like, a region 1042A to be a connection point between the first electrode 961A and the first rewiring 1011, a region 1042C to be a connection point between the first electrode 961A and the embedded Cu 1014, and a region 1042B to be a connection point between the second electrode 961B and the second rewiring 1012 are opened. Then, the seed metal 962 is formed on the upper surfaces of the opened regions 1042A, 1042B, and 1042C and the protective film 963 by, for example, sputtering.

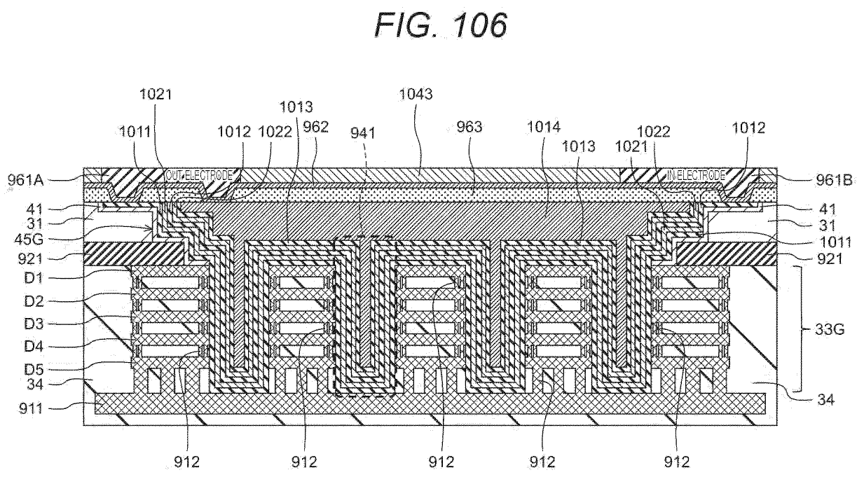

Next, as illustrated in FIG. 106, the first electrode 961A and the second electrode 961B are formed. Specifically, after a photoresist 1043 is patterned by a lithography method so as to open a region where the first electrode 961A and the second electrode 961B are formed, Cu is stacked on the opened region by, for example, electrolytic plating, whereby the first electrode 961A and the second electrode 961B are formed.

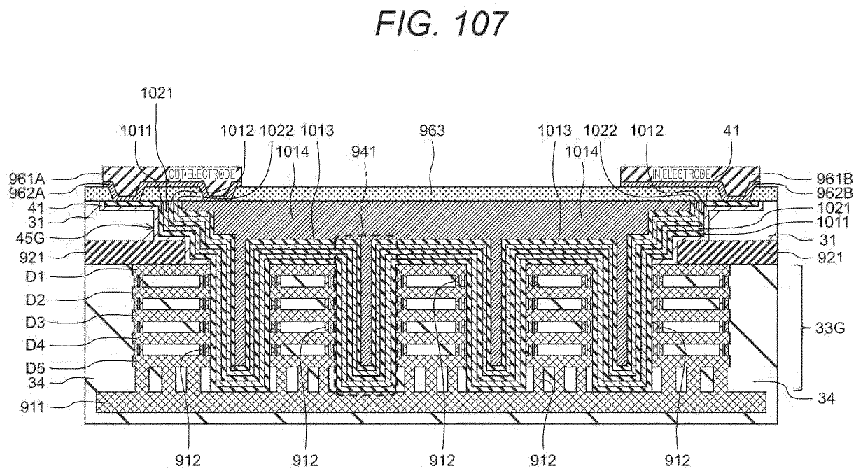

Finally, as illustrated in FIG. 107, the photoresist 1043 and the seed metal 962 formed in a region other than the regions of the first electrode 961A and the second electrode 961B are removed by wet etching or the like, whereby the cylinder-type MIM two-layer capacitor illustrated in FIG. 100 is completed.

The cylinder-type MIM two-layer capacitor illustrated in FIG. 100 can be manufactured as described above.

### <Application to Solid-State Imaging Device of Single-Plate Front Surface Irradiation Type>

In the above-described example, an example has been described in which the cylinder-type MIM capacitor is applied to the back surface irradiation type solid-state imaging device 1 configured by stacking the sensor substrate 11 and the logic substrate 12, but the cylinder-type MIM capacitor can also be applied to the solid-state imaging device 1 using one silicon substrate (single plate semiconductor substrate) 31. Furthermore, the present invention can also be applied to a front surface irradiation type solid-state imaging device 1 that photoelectrically converts light incident from the front surface side of the silicon substrate 31 on which the multilayer wiring layer 32 is formed.

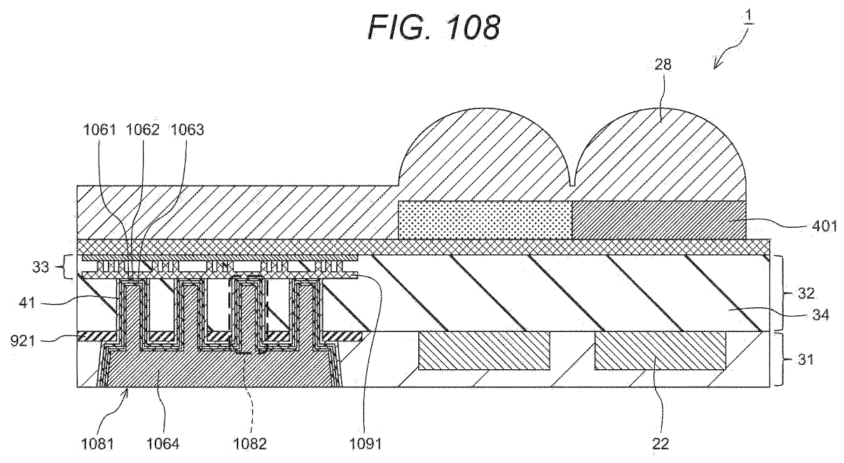

FIG. 108 is a cross-sectional view illustrating an example in which the cylinder-type MIM capacitor is applied to a single-plate front surface irradiation type solid-state imaging device 1.

The solid-state imaging device 1 in FIG. 108 is a single-plate front surface irradiation type solid-state imaging device including a multilayer wiring layer 32, a color filter 401, an on-chip lens 28, and the like on the front surface side of one silicon substrate 31.

The cylinder-type MIM capacitor 1081 has an MIM structure including the first rewiring 1061, the high dielectric film 1062, the second rewiring 1063, and the embedded Cu 1064. The cylinder-type MIM capacitor 1081 has a cylinder capacitor protrusion 1082 embedded up to the metal wiring layer 1091 of the internal electrode 33 through the opening of the STI 921. The cylinder capacitor protrusion 1082 can be formed by forming the pattern shape of the STI 921 into a lattice-shaped pattern shape similar to the above-described lattice pattern wiring Dx.

### 39. 14th Configuration Example of Capacitor

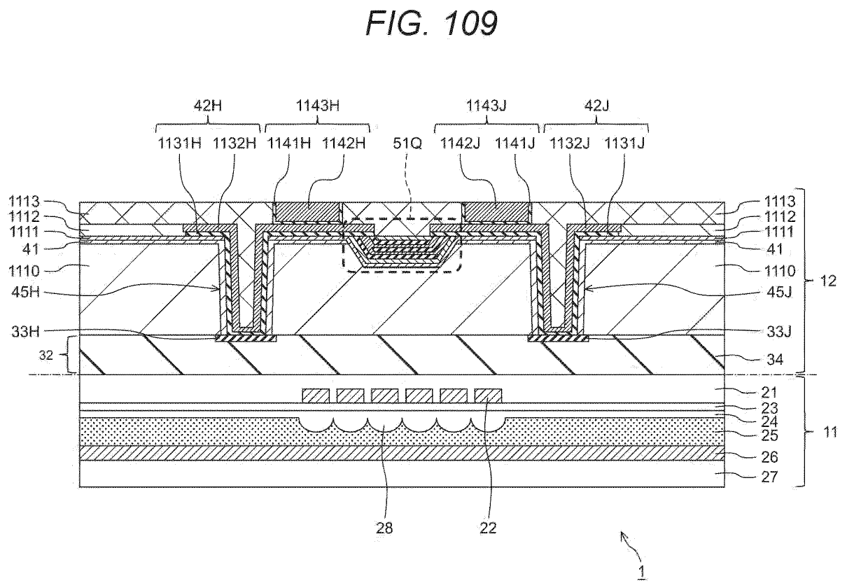

FIG. 109 is a cross-sectional view of a solid-state imaging device 1 according to a 14th embodiment.

A solid-state imaging device 1 illustrated in FIG. 109 is a chip size package type CMOS solid-state imaging device configured by stacking a sensor substrate 11 and a logic substrate 12. The sensor substrate 11 and the logic substrate 12 are joined by a surface indicated by a one-dot chain line. However, FIG. 109 illustrates that the sensor substrate 11 is disposed on the lower side and the logic substrate 12 is disposed on the upper side, and the vertical direction of the solid-state imaging device 1 is opposite to that in FIG. 1. Pillars (lands) 1143 (1143H and 1143J), which are external connection terminals instead of the solder bumps 47, are formed on the back surface side of the solid-state imaging device 1 on the upper side in FIG. 109.

Since the configuration of the sensor substrate 11 is similar to that in FIG. 1, the description thereof will be omitted. The interlayer insulating film 25, the bonding resin 26, and the light-transmissive substrate 27 of the sensor substrate 11 may be omitted.

The logic substrate 12 includes a semiconductor substrate 1110 using, for example, silicon (Si) as a semiconductor. The semiconductor substrate 1110 may be a substrate using a compound semiconductor such as InGaP, InAIP, InGaAs, or InAlAs, but in the present embodiment, it is described that the semiconductor substrate is the silicon substrate 1110 according to the other configuration examples described above. In the drawing, the multilayer wiring layer 32 is formed on a first surface side (sensor substrate 11 side) of the silicon substrate 1110 which is a lower side. On a second surface side opposite to the first surface side of the silicon substrate 1110 on which the multilayer wiring layer 32 is formed, a first interlayer insulating film 41, a second interlayer insulating film 1111, first rewirings 42 (42H and 42J), a third interlayer insulating film 1112, and a protective film 1113 are formed from a side closer to the silicon substrate 1110. The first rewiring 42 and the third interlayer insulating film 1112 are formed in the same layer, and the third interlayer insulating film 1112 is formed in a region where the first rewiring 42 is not formed. The pillars 1143 (1143H and 1143J) are connected to the first rewiring 42, and the back surface of the solid-state imaging device 1 in a region where the pillars 1143 are not formed is covered with the protective film 1113. The first surface side of the silicon substrate 1110 on which the multilayer wiring layer 32 is formed corresponds to a front surface side of the silicon substrate 1110, and the second surface side on which the two interlayer insulating films and the rewiring are formed corresponds to a back surface side of the silicon substrate 1110. As a material of the second interlayer insulating film 1111 and the third interlayer insulating film 1112, a material similar to that of the second interlayer insulating film 43 described above, for example, a SiO2 film, a low-k film, a SiOC film, a SiN film, a SiON film, or the like can be used. As a material of the protective film 1113, a material similar to the protective film 48 described above, for example, a solder resist which is an organic material can be used.

Two internal electrodes 33H and 33J are formed in a predetermined region of the multilayer wiring layer 32 of the silicon substrate 1110. Through holes 45H and 45J are formed in the silicon substrate 1110 at positions corresponding to the internal electrodes 33H and 33J, respectively.

The first interlayer insulating film 41 is formed on a side surface (inner peripheral surface) of the through hole 45H formed at a position corresponding to the internal electrode 33H and the back surface side of the silicon substrate 1110. The first interlayer insulating film 41 electrically isolates the first rewiring 42H from the silicon substrate 1110. The first rewiring 42H is formed on the back surface side of the silicon substrate 1110 and the side surface (inner peripheral surface) of the through hole 45H, and is connected to the internal electrode 33H formed in the multilayer wiring layer 32 on the front surface side. Furthermore, the pillar 1143H is formed on a part of the upper surface of the first rewiring 42H. The first rewiring 42H includes, for example, a seed metal 1131H including a barrier metal and a Cu seed film, and a Cu wiring 1132H. As a material of the barrier metal film, tantalum (Ta), titanium (Ti), tungsten (W), zirconium (Zr), a nitride film thereof, a carbonized film thereof, or the like can be used.

The first interlayer insulating film 41 is formed on a side surface (inner peripheral surface) of the through hole 45J formed at a position corresponding to the internal electrode 33J and the back surface side of the silicon substrate 1110. The first interlayer insulating film 41 electrically isolates the first rewiring 42J from the silicon substrate 1110. The first rewiring 42J is formed on the back surface side of the silicon substrate 1110 and the side surface (inner peripheral surface) of the through hole 45J, and is connected to the internal electrode 33J formed in the multilayer wiring layer 32 on the front surface side. Furthermore, the pillar 1143J is formed on a part of the upper surface of the first rewiring 42J. The first rewiring 42J includes, for example, a seed metal 1131J including a barrier metal and a Cu seed film, and a Cu wiring 1132J. The material of the barrier metal is similar to those described above.

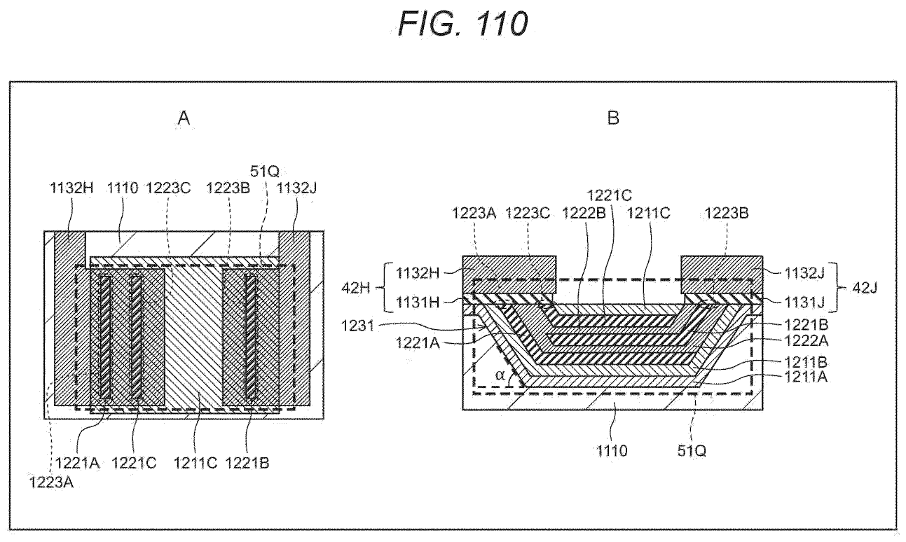

A capacitor 51Q is formed between the pillars 1143H and 1143J. Different potentials are supplied to the pillar 1143H and the pillar 1143J. Thus, the capacitor 51Q can have electrostatic capacitance. A detailed structure of the capacitor 51Q will be described with reference to FIG. 110.

FIG. 110 is an enlarged view illustrating a detailed structure of the capacitor 51Q according to a 14th configuration example, which is the capacitor 51 of the solid-state imaging device 1 of the 14th embodiment. A of FIG. 110 illustrates a plan view, and B of FIG. 110 illustrates a cross-sectional view.

The capacitor 51Q is formed in a trench 1231 on the back surface side of the silicon substrate 1110 in which the first rewirings 42H and 42J are formed. The trench 1231 has a side surface inclined so that a plane area of an upper portion equal to the interface of the silicon substrate 1110 is large and a plane area of a dug bottom portion is small. The inclination angle α of the trench 1231 is, for example, in a range of 45 to 70 degrees with respect to a plane parallel to the silicon substrate 1110.

In the trench 1231, a first insulating film 1211A, a second insulating film 1211B, a first electrode film 1221A, a dielectric film 1222A, a second electrode film 1221B, a dielectric film 1222B, a third electrode film 1221C, and a third insulating film 1211C are stacked in this order from a bottom portion to the top. More specifically, the first insulating film 1211A is formed at the bottom portion in the trench 1231, the second insulating film 1211B is formed on the first insulating film 1211A, and the third insulating film 1211C is formed at the uppermost portion in the trench 1231. Then, between the second insulating film 1211B and the third insulating film 1211C, the first electrode film 1221A, the dielectric film 1222A, the second electrode film 1221B, the dielectric film 1222B, and the third electrode film 1221C are stacked in this order upward from the bottom portion of the trench 1231. Each of the first electrode film 1221A, the dielectric film 1222A, the second electrode film 1221B, the dielectric film 1222B, and the third electrode film 1221C has an inclination of an angle α similar to the inclination of the trench 1231, and is refracted along the side surface of the trench 1231 toward the interface of the silicon substrate 1110.

The first electrode film 1221A and the third electrode film 1221C are connected to the seed metal 1131H of the first rewiring 42H on the left side in the drawing. The first electrode film 1221A is connected to (the seed metal 1131H of) the first rewiring 42H by a linear electrode connection surface 1223A. The third electrode film 1221C is connected to (the seed metal 1131H of) the first rewiring 42H by the linear electrode connection surface 1223C. The second electrode film 1221B is connected to the seed metal 1131J of the first rewiring 42J on the right side in the drawing. The second electrode film 1221B is connected to (the seed metal 1131J of) the first rewiring 42J by the linear electrode connection surface 1223B. As illustrated in the plan view, the three linear electrode connection surfaces 1223A, 1223B, and 1223C are arranged side by side in parallel, in other words, arranged side by side in the same axial direction (for example, in the Y-axis direction).

The dielectric film 1222A between the first electrode film 1221A and the second electrode film 1221B and the dielectric film 1222B between the second electrode film 1221B and the third electrode film 1221C are connected below the first rewiring 42H using the same material. A first potential (for example, the power supply voltage) is supplied to the first electrode film 1221A and the third electrode film 1221C via the first rewiring 42H, and a second potential (for example, ground) different from the first potential (for example, the power supply voltage) is supplied to the second electrode film 1221B via the first rewiring 42J. That is, the capacitor 51Q has a capacitor structure in which two parallel plate capacitors are connected in parallel.

As a material of the first insulating film 1211A and the second insulating film 1211B, for example, a SiO2 film, a low-k film, a SiOC film, a SiN film, a SiON film, or the like can be used. However, different materials are used for the materials of the first insulating film 1211A and the second insulating film 1211B so that a selection ratio can be obtained. The first insulating film 1211A can be formed in common with the second interlayer insulating film 1111 (FIG. 109) in a region other than the capacitor 51Q.

The materials of the first electrode film 1221A, the second electrode film 1221B, and the third electrode film 1221C only need to be any metal material that can be processed by dry etching or wet etching, and for example, titanium (Ti), tungsten (W), copper (Cu), aluminum (Al), gold (Au), or the like can be employed.

The dielectric films 1222A and 1222B can be, as a matter of course, a silicon oxide film (SiO2 film), and can be, for example, a tantalum oxide film, an aluminum oxide film, a hafnium oxide film, a titanium oxide film, a zirconium oxide film, a niobium oxide film, a silicon nitride film, or the like, or may be two or more stacked films thereof. The dielectric films 1222A and 1222B may be of the same material or different materials.

As described above, the capacitor 51Q according to the 14th configuration example is configured so that the inclined trench 1231 is provided between two adjacent rewirings 42 (42H and 42J), and the plurality of electrode films 1221 (1221A, 1221B, and 1221C) and the dielectric films 1222 (1222A and 1222B) are stacked and embedded in the trench. Thus, electrostatic capacitance can be provided, and higher speed transmission can be performed.

For example, in the case of the capacitor 51E illustrated in FIG. 19, the formation positions of the planar capacitor and the cylindrical capacitor are limited to the position of the through hole 45A and the position of the first rewiring 42A on the silicon substrate 31. In the case of the capacitor 51Q according to the 14th configuration example, the capacitor can be formed at a desired position without being limited by the existing wiring pattern or the underlying semiconductor (semiconductor substrate 1110).

### 40. Manufacturing Method of Capacitor According to 14th Configuration Example

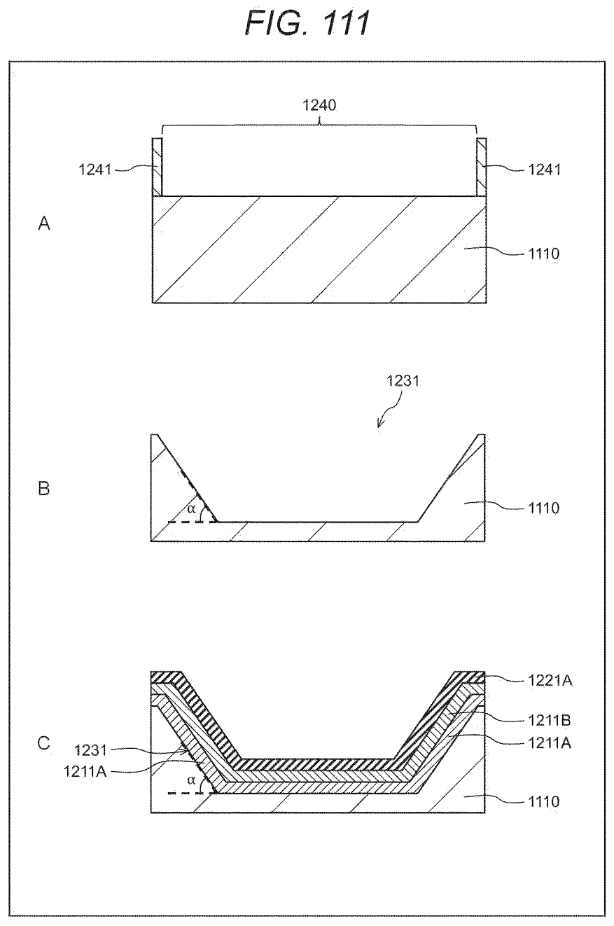

Next, a manufacturing method of the capacitor 51Q according to the 14th configuration example illustrated in FIG. 110 will be described with reference to FIGS. 111 to 116.

First, as illustrated in A of FIG. 111, a photoresist 1241 is patterned so as to open a region 1240 of the silicon substrate 1110 forming the capacitor 51Q, and then, as illustrated in B of FIG. 111, the silicon substrate 1110 is dry-etched or wet-etched to form the trench 1231 inclined at a predetermined angle α in the silicon substrate 1110. After the formation of the trench 1231, the photoresist 1241 is removed by wet etching or ashing.

Next, as illustrated in C of FIG. 111, the first insulating film 1211A, the second insulating film 1211B, and the first electrode film 1221A are formed in this order on an upper surface of the trench 1231. Each of the first insulating film 1211A, the second insulating film 1211B, and the first electrode film 1221A can be formed using, for example, CVD, physical vapor deposition (PVD), or the like. The first insulating film 1211A and the second insulating film 1211B are different materials in order to have a selection ratio. For example, the first insulating film 1211A can be formed by a SiN film, and the second insulating film 1211B can be formed by a SiO2 film.

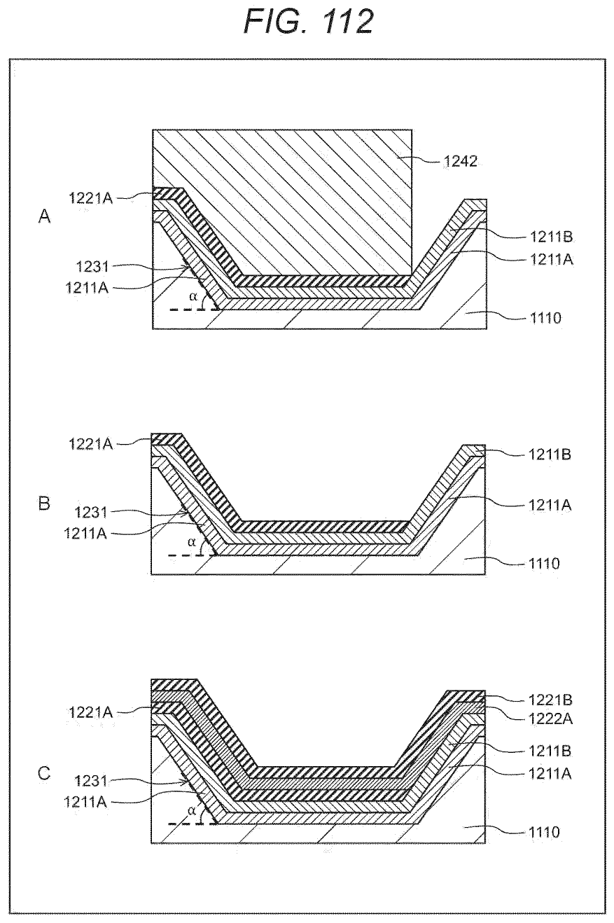

Next, as illustrated in A of FIG. 112, an unnecessary first electrode film 1221A is removed by dry etching or wet etching in a state where a region required as the first electrode film 1221A is masked with a photoresist 1242. After the etching, the photoresist 1242 is removed by wet etching or ashing and brought into a state illustrated in B of FIG. 112.

Next, as illustrated in C of FIG. 112, the dielectric film 1222A and the second electrode film 1221B are formed in this order on the patterned first electrode film 1221A. Each of the dielectric film 1222A and the second electrode film 1221B can be formed by using, for example, CVD, PVD, or the like.

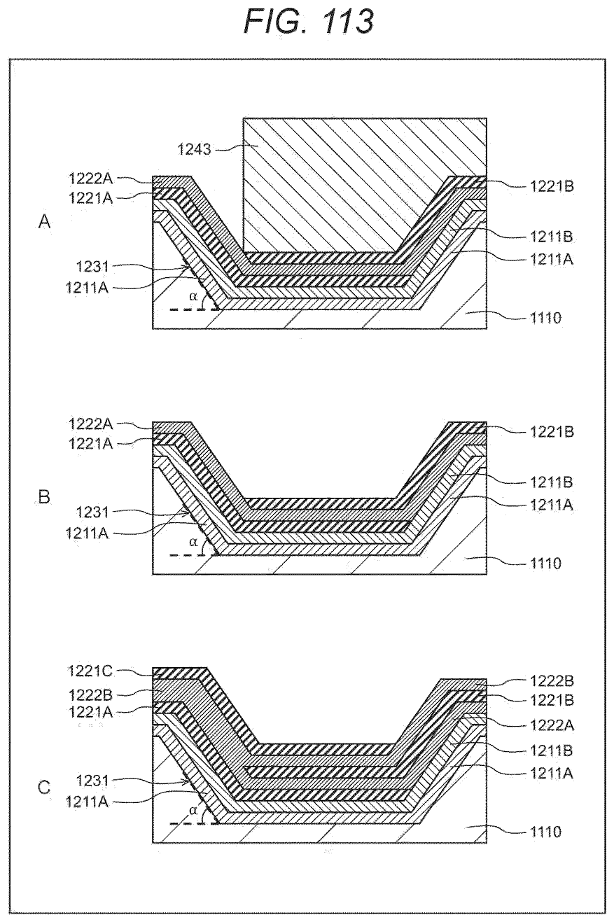

Then, as illustrated in A of FIG. 113, similarly to the first electrode film 1221A, the unnecessary second electrode film 1221B is removed by dry etching or wet etching in a state where a necessary region is masked with the photoresist 1243. After the etching, the photoresist 1243 is removed by wet etching or ashing and brought into a state illustrated in B of FIG. 113.

Moreover, as illustrated in C of FIG. 113, the dielectric film 1222B and the third electrode film 1221C are formed in this order, and an unnecessary region of the third electrode film 1221C is removed by dry etching or wet etching. Each of the dielectric film 1222B and the third electrode film 1221C can be formed by using, for example, CVD, PVD, or the like.

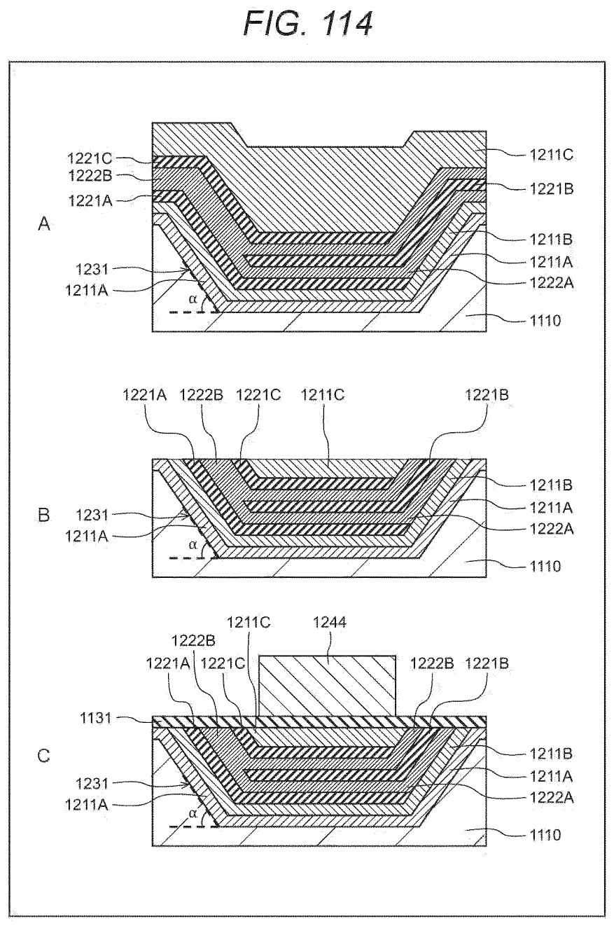

Next, as illustrated in A of FIG. 114, the third insulating film 1211C is formed by using CVD, PVD, or the like at a film thickness at which the recess of the third electrode film 1221C on the uppermost layer is filled, and then, as illustrated in B of FIG. 114, planarization is performed by CMP to a level at which an upper surface of the first insulating film 1211A is exposed. The selection ratio between the first insulating film 1211A and the second insulating film 1211B is ensured, and the planarization processing ends at a level where the first insulating film 1211A serves as a CMP stopper film and the upper surface of the first insulating film 1211A is exposed. Thus, as illustrated in the plan view of A of FIG. 110, the first electrode film 1221A, the second electrode film 1221B, and the third electrode film 1221C are exposed to be linearly arranged on the same plane as the upper surface of the first insulating film 1211A.

Next, as illustrated in C of FIG. 114, the seed metal 1131 including a barrier metal and a Cu seed film is formed by, for example, PVD, and then a photoresist 1244 is patterned in a region other than a region to be the first rewiring 42H or the first rewiring 42J.

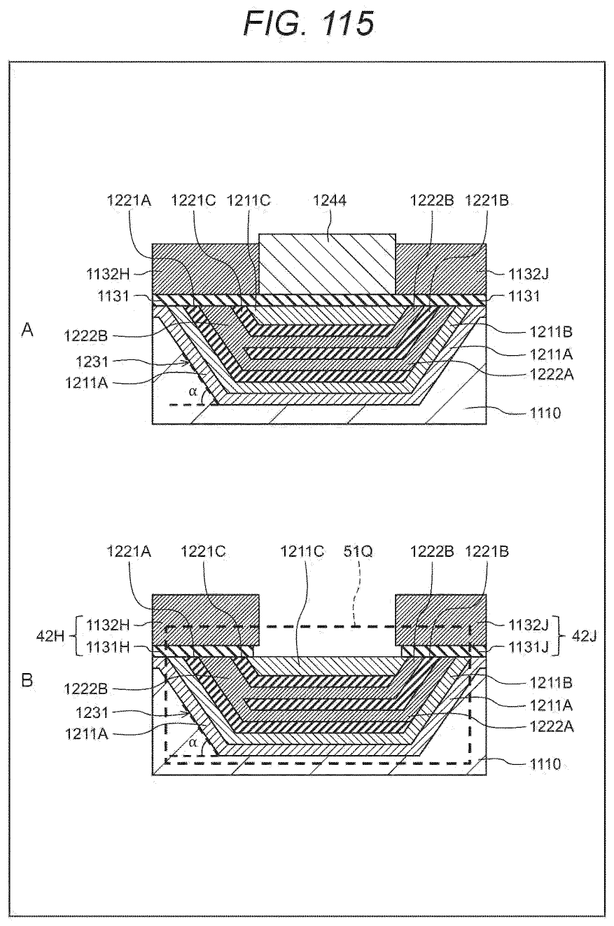

Next, as illustrated in A of FIG. 115, Cu wirings 1132H and 1132J are deposited on the seed metal 1131 not covered with the photoresist 1244 by, for example, electrolytic plating.

Finally, as illustrated in B of FIG. 115, the photoresist 1244 is removed by wet etching or ashing, and the seed metal 1131 under the photoresist 1244 is removed by wet etching. By removing the seed metal 1131 under the photoresist 1244, the left and right remaining seed metals 1131 become the seed metals 1131H and 1131J of the first rewirings 42H and 42J, respectively.

Through the above steps, the capacitor 51Q according to the 14th configuration example illustrated in FIG. 110 is formed. After the logic substrate 12 on which the capacitor 51Q is formed is completed, the logic substrate 12 is bonded to the sensor substrate 11 at an appropriate timing, and the solid-state imaging device 1 is completed.

According to the structure of the capacitor 51Q described above, a step of forming a contact wiring to the capacitive element is unnecessary, and a connection portion (electrode connection surface 1223) with the rewiring 42 can be formed at a time by planarizing a film formed on the silicon substrate 1110 by CMP. Therefore, the capacitor 51 can be formed in a simple process.

### 41. Modification of 14th Configuration Example

A modification of the capacitor 51Q according to the 14th configuration example will be described. Note that, in the following modification, parts corresponding to those of the capacitor 51Q illustrated in FIG. 110 are denoted by the same reference numerals, and description of the parts will be omitted as appropriate. Note that, hereinafter, the configuration of the capacitor 51Q illustrated in FIG. 110 is referred to as a basic configuration example of the capacitor 51Q.

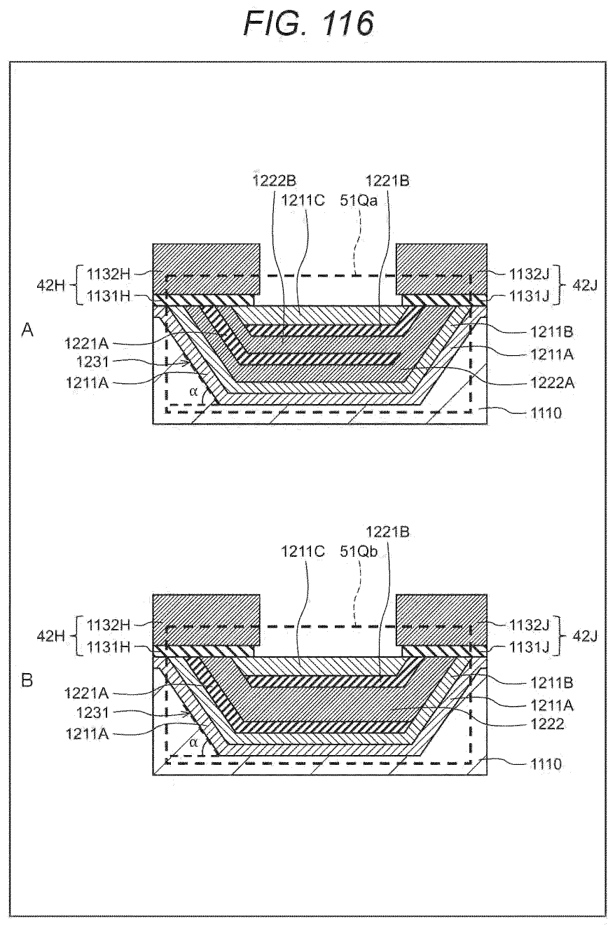

A of FIG. 116 is a cross-sectional view of a capacitor 51Qa which is a first modification of the capacitor 51Q.

In the capacitor 51Qa according to the first modification, as compared with the basic configuration of the capacitor 51Q illustrated in FIG. 110, the third electrode film 1221C connected to the seed metal 1131H of the first rewiring 42H on the left side is omitted. That is, the capacitor 51Qa according to the first modification includes the two electrode films 1221 of the first electrode film 1221A connected to the left first rewiring 42H and the second electrode film 1221B connected to the right first rewiring 42J, and the dielectric films 1222A and 1222B. The basic configuration of the capacitor 51Q illustrated in FIG. 110 has a capacitor structure in which two parallel plate capacitors are connected in parallel, but the capacitor 51Qa according to the first modification has a structure of one parallel plate capacitor.

B of FIG. 116 is a cross-sectional view of a capacitor 51Qb which is a second modification of the capacitor 51Q.

In the capacitor 51Qb according to the second modification, as compared with the basic configuration of the capacitor 51Q illustrated in FIG. 110, the third electrode film 1221C connected to the seed metal 1131H of the first rewiring 42H on the left side is omitted. A difference from the capacitor 51Qa according to the first modification in A of FIG. 116 is a distance (thickness) between the two electrode films 1221 of the first electrode film 1221A and the second electrode film 1221B. In the capacitor 51Qa according to the first modification in A of FIG. 116, the distance between the first electrode film 1221A and the second electrode film 1221B is short, and the dielectric film 1222A is also formed below the first electrode film 1221A. On the other hand, in the capacitor 51Qb according to the second modification, the dielectric film 1222 is not formed below the first electrode film 1221A, and the distance between the first electrode film 1221A and the second electrode film 1221B is ensured to be larger than that of the capacitor 51Qa according to the first modification.

As described above, the electrostatic capacitance of the capacitor 51Q can be arbitrarily designed by changing the distance between the electrode films 1221, the number and arrangement of the electrode films 1221, and the like of the capacitor 51Q.

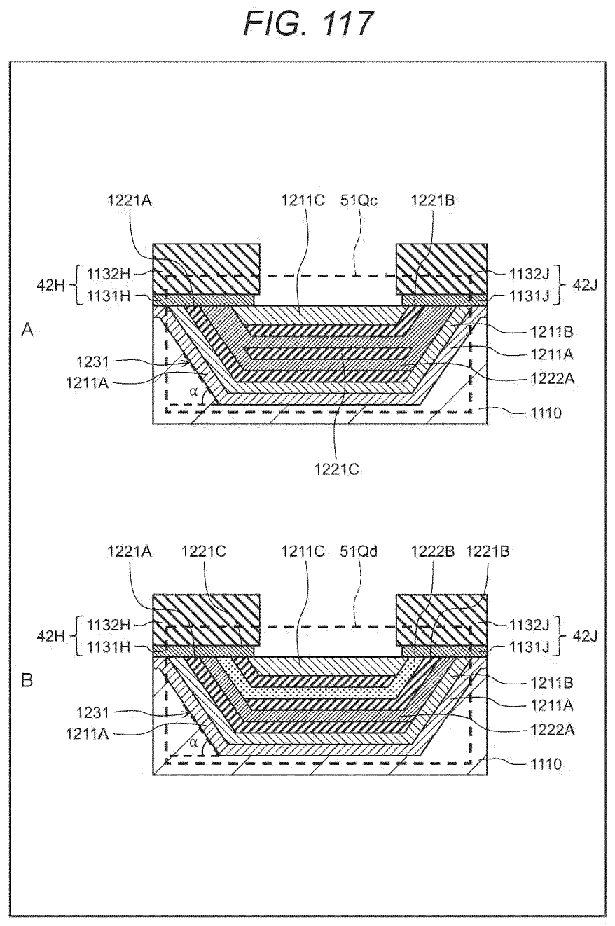

A of FIG. 117 is a cross-sectional view of a capacitor 51Qc that is a third modification of the capacitor 51Q.

The capacitor 51Qc according to the third modification has a configuration in which a third electrode film 1221C not connected to any of the first rewirings 42 is added between the first electrode film 1221A and the second electrode film 1221B, as compared with the configuration of the capacitor 51Qb of the second modification illustrated in B of FIG. 116. The capacitor 51Qc has a capacitor structure in which two parallel plate capacitors are connected in series. The capacitor 51Q can have a structure in which a plurality of stacked electrode films 1221 is connected in series as described above, or can have a structure in which they are connected in parallel.

B of FIG. 117 is a cross-sectional view of a capacitor 51Qd which is a fourth modification of the capacitor 51Q.

In the basic configuration of the capacitor 51Q illustrated in FIG. 110, the same material is used for the dielectric film 1222A between the first electrode film 1221A and the second electrode film 1221B and the dielectric film 1222B between the second electrode film 1221B and the third electrode film 1221C. On the other hand, in the capacitor 51Qd according to the fourth modification, different materials are used for the dielectric film 1222A and the dielectric film 1222B. By changing the materials of the dielectric film 1222A and the dielectric film 1222B, the electrostatic capacitance of the capacitor 51Q can be arbitrarily designed.

### Other Configuration Examples

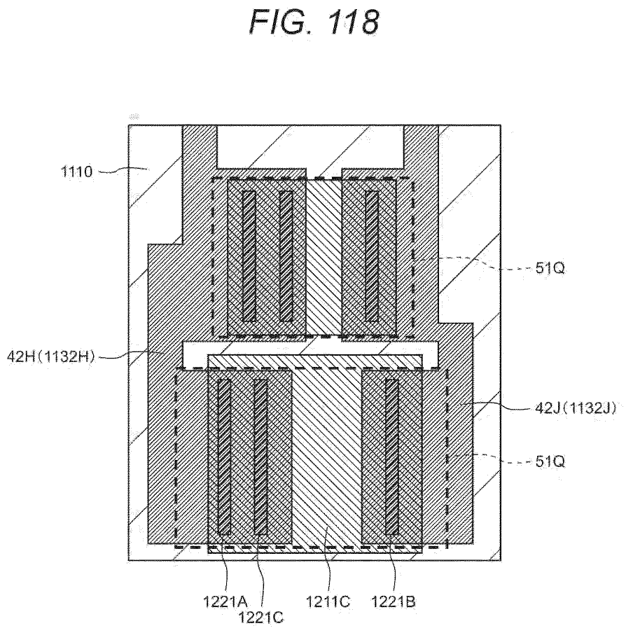

FIG. 118 illustrates a configuration example in which the two capacitors 51Q illustrated in FIG. 110 are connected in parallel by the first rewiring 42H and the first rewiring 42J. The two capacitors 51Q are configured to have different planar sizes and different magnitudes of electrostatic capacitance, but may be formed to have the same size, and the two capacitors 51Q having the same electrostatic capacitance may be connected in parallel. Furthermore, instead of connecting the two capacitors 51Q in parallel, the first rewiring 42H and the first rewiring 42J may be connected in series. A configuration example in which plural, three or more capacitors 51Q are connected in parallel or in series by the first rewiring 42 may be used.

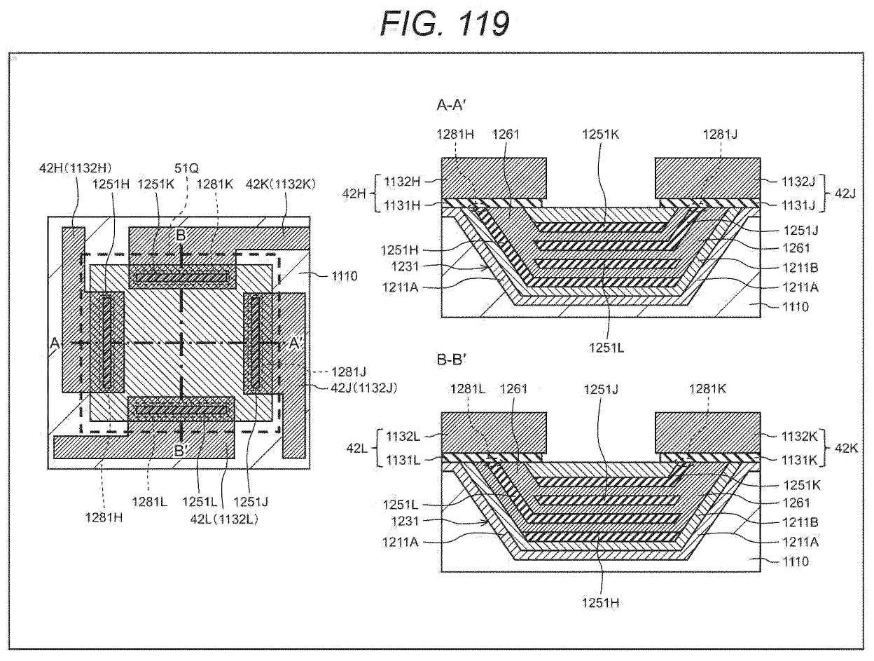

FIG. 119 is a plan view and a cross-sectional view illustrating another configuration example of the capacitor 51Q. The left side of FIG. 119 illustrates a plan view of the capacitor 51Q according to another configuration example, and the right side of FIG. 119 illustrates cross-sectional views taken along lines A-A′ and B-B′ of the plan view.

The capacitor 51Q in FIG. 119 is configured by stacking four electrode films 1251H, 1251J, 1251K, and 1251L and a dielectric film 1261 in the trench 1231. The trench 1231 has a quadrangular truncated pyramid shape. The four electrode films 1251H, 1251J, 1251K, and 1251L are connected to different first rewirings 42, respectively. Specifically, the electrode film 1251H is connected to the first rewiring 42H, and the electrode film 1251J is connected to the first rewiring 42J. The electrode film 1251K is connected to the first rewiring 42K, and the electrode film 1251L is connected to the first rewiring 42L. The electrode film 1251H and the first rewiring 42H are connected by an electrode connection surface 1281H on the semiconductor substrate 1110. The electrode film 1251J and the first rewiring 42J are connected by an electrode connection surface 1281J on the semiconductor substrate 1110. The electrode film 1251K and the first rewiring 42K are connected by an electrode connection surface 1281K on the semiconductor substrate 1110. The electrode film 1251L and the first rewiring 42L are connected by an electrode connection surface 1281L on the semiconductor substrate 1110. The electrode connection surfaces 1281H, 1281J, 1281K, and 1281L are arranged in a substantially quadrangular shape in plan view on the semiconductor substrate 1110. Here, the substantially quadrangular shape means a quadrangular shape to which corners of four corners of the quadrangle are not connected.

In the basic configuration example of the capacitor 51Q illustrated in FIG. 110 and the modification thereof described above, the linear electrode connection surfaces 1223A, 1223B, and 1223C at the interface of the silicon substrate 1110 are arranged in parallel, in other words, arranged in the same axial direction (for example, in the Y-axis direction).

On the other hand, in the capacitor 51Q in FIG. 119, the two opposing electrode connection surfaces 1281H and 1281J are arranged so as to be orthogonal to the other two opposing electrode connection surfaces 1281K and 1281L, and are arranged so as to form a substantially quadrangular shape.

As described above, the capacitor 51Q can be configured so that the number of layers of the electrode film 1251 stacked in the trench 1231 is four or more, and the planar shape of the electrode connection surface 1281 where each of the plurality of electrode films 1251 is connected to the first rewiring 42 on the silicon substrate 1110 is a substantially polygonal shape of a quadrangle or more. The trench 1231 has a polygonal truncated pyramid shape. For example, in a case where the number of layers of the electrode film 1251 stacked in the trench 1231 is six, the planar shape of the electrode connection surface 1281 in which each of the plurality of electrode films 1251 is connected to the first rewiring 42 on the silicon substrate 1110 can be configured to be a substantially hexagonal shape. The trench 1231 has a hexagonal truncated pyramid shape. In each of the plurality of electrode films 1251 having the substantially polygonal electrode connection surface 1281, different potentials are applied to at least the electrode films 1251 adjacent in the vertical direction or the planar direction. Different potentials may be applied to each of the plurality of electrode films 1251 having the substantially polygonal electrode connection surface 1281.

### 42. Combination of Capacitor and Another Capacitor According to 14th Configuration Example

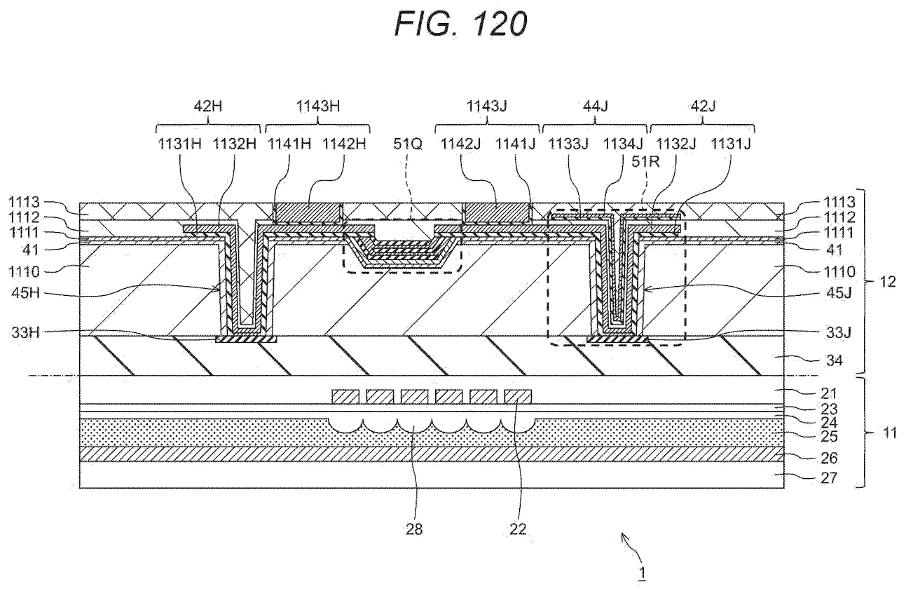

FIG. 120 is a cross-sectional view illustrating a modification of the solid-state imaging device 1 according to the 14th embodiment.

In FIG. 120, parts corresponding to those of the solid-state imaging device 1 illustrated in FIG. 109 are denoted by the same reference numerals, and description of the parts will be omitted as appropriate, and different parts will be described.

The solid-state imaging device 1 illustrated in FIG. 120 includes both the capacitor 51Q illustrated in FIG. 109 and a capacitor 51R including the combination of the planar capacitor and the cylindrical capacitor described in FIG. 19.

The capacitor 51R having the planar capacitor and the cylindrical capacitor includes a first rewiring 42J, a second rewiring 44J, and a third interlayer insulating film 1112 therebetween. The second rewiring 44J includes, for example, a seed metal 1133J including a barrier metal and a Cu seed film, and a Cu wiring 1134J.

As described above, the capacitor 51Q according to the 14th configuration example can be used together with the capacitor 51R including the planar capacitor and the cylindrical capacitor. Thus, since the electrostatic capacitance can be further increased, higher speed transmission can be performed.

The solid-state imaging device 1 can employ a configuration in which two or more capacitors 51 of the first to 14th configuration examples described above are arbitrarily combined.

### 43. Usage Example of Image Sensor

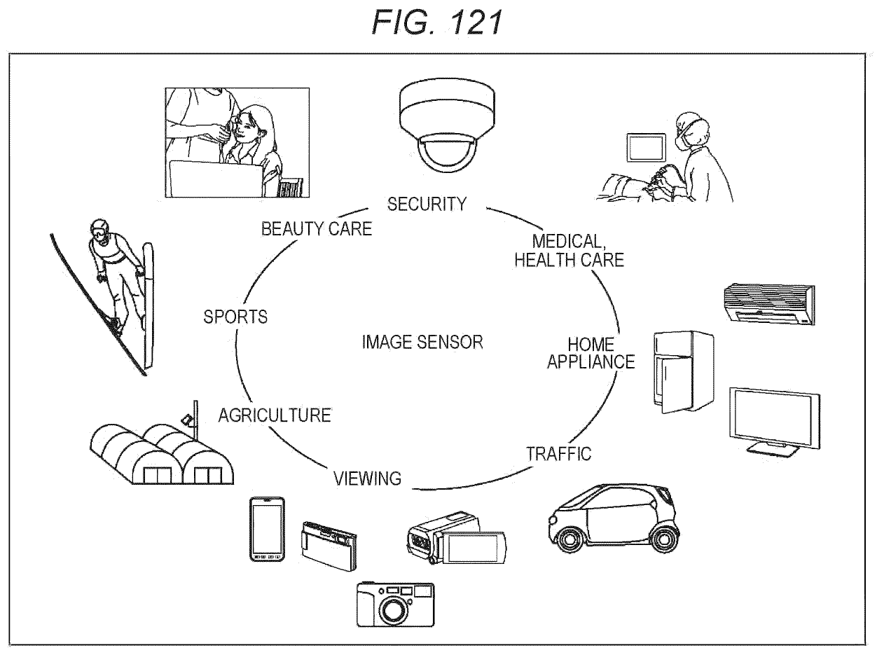

FIG. 121 is a diagram illustrating a usage example of an image sensor using the above-described solid-state imaging device 1.

The image sensor using the above-described solid-state imaging device 1 can be used, for example, in various cases of sensing light such as visible light, infrared light, ultraviolet light, X-rays, and the like as follows.
A device that captures an image to be used for viewing, such as a digital camera and a portable device with a camera function
A device for traffic purpose such as an in-vehicle sensor that captures images of the front, rear, surroundings, interior, and the like of an automobile, a monitoring camera for monitoring traveling vehicles and roads, and a ranging sensor that measures a distance between vehicles and the like for safe driving such as automatic stop, recognition of a driver's condition, and the like
A device for home appliance such as a television, a refrigerator, and an air conditioner that captures an image of a user's gesture and performs a device operation according to the gesture
A device used for medical and health care such as an endoscope and a device that performs angiography by receiving infrared light
A device used for security such as a security monitoring camera and an individual authentication camera
A device used for beauty care such as a skin measuring instrument for capturing images of skin and a microscope for capturing images of the scalp
A device used for sport such as an action camera or a wearable camera for sports applications or the like
A device used for agriculture such as a camera for monitoring conditions of fields and crops.

### 44. Application Example for Electronic Device

The present technology is not limited to application to a solid-state imaging device. That is, the present technology can be applied to all electronic devices that use a solid-state imaging device for an image capture unit (photoelectric converting unit), such as an imaging device such as a digital still camera or video camera, a portable terminal device having an imaging function, or a copying machine using a solid-state imaging device in an image reading unit. The solid-state imaging device may be formed as one chip, or may be in the form of a module having an imaging function in which an image pickup unit and a signal processing section or an optical system are packaged together.

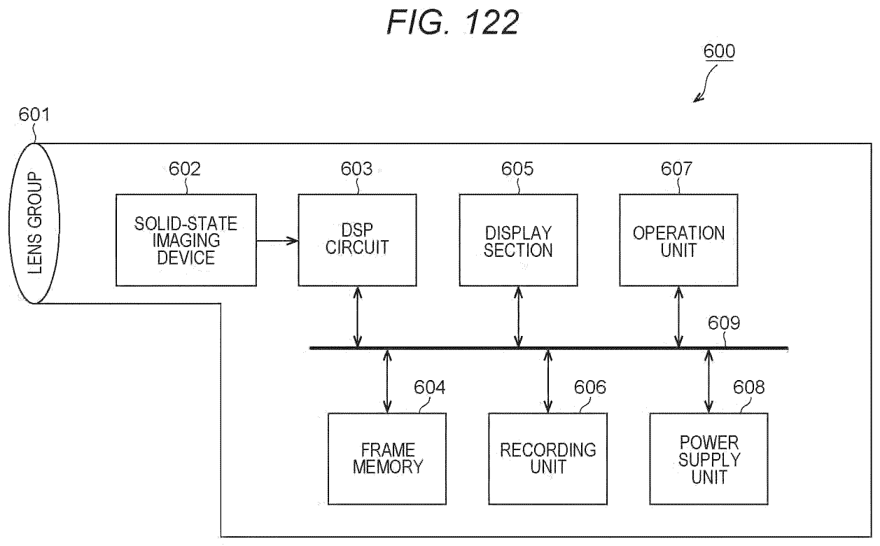

FIG. 122 is a block diagram illustrating a configuration example of an imaging device as an electronic device to which the present technology is applied.

An imaging device 600 in FIG. 122 includes an optical unit 601 including a lens group and the like, a solid-state imaging device (imaging device) 602 in which the configuration of the solid-state imaging device 1 in FIG. 1 is employed, and a digital signal processor (DSP) circuit 603 that is a camera signal processing circuit. Furthermore, the imaging device 600 also includes a frame memory 604, a display section 605, a recording unit 606, an operation unit 607, and a power supply unit 608. The DSP circuit 603, the frame memory 604, the display section 605, the recording unit 606, the operation unit 607, and the power supply unit 608 are connected with each other via a bus line 609.

The optical unit 601 captures incident light (image light) from a subject and forms an image on an imaging surface of the solid-state imaging device 602. The solid-state imaging device 602 converts the light amount of the incident light imaged on the imaging surface by the optical unit 601 into an electric signal in units of pixels and outputs the electric signal as a pixel signal. As the solid-state imaging device 602, the solid-state imaging device 1 in FIG. 1, that is, a solid-state imaging device in which a capacitor 51 is formed using two rewiring layers of a first rewiring 42 and a second rewiring 44, and a potential is stabilized by connecting the capacitor 51 to an internal electrode 33A connected to a power supply voltage, thereby improving signal delay and jitter can be used.

The display section 605 includes, for example, a thin display such as a liquid crystal display (LCD) or an organic electro luminescence (EL) display, and displays a moving image or a still image captured by the solid-state imaging device 602. The recording unit 606 records the moving image or the still image captured by the solid-state imaging device 602 on a recording medium such as a hard disk or a semiconductor memory.

The operation unit 607 issues operation commands regarding various functions of the imaging device 600 under operation by the user. The power supply unit 608 supplies various power sources serving as operation power sources for the DSP circuit 603, the frame memory 604, the display section 605, the recording unit 606, and the operation unit 607 to these supply targets as appropriate.

As described above, by using the solid-state imaging device 1 to which each of the above-described embodiments is applied as the solid-state imaging device 602, signal delay and jitter can be improved. Therefore, even in the imaging device 600 such as a video camera, a digital still camera, or a camera module for a mobile device such as a mobile phone or other devices, the increased rate of capturing images can be achieved.

### <45. Application Example to Endoscopic Surgery System>

The technology according to the present disclosure (the present technology) can be applied to various products. For example, the technology according to the present disclosure may be applied to an endoscopic surgery system.

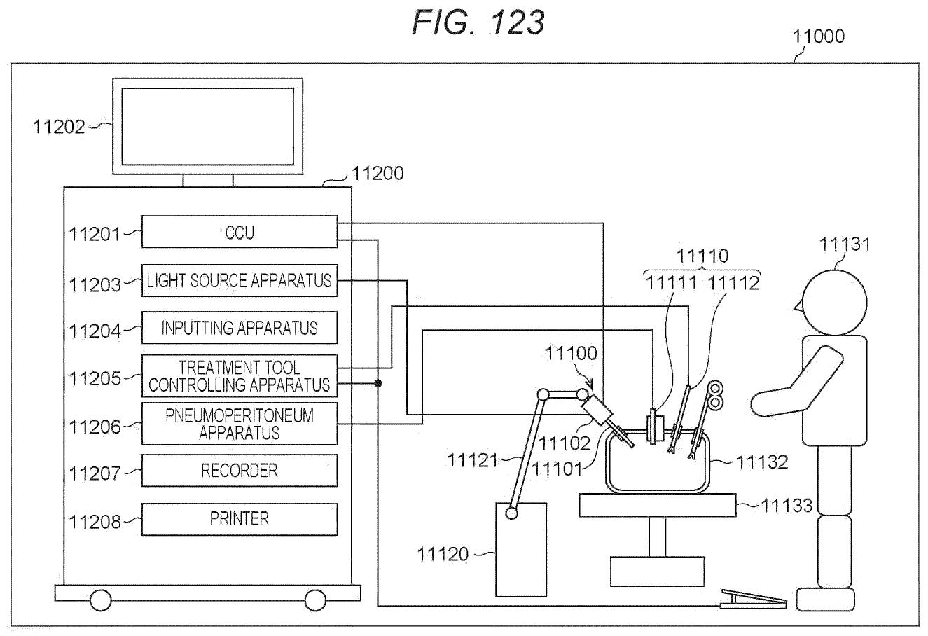

FIG. 123 is a diagram illustrating an example of a schematic configuration of an endoscopic surgery system to which the technology according to the present disclosure (present technology) can be applied.

FIG. 123 illustrates a state in which a surgeon (medical doctor) 11131 is performing surgery for a patient 11132 on a patient bed 11133 using an endoscopic surgery system 11000. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process). The display apparatus 11202 displays thereon an image based on an image signal, for which the image processes have been performed by the CCU 11201, under the control of the CCU 11201.

The light source apparatus 11203 includes a light source such as a light emitting diode (LED), for example, and supplies irradiation light for imaging a surgical region or the like to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

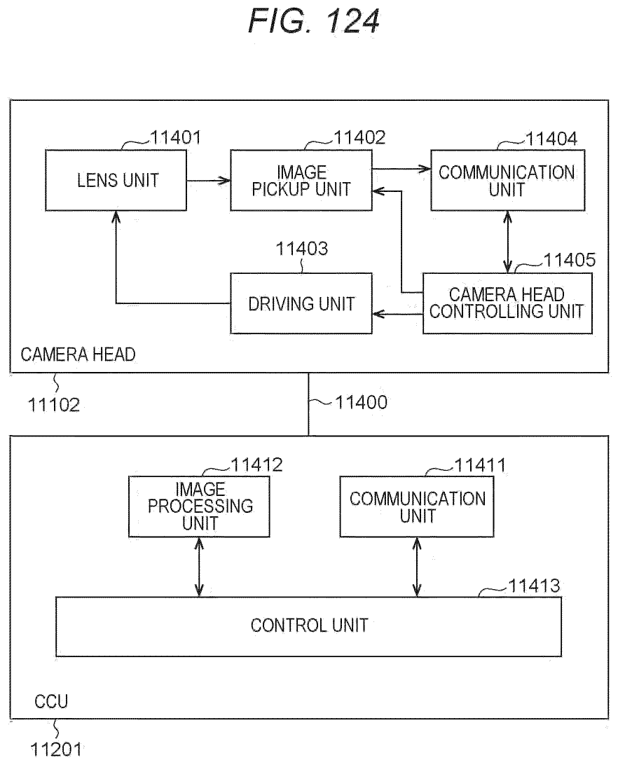

FIG. 124 is a block diagram illustrating an example of functional configurations of the camera head 11102 and the CCU 11201 illustrated in FIG. 123.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. Alternatively, the image pickup unit 11402 may include a pair of image pickup elements for acquiring right-eye and left-eye image signals corresponding to three-dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements. Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to the lens unit 11401 and the image pickup unit 11402 of the camera head 11102 among the above-described configurations. Specifically, the solid-state imaging device 1 according to each embodiment can be applied as the lens unit 11401 and the image pickup unit 11402. By applying the technology according to the present disclosure to the lens unit 11401 and the image pickup unit 11402, it is possible to obtain a clearer surgical region image while downsizing the camera head 11102.

Note that an endoscopic surgery system has been described as an example herein, but the technology according to the present disclosure may be applied to a microscopic surgery system or the like, for example.

### 46. Application Example to Mobile Body

The technology according to the present disclosure (the present technology) can be applied to various products. For example, the technology according to the present disclosure may be achieved in the form of a device to be mounted on a mobile body of any kind, such as an automobile, an electric vehicle, a hybrid electric vehicle, a motorcycle, a bicycle, a personal mobility, an airplane, a drone, a vessel, or a robot.

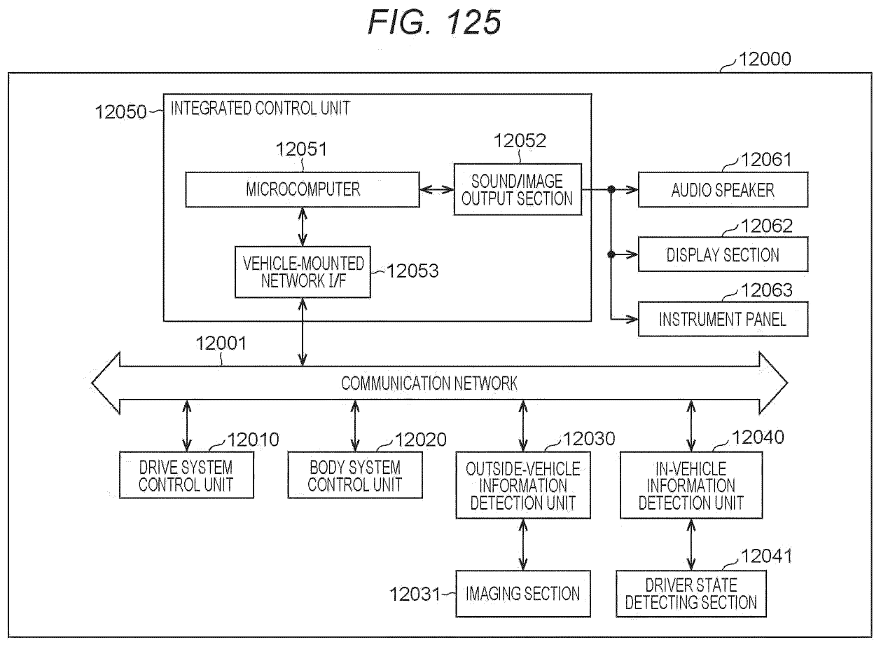

FIG. 125 is a block diagram illustrating a schematic configuration example of a vehicle control system that is an example of a mobile body control system to which the technology according to the present disclosure can be applied.

The vehicle control system 12000 includes a plurality of electronic control units connected to each other via a communication network 12001. In the example illustrated in FIG. 125, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver.” The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 125, an audio speaker 12061, a display section 12062, and an instrument panel 12063 are illustrated as examples of the output devices. The display section 12062 may, for example, include at least one of an on-board display and a head-up display.

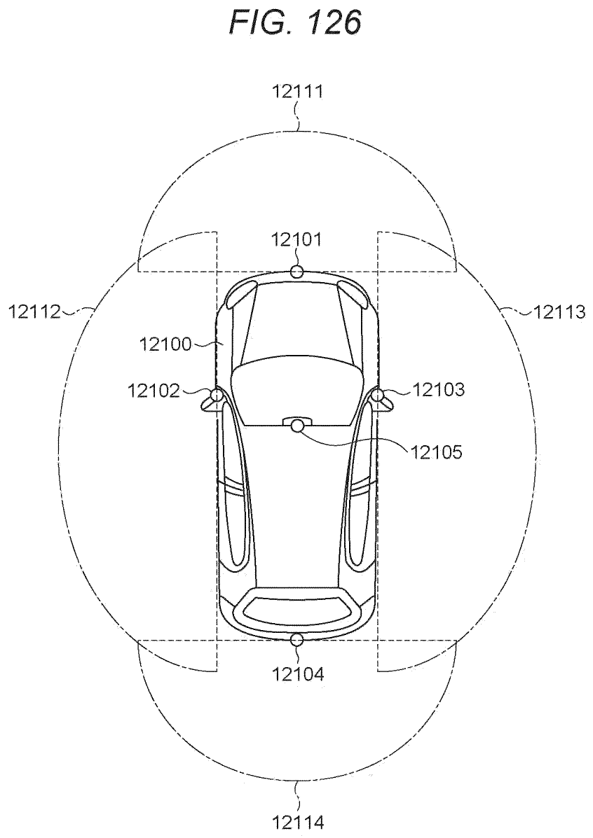

FIG. 126 is a view illustrating an example of the installation position of the imaging section 12031.

In FIG. 126, a vehicle 12100 includes imaging sections 12101, 12102, 12103, 12104, and 12105, as the imaging section 12031.

The imaging sections 12101, 12102, 12103, 12104, and 12105 are, for example, provided at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 126 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 among the configurations described above. Specifically, the solid-state imaging device 1 according to each embodiment can be applied as the imaging section 12031. By applying the technology according to an embodiment of the present disclosure to the imaging section 12031, it is possible to obtain a more easily viewable captured image while reducing the size. Furthermore, it is possible to reduce driver's fatigue and increase the safety of the driver and the vehicle by using the obtained captured image.

Furthermore, the present technology is not limited to application to a solid-state imaging device that detects distribution of the amount of incident light of visible light and captures the distribution as an image, and can be applied to all solid-state imaging devices (physical quantity distribution detection devices) such as a solid-state imaging device that captures distribution of the amount of incident infrared rays, X-rays, particles, or the like as an image, a fingerprint detection sensor that detects distribution of other physical quantities such as pressure, capacitance, and the like, and captures the distribution as an image in a broad sense, and the like.

Furthermore, the present technology can be applied not only to solid-state imaging devices but also to general semiconductor devices having other semiconductor integrated circuits.

An embodiment of the present technology is not limited to the embodiment described above, and various modifications can be made without departing from the scope of the present technology.

For example, it is possible to employ a mode obtained by combining all or some of the plurality of embodiments described above.

Note that, the effects described in the present specification are merely examples and are not limited, and there may be effects other than those described in the present specification.

Note that the technique of the present disclosure can have the following configurations.

(1)

A semiconductor device including:
an internal electrode formed on a first surface side of a semiconductor substrate;
a through hole formed at a position corresponding to the internal electrode of the semiconductor substrate;
a first rewiring formed on a second surface side opposite to the first surface side of the semiconductor substrate and connected to the internal electrode via the through hole;
a second rewiring connected to the first rewiring and formed on a side closer to an external connection terminal than the first rewiring; and
an interlayer insulating film formed between the first rewiring and the second rewiring, in which
two of a first internal electrode and a second internal electrode are provided as the internal electrode, and
the first rewiring connected to the first internal electrode, the second rewiring connected to the second internal electrode, and the interlayer insulating film constitute a capacitor.
   (2)

The semiconductor device according to (1) above, further including:
photoelectric conversion elements arranged in a matrix on the first surface side of the semiconductor substrate.
   (3)

The semiconductor device according to (1) or (2) above, in which the first internal electrode is connected to an external connection terminal via the first rewiring and the second rewiring.

(4)

The semiconductor device according to (3) above, in which a power supply voltage or ground is supplied to the external connection terminal.

(5)

The semiconductor device according to any one of (1) to (4) above, in which the first rewiring and the second rewiring constituting the capacitor include a planar capacitor formed on the second surface side of the semiconductor substrate.

(6)

The semiconductor device according to any one of (1) to (5) above, in which
the first rewiring and the second rewiring constituting the capacitor include a cylindrical capacitor formed inside the through hole.
   (7)

The semiconductor device according to (6) above, in which the second rewiring is embedded in the through hole in a plug shape.

(8)

The semiconductor device according to (6) above, in which
a side surface of the through hole in which the cylindrical capacitor is formed is formed in an uneven shape.
   (9)

The semiconductor device according to (6) above, in which
a side surface of the through hole in which the cylindrical capacitor is formed is formed in any of an arc shape, a triangular shape, or a quadrangular shape in a cross-sectional view.
   (10)

The semiconductor device according to (6) above, in which an amount of recess on a side surface of the through hole is equal to or more than 0.3 μm with respect to a smooth surface connecting apexes of protrusions.

(11)

The semiconductor device according to (6) above, in which
only a part in a depth direction of a side surface of the through hole in which the cylindrical capacitor is formed is formed in an uneven shape.
   (12)

The semiconductor device according to (1) above, in which
the internal electrode has a multilayer wiring structure in which a plurality of lattice pattern wirings is stacked.
   (13)

The semiconductor device according to (12) above, in which
the internal electrode has a multilayer wiring structure in which a plurality of lattice pattern wirings is stacked by staggering.
   (14)

The semiconductor device according to (12) above, in which
the internal electrode has a multilayer wiring structure in which a plurality of lattice pattern wirings is stacked by staggering.
   (15)

The semiconductor device according to (6) above, in which
the internal electrode has a multilayer wiring structure in which a plurality of lattice pattern wirings is stacked so as to overlap each other in plan view.
   (16)

The semiconductor device according to (6) above, in which
a bottom portion of the first rewiring of the cylindrical capacitor is formed in an uneven shape.
   (17)

The semiconductor device according to (6) above, in which
the internal electrode has a multilayer wiring structure in which a plurality of lattice pattern wirings is stacked, and
the cylindrical capacitor has a protrusion embedded in an opening of one or more of the lattice pattern wirings.
   (18)

The semiconductor device according to (17) above, in which
the cylindrical capacitor includes a plurality of the protrusions having different diameters and depths.
   (19)

The semiconductor device according to (17) above, in which
the protrusion of the cylindrical capacitor is formed in a circular or rectangular planar shape.
   (20)

The semiconductor device according to (1) above, further including:
a first electrode connected to a rewiring formed on the second surface side of the semiconductor substrate;
a second electrode surrounding a periphery of the first electrode in plan view; and
an insulating film between the first electrode and the second electrode, in which the first electrode, the second electrode, and the insulating film constitute a capacitor.
   (21)

The semiconductor device according to (1) above, further including:
a trench formed in the semiconductor substrate and having a side surface inclined at a predetermined angle;
at least two electrode films of a first electrode film and a second electrode film stacked in the trench; and
a dielectric film formed between at least the first electrode film and the second electrode film, in which
the first electrode film is connected to the first rewiring on the semiconductor substrate along the side surface of the trench,
the second electrode film is connected to another of the first rewirings on the semiconductor substrate along the side surface of the trench, and
a capacitor is formed by stacking the first electrode film, the dielectric film, and the second electrode film.
   (22)

The semiconductor device according to any one of (1) to (7) above, in which
the capacitor is constituted by connecting, in series or in parallel, a planar capacitor formed by the first rewiring and the second rewiring on the second surface side of the semiconductor substrate, and a cylindrical capacitor formed by the first rewiring and the second rewiring in the through hole.
   (23)

The semiconductor device according to any one of (1) to (8) above, in which
the capacitor includes an interlayer thin film portion in which a film thickness of the interlayer insulating film between the first rewiring and the second rewiring is formed to be thinner than a film thickness of another of the interlayer insulating films.
   (24)

The semiconductor device according to (23) above, in which
the film thickness of the interlayer insulating film of the interlayer thin film portion is equal to or less than 500 nm, and
the film thickness of the another of the interlayer insulating films is 5 μm to 10 μm.
   (25)

The semiconductor device according to any one of (1) to (10) above, in which
the interlayer insulating film between the first rewiring and the second rewiring constituting the capacitor is formed by a high dielectric film.
   (26)

The semiconductor device according to (25) above, in which
the high dielectric film is formed on an entire surface in plan view.
   (27)

The semiconductor device according to (25) above, in which
the high dielectric film is formed only in a region where the first rewiring and the second rewiring constituting the capacitor overlap each other.
   (28)

The semiconductor device according to any one of (1) to (13) above, in which
the semiconductor substrate has a groove dug to a predetermined depth, and
a step is formed in the groove of the semiconductor substrate in the first rewiring and the second rewiring constituting the capacitor.
   (29)

The semiconductor device according to (28) above, in which
the groove is formed at a same depth as the through hole.
   (30)

The semiconductor device according to any one of (1) to (15) above, in which
the first rewiring includes a first wiring and a second wiring capacitively coupled in a planar direction, and
the second rewiring includes a third wiring and a fourth wiring capacitively coupled in the planar direction.
   (31)

The semiconductor device according to (30) above, in which
a planar shape of each of the first wiring and the second wiring is a comb shape, and a planar shape of each of the third wiring and the fourth wiring is a comb shape.
   (32)

The semiconductor device according to any one of (1) to (17) above, in which the first rewiring and the second rewiring constituting the capacitor are formed in a region overlapping an entire region of a pixel region.

(33)

A manufacturing method of a semiconductor device, the method including:
forming an internal electrode formed on a first surface side of a semiconductor substrate,
a through hole formed at a position corresponding to the internal electrode of the semiconductor substrate,
a first rewiring formed on a second surface side opposite to the first surface side of the semiconductor substrate and connected to the internal electrode via the through hole,
a second rewiring connected to the first rewiring and formed on a side closer to an external connection terminal than the first rewiring, and
an interlayer insulating film formed between the first rewiring and the second rewiring, in which
two of a first internal electrode and a second internal electrode are formed as the internal electrode, and
the first rewiring connected to the first internal electrode, the second rewiring connected to the second internal electrode, and the interlayer insulating film constitute a capacitor.
   (34)

An electronic device including a semiconductor device including:
an internal electrode formed on a first surface side of a semiconductor substrate;
a through hole formed at a position corresponding to the internal electrode of the semiconductor substrate;
a first rewiring formed on a second surface side opposite to the first surface side of the semiconductor substrate and connected to the internal electrode via the through hole;
a second rewiring connected to the first rewiring and formed on a side closer to an external connection terminal than the first rewiring; and
an interlayer insulating film formed between the first rewiring and the second rewiring, in which
two of a first internal electrode and a second internal electrode are provided as the internal electrode, and
the first rewiring connected to the first internal electrode, the second rewiring connected to the second internal electrode, and the interlayer insulating film constitute a capacitor.

### <1A>

A semiconductor device including:
a first electrode connected to a rewiring formed on a back surface side of a semiconductor substrate;
a second electrode surrounding a periphery of the first electrode in plan view; and
an insulating film between the first electrode and the second electrode, in which a capacitor is constituted by the first electrode, the second electrode, and the insulating film.

### <2A>

The semiconductor device according to <1A> above, in which
the insulating film includes a high dielectric film having a relative permittivity higher than a relative permittivity of a silicon oxide film.

### <3A>

The semiconductor device according to <1A> or <2A> above, in which
the first electrode is an external connection terminal, and
the second electrode is connected to an external connection terminal different from the first electrode.

### <4A>

The semiconductor device according to any one of <1A> to <3A> above, in which
the first electrode is connected to a rewiring,
the insulating film is also formed between the second electrode and the rewiring, and
the capacitor includes the second electrode, the rewiring, and the insulating film.

### <5A>

The semiconductor device according to any one of <1A> to <4A> above, in which
the first electrode is an external connection terminal, and
a power supply voltage, ground, or a signal is supplied to the first electrode.

### <6A>

The semiconductor device according to any one of <1A> to <5A> above, in which
a periphery of the first electrode is covered with a protective film, and
an upper surface of the second electrode is covered with the protective film in plan view.

### <7A>

The semiconductor device according to any one of <1A> to <6A> above, in which
a periphery of the second electrode is covered with the insulating film in plan view.

### <8A>

The semiconductor device according to any one of <1A> to <7A> above, in which
a back surface of the device excluding the first electrode is covered with a protective film.

### <9A>

The semiconductor device according to any one of <1A> to <8A> above, in which
the second electrode is a wiring that annularly surrounds the first electrode in plan view.

### <10A>

The semiconductor device according to any one of <1A> to <9A> above, in which
the first electrode has a circular shape or a polygonal shape in plan view, and
the second electrode is a wiring that annularly surrounds the first electrode having a circular shape or a polygonal shape.

### <11A>

The semiconductor device according to any one of <1A> to <10A> above, in which
the first electrode and the second electrode each have a barrier metal on a side surface, and
a material of the barrier metal contains any one of Ta, TaN, Ti, TiN, and Ru.

### <12A>

A manufacturing method of a semiconductor device, the method including:
forming a first electrode connected to a rewiring formed on a back surface side of a semiconductor substrate,
a second electrode surrounding a periphery of the first electrode in plan view, and
an insulating film between the first electrode and the second electrode, in which
a capacitor is constituted by the first electrode, the second electrode, and the insulating film.

### <1B>a Semiconductor Device Including:

a trench formed in a semiconductor substrate and having a side surface inclined at a predetermined angle;
at least two electrode films of a first electrode film and a second electrode film stacked in the trench; and
a dielectric film formed between at least the first electrode film and the second electrode film, in which
the first electrode film formed along the side surface of the trench is connected to a first rewiring on the semiconductor substrate,
the second electrode film formed along the side surface of the trench is connected to another of the first rewirings on the semiconductor substrate, and
a capacitor is constituted by stacking the first electrode film, the dielectric film, and the second electrode film.

### <2B>

The semiconductor device according to <1B> above, further including
a third electrode film in the trench, in which
the capacitor is configured by stacking the first electrode film to the third electrode film and the dielectric film.

### <3B>

The semiconductor device according to <2B> above, in which
the third electrode film is configured to be connected to the first rewiring on the semiconductor substrate along a side surface of the trench.

### <4B>

The semiconductor device according to <2B> above, in which
the third electrode film is configured not to be connected to any of the first rewirings on the semiconductor substrate.

### <5B>

The semiconductor device according to any one of <2B> to <4B> above, in which
a material of the dielectric film between the first electrode film and the second electrode film is different from a material of the dielectric film between the second electrode film and the third electrode film.

### <6B>

The semiconductor device according to any one of <2B> to <5B> above, in which
the capacitor has a configuration in which two parallel plate capacitors are connected in parallel.

### <7B>

The semiconductor device according to any one of <2B> to <6B> above, in which
the capacitor has a configuration in which two parallel plate capacitors are connected in series.

### <8B>

The semiconductor device according to any one of <1B> to <7B> above, in which
the predetermined angle is in a range of 45 to 70 degrees.

### <9B>

The semiconductor device according to any one of <1B> to <8B> above, in which
a connection surface between the first electrode film and the first rewiring and a connection surface between the second electrode film and another of the first rewirings are linear in plan view and arranged in parallel.

### <10B>

The semiconductor device according to any one of <1B> to <9B> above, further including
a third electrode film and a fourth electrode film in the trench, in which
the first electrode film to the fourth electrode film are configured to be respectively connected to different first rewirings.

### <11B>

The semiconductor device according to <10B> above, in which
the four connection surfaces where the first electrode film to the fourth electrode film are connected to the first rewiring are arranged in a substantially quadrangular shape in plan view.

### <12B>

The semiconductor device according to <10B> or <11B> above, in which
different potentials are supplied to at least two adjacent electrode films among the first electrode film to the fourth electrode film.

### <13B>

The semiconductor device according to any one of <10B> to <12B> above, in which
different potentials are supplied to the first electrode film to the fourth electrode film.

### <14B>

The semiconductor device according to any one of <10B> to <13B> above, in which
the trench has a polygonal truncated pyramid shape.

### <15B>

The semiconductor device according to any one of <10B> to <14B> above, in which
the trench has a quadrangular truncated pyramid shape.

### <16B>

The semiconductor device according to any one of <1B> to <15B> above, in which
a plurality of the capacitors is connected in parallel or in series by the first rewiring.

### <17B>

The semiconductor device according to any one of <1B> to <16B> above, in which
two insulating films of different materials are stacked at a bottom portion of the trench.

### <18B>

A manufacturing method of a semiconductor device, the method including:
forming a trench having a side surface inclined at a predetermined angle in a semiconductor substrate;
forming at least two electrode films of a first electrode film and a second electrode film stacked in the trench;
forming a dielectric film between at least the first electrode film and the second electrode film, in which
the first electrode film formed along the side surface of the trench is formed to be connected to a first rewiring on the semiconductor substrate, and the second electrode film formed along the side surface of the trench is formed to be connected to another of the first rewirings on the semiconductor substrate, and
a capacitor is constituted by stacking the first electrode film, the dielectric film, and the second electrode film.

### REFERENCE SIGNS LIST

1 Solid-state imaging device
11 Sensor substrate
12 Logic substrate
21 Semiconductor substrate (silicon substrate)
22 Photodiode
23 Planarization film
24 Lens layer
25 Interlayer insulating film
26 Bonding resin
27 Light-transmissive substrate
28 On-chip lens
31 Semiconductor substrate (silicon substrate)
32 Multilayer wiring layer
33A to 33J Internal electrode
34 Interlayer insulating film
41 First interlayer insulating film
42 to 42L First rewiring
43, 43X, 43Y, 43Y′ Second interlayer insulating film
44A to 44J Second rewiring
45A to 45J Through hole
46A to 46C Through hole
47A, 47B Solder bump
48 Protective film
51A to 51R Capacitor
71 Pixel region
72 Peripheral region
111 Interlayer thin film portion
161 High dielectric film
221 Second rewiring
241 Second rewiring
261 First rewiring
262 Second rewiring
263A, 263B Groove
281 First rewiring
282 Second rewiring
283A, 283B Stopper film
284A, 284B Groove
301 First rewiring
301A First wiring
301B Second wiring
302 Second rewiring
302A First wiring
302B Second wiring
331 First rewiring
332 Second rewiring
351 Capacitor region
431 Semiconductor substrate
471 Semiconductor substrate
483 Internal electrode
492A, 492B Second interlayer insulating film
493 Through hole
501A, 501B First rewiring
502A, 502B Second rewiring
521A, 521C Seed metal
522A, 522C Cu wiring
523 Seed metal
524 Cu wiring
525 Seed metal
531 Pillar
561A Barrier metal
561A′ Seed metal
562A Cu seed film
563A Cu wiring
564A Seed metal
565A Copper
565A′ Copper
566A Seed metal
567A Copper
571 Pillar
572R Ring wiring
573 High dielectric film
574 First rewiring
600 Imaging device
602 Solid-state imaging device
801A′ Seed metal
803A Cu wiring
831 Third interlayer insulating film
851 High dielectric film
851A High dielectric film
851B High dielectric film
861 Region
D1 to D5 Lattice pattern wiring
901 High dielectric film
911 Metal wiring layer
912 Contact wiring
941 Cylinder capacitor protrusion
961A First electrode
961B Second electrode
961B Second electrode
962 Seed metal
963 Protective film
1011 First rewiring
1012 Second rewiring
1013 Third rewiring
1021 High dielectric film
1022 High dielectric film
1061 First rewiring
1062 High dielectric film
1063 Second rewiring
1081 Cylinder-type MIM capacitor
1082 Cylinder capacitor protrusion
1091 Metal wiring layer
1110 Semiconductor substrate
1111 Second interlayer insulating film
1112 Third interlayer insulating film
1113 Protective film
1131 Seed metal
1211 Insulating film
1221 Electrode film
1222 Dielectric film
1223 Electrode connection surface
1231 Trench
1241 Photoresist
1242 Photoresist
1243 Photoresist
1244 Photoresist
1251 Electrode film
1261 Dielectric film
1281 Electrode connection surface

What is claimed is:

1. A semiconductor device, comprising:
an internal electrode formed on a first surface side of a semiconductor substrate;
a through hole formed at a position corresponding to the internal electrode of the semiconductor substrate;
a first rewiring formed on a second surface side opposite to the first surface side of the semiconductor substrate and connected to the internal electrode via the through hole;
a second rewiring connected to the first rewiring and formed on a side closer to an external connection terminal than the first rewiring; and
an interlayer insulating film formed between the first rewiring and the second rewiring, wherein
two of a first internal electrode and a second internal electrode are provided as the internal electrode, and
the first rewiring connected to the first internal electrode, the second rewiring connected to the second internal electrode, and the interlayer insulating film constitute a capacitor.

2. The semiconductor device according to claim 1, further comprising:
photoelectric conversion elements arranged in a matrix on the first surface side of the semiconductor substrate.

3. The semiconductor device according to claim 1, wherein
the first internal electrode is connected to an external connection terminal via the first rewiring and the second rewiring.

4. The semiconductor device according to claim 3, wherein
a power supply voltage or ground is supplied to the external connection terminal.

5. The semiconductor device according to claim 1, wherein
the first rewiring and the second rewiring constituting the capacitor include a planar capacitor formed on the second surface side of the semiconductor substrate.

6. The semiconductor device according to claim 1, wherein
the first rewiring and the second rewiring constituting the capacitor include a cylindrical capacitor formed inside the through hole.

7. The semiconductor device according to claim 6, wherein
the second rewiring is embedded in the through hole in a plug shape.

8. The semiconductor device according to claim 6, wherein
a side surface of the through hole in which the cylindrical capacitor is formed is formed in an uneven shape.

9. The semiconductor device according to claim 6, wherein
a side surface of the through hole in which the cylindrical capacitor is formed is formed in any of an arc shape, a triangular shape, or a quadrangular shape in a cross-sectional view.

10. The semiconductor device according to claim 6, wherein
an amount of recess on a side surface of the through hole is equal to or more than 0.3 μm with respect to a smooth surface connecting apexes of protrusions.

11. The semiconductor device according to claim 6, wherein
only a part in a depth direction of a side surface of the through hole in which the cylindrical capacitor is formed is formed in an uneven shape.

12. The semiconductor device according to claim 1, wherein
the internal electrode has a multilayer wiring structure in which a plurality of lattice pattern wirings is stacked.

13. The semiconductor device according to claim 12, wherein
the internal electrode has a multilayer wiring structure in which a plurality of lattice pattern wirings is stacked by staggering.

14. The semiconductor device according to claim 12, wherein
the internal electrode has a multilayer wiring structure in which a plurality of lattice pattern wirings is stacked by staggering.

15. The semiconductor device according to claim 6, wherein
the internal electrode has a multilayer wiring structure in which a plurality of lattice pattern wirings is stacked so as to overlap each other in plan view.

16. The semiconductor device according to claim 6, wherein
a bottom portion of the first rewiring of the cylindrical capacitor is formed in an uneven shape.

17. The semiconductor device according to claim 6, wherein
the internal electrode has a multilayer wiring structure in which a plurality of lattice pattern wirings is stacked, and
the cylindrical capacitor has a protrusion embedded in an opening of one or more of the lattice pattern wirings.

18. The semiconductor device according to claim 17, wherein
the cylindrical capacitor includes a plurality of the protrusions having different diameters and depths.

19. The semiconductor device according to claim 17, wherein
the protrusion of the cylindrical capacitor is formed in a circular or rectangular planar shape.

20. The semiconductor device according to claim 1, further comprising:
a first electrode connected to a rewiring formed on the second surface side of the semiconductor substrate;
a second electrode surrounding a periphery of the first electrode in plan view; and
an insulating film between the first electrode and the second electrode, wherein the first electrode, the second electrode, and the insulating film constitute a capacitor.

21. The semiconductor device according to claim 1, further comprising:
a trench formed in the semiconductor substrate and having a side surface inclined at a predetermined angle;
at least two electrode films of a first electrode film and a second electrode film stacked in the trench; and
a dielectric film formed between at least the first electrode film and the second electrode film, wherein
the first electrode film is connected to the first rewiring on the semiconductor substrate along the side surface of the trench,
the second electrode film is connected to another of the first rewirings on the semiconductor substrate along the side surface of the trench, and
a capacitor is formed by stacking the first electrode film, the dielectric film, and the second electrode film.

22. The semiconductor device according to claim 1, wherein
the capacitor is constituted by connecting, in series or in parallel, a planar capacitor formed by the first rewiring and the second rewiring on the second surface side of the semiconductor substrate, and a cylindrical capacitor formed by the first rewiring and the second rewiring in the through hole.

23. The semiconductor device according to claim 1, wherein
the capacitor includes an interlayer thin film portion in which a film thickness of the interlayer insulating film between the first rewiring and the second rewiring is formed to be thinner than a film thickness of another of the interlayer insulating films.

24. The semiconductor device according to claim 23, wherein
the film thickness of the interlayer insulating film of the interlayer thin film portion is equal to or less than 500 nm, and
the film thickness of the another of the interlayer insulating films is 5 μm to 10 μm.

25. The semiconductor device according to claim 1, wherein
the interlayer insulating film between the first rewiring and the second rewiring constituting the capacitor is formed by a high dielectric film.

26. The semiconductor device according to claim 25, wherein
the high dielectric film is formed on an entire surface in plan view.

27. The semiconductor device according to claim 25, wherein
the high dielectric film is formed only in a region where the first rewiring and the second rewiring constituting the capacitor overlap each other.

28. The semiconductor device according to claim 1, wherein
the semiconductor substrate has a groove dug to a predetermined depth, and
a step is formed in the groove of the semiconductor substrate in the first rewiring and the second rewiring constituting the capacitor.

29. The semiconductor device according to claim 28, wherein
the groove is formed at a same depth as the through hole.

30. The semiconductor device according to claim 1, wherein
the first rewiring includes a first wiring and a second wiring capacitively coupled in a planar direction, and
the second rewiring includes a third wiring and a fourth wiring capacitively coupled in the planar direction.

31. The semiconductor device according to claim 30, wherein
a planar shape of each of the first wiring and the second wiring is a comb shape, and a planar shape of each of the third wiring and the fourth wiring is a comb shape.

32. The semiconductor device according to claim 1, wherein
the first rewiring and the second rewiring constituting the capacitor are formed in a region including an entire region of a pixel region in plan view.

33. A manufacturing method of a semiconductor device, the method comprising:
forming an internal electrode formed on a first surface side of a semiconductor substrate,
a through hole formed at a position corresponding to the internal electrode of the semiconductor substrate,
a first rewiring formed on a second surface side opposite to the first surface side of the semiconductor substrate and connected to the internal electrode via the through hole,
a second rewiring connected to the first rewiring and formed on a side closer to an external connection terminal than the first rewiring, and
an interlayer insulating film formed between the first rewiring and the second rewiring, wherein
two of a first internal electrode and a second internal electrode are formed as the internal electrode, and
the first rewiring connected to the first internal electrode, the second rewiring connected to the second internal electrode, and the interlayer insulating film constitute a capacitor.

34. An electronic device comprising a semiconductor device, comprising:
an internal electrode formed on a first surface side of a semiconductor substrate;
a through hole formed at a position corresponding to the internal electrode of the semiconductor substrate;
a first rewiring formed on a second surface side opposite to the first surface side of the semiconductor substrate and connected to the internal electrode via the through hole;
a second rewiring connected to the first rewiring and formed on a side closer to an external connection terminal than the first rewiring; and
an interlayer insulating film formed between the first rewiring and the second rewiring, wherein
two of a first internal electrode and a second internal electrode are provided as the internal electrode, and
the first rewiring connected to the first internal electrode, the second rewiring connected to the second internal electrode, and the interlayer insulating film constitute a capacitor.

35. A semiconductor device, comprising:
a first electrode connected to a rewiring formed on a back surface side of a semiconductor substrate;
a second electrode surrounding a periphery of the first electrode in plan view; and
an insulating film between the first electrode and the second electrode, wherein a capacitor is constituted by the first electrode, the second electrode, and the insulating film.

36. The semiconductor device according to claim 35, wherein
the insulating film includes a high dielectric film having a relative permittivity higher than a relative permittivity of a silicon oxide film.

37. The semiconductor device according to claim 35, wherein
the first electrode is an external connection terminal, and
the second electrode is connected to an external connection terminal different from the first electrode.

38. The semiconductor device according to claim 35, wherein
the first electrode is connected to a rewiring,
the insulating film is also formed between the second electrode and the rewiring, and
the capacitor includes the second electrode, the rewiring, and the insulating film.

39. The semiconductor device according to claim 35, wherein
the first electrode is an external connection terminal, and
a power supply voltage, ground, or a signal is supplied to the first electrode.

40. The semiconductor device according to claim 35, wherein
a periphery of the first electrode is covered with a protective film, and
an upper surface of the second electrode is covered with the protective film in plan view.

41. The semiconductor device according to claim 35, wherein
a periphery of the second electrode is covered with the insulating film in plan view.

42. The semiconductor device according to claim 35, wherein
a back surface of the device excluding the first electrode is covered with a protective film.

43. The semiconductor device according to claim 35, wherein
the second electrode is a wiring that annularly surrounds the first electrode in plan view.

44. The semiconductor device according to claim 35, wherein
the first electrode has a circular shape or a polygonal shape in plan view, and
the second electrode is a wiring that annularly surrounds the first electrode having a circular shape or a polygonal shape.

45. The semiconductor device according to claim 35, wherein
the first electrode and the second electrode each have a barrier metal on a side surface, and
a material of the barrier metal contains any one of Ta, TaN, Ti, TiN, and Ru.

46. A manufacturing method of a semiconductor device, the method comprising:
forming a first electrode connected to a rewiring formed on a back surface side of a semiconductor substrate,
a second electrode surrounding a periphery of the first electrode in plan view, and
an insulating film between the first electrode and the second electrode, wherein
a capacitor is constituted by the first electrode, the second electrode, and the insulating film.

47. A semiconductor device, comprising:
a trench formed in a semiconductor substrate and having a side surface inclined at a predetermined angle;
at least two electrode films of a first electrode film and a second electrode film stacked in the trench; and
a dielectric film formed between at least the first electrode film and the second electrode film, wherein
the first electrode film formed along the side surface of the trench is connected to a first rewiring on the semiconductor substrate,
the second electrode film formed along the side surface of the trench is connected to another of the first rewirings on the semiconductor substrate, and
a capacitor is constituted by stacking the first electrode film, the dielectric film, and the second electrode film.

48. The semiconductor device according to claim 47, further comprising:
a third electrode film in the trench, wherein
the capacitor is configured by stacking the first electrode film to the third electrode film and the dielectric film.

49. The semiconductor device according to claim 48, wherein
the third electrode film is configured to be connected to the first rewiring on the semiconductor substrate along a side surface of the trench.

50. The semiconductor device according to claim 48, wherein
the third electrode film is configured not to be connected to any of the first rewirings on the semiconductor substrate.

51. The semiconductor device according to claim 48, wherein
a material of the dielectric film between the first electrode film and the second electrode film is different from a material of the dielectric film between the second electrode film and the third electrode film.

52. The semiconductor device according to claim 48, wherein
the capacitor has a configuration in which two parallel plate capacitors are connected in parallel.

53. The semiconductor device according to claim 48, wherein
the capacitor has a configuration in which two parallel plate capacitors are connected in series.

54. The semiconductor device according to claim 47, wherein
the predetermined angle is in a range of 45 to 70 degrees.

55. The semiconductor device according to claim 47, wherein
a connection surface between the first electrode film and the first rewiring and a connection surface between the second electrode film and another of the first rewirings are linear in plan view and arranged in parallel.

56. The semiconductor device according to claim 47, further comprising:
a third electrode film and a fourth electrode film in the trench, wherein
the first electrode film to the fourth electrode film are configured to be respectively connected to different first rewirings.

57. The semiconductor device according to claim 56, wherein
the four connection surfaces where the first electrode film to the fourth electrode film are connected to the first rewiring are arranged in a substantially quadrangular shape in plan view.

58. The semiconductor device according to claim 56, wherein
different potentials are supplied to at least two adjacent electrode films among the first electrode film to the fourth electrode film.

59. The semiconductor device according to claim 56, wherein
different potentials are supplied to the first electrode film to the fourth electrode film.

60. The semiconductor device according to claim 56, wherein
the trench has a polygonal truncated pyramid shape.

61. The semiconductor device according to claim 56, wherein
the trench has a quadrangular truncated pyramid shape.

62. The semiconductor device according to claim 47, wherein
a plurality of the capacitors is connected in parallel or in series by the first rewiring.

63. The semiconductor device according to claim 47, wherein
two insulating films of different materials are stacked at a bottom portion of the trench.

64. A manufacturing method of a semiconductor device, the method comprising:
forming a trench having a side surface inclined at a predetermined angle in a semiconductor substrate;
forming at least two electrode films of a first electrode film and a second electrode film stacked in the trench;
forming a dielectric film between at least the first electrode film and the second electrode film, wherein
the first electrode film formed along the side surface of the trench is formed to be connected to a first rewiring on the semiconductor substrate, and the second electrode film formed along the side surface of the trench is formed to be connected to another of the first rewirings on the semiconductor substrate, and
a capacitor is constituted by stacking the first electrode film, the dielectric film, and the second electrode film.
